(19) United States
(12) Patent Application Publication
(10) Pub. No.: US 2026/0324069 A1
(43) Pub. Date: Oct. 15, 2026

(54) SEMICONDUCTOR DEVICE INCLUDING COMPLEMENTARY CELL REGIONS AND NON-COMPLEMENTARY CELL REGIONS AND METHOD OF MANUFACTURING SAME

(71) Applicant: TAIWAN SEMICONDUCTOR MANUFACTURING COMPANY, LTD., Hsinchu (TW)

(72) Inventors: Shuhei MATSUO, Hsinchu (TW); Tomoasa TAKADA, Hsinchu (TW); Tung-An LAN, Hsinchu (TW); Yoshinori ITOTAGAWA, Hsinchu (TW); Jia-Hong GAO, Hsinchu (TW)

(21) Appl. No.: 19/361,347

(22) Filed: Oct. 17, 2025

Related U.S. Application Data
(60) Provisional application No. 63/788,724, filed on Apr. 14, 2025.

(51) Int. Cl. H10D 84/90; H10D 89/10

(52) U.S. Cl. CPC H10D 84/974; H10D 84/931; H10D 89/10

(57) ABSTRACT

A library of standard cell regions is comprised of standard CMOS cell regions and standard non-CMOS standard cell regions. A semiconductor device includes: active regions (ARs) correspondingly configured with a first dopant type (first-type AR) or a second dopant type (second-type AR); cell regions including complementary cell regions and non-complementary cell regions; wherein each of the complementary cell regions including both first-type and second-type ARs; wherein each of the non-complementary cell regions including one AR of the first-type or the second-type and being free of including another AR conversely of the second-type or the first-type ARs; wherein the complementary cell regions having a height of at least about one unit, and the non-complementary cell regions having a height of about one-half unit; and wherein a first one of the non-complementary cell regions being arranged one of above or under a first one of the complementary cell regions.

### PRIORITY CLAIM

The application claims the priority of U.S. Provisional Application No. 63/788,724, filed Apr. 14, 2025, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1C are block diagrams, in accordance with some embodiments.

FIGS. 2A-2Q are diagrams of cell regions, in accordance with some embodiments.

FIG. 3AA-3AZ, 3BA-3BZ and 3CA-3CH are diagrams of arrangements of cell regions, in accordance with some embodiments.

FIG. 4AA-4AZ, 4BA-4BZ and 4CA-4CH are diagrams of arrangements of cell regions, in accordance with some embodiments.

FIG. 5AA-5AZ and 5BA-5BI are diagrams of arrangements of cell regions, in accordance with some embodiments.

FIGS. 6A-6F are diagrams of arrangements of cell regions, in accordance with some embodiments.

FIGS. 7A-7B are cross-sectional views, in accordance with some embodiments.

FIGS. 8-9 are flowcharts of corresponding methods, in accordance with some embodiments.

FIG. 10 is a block diagram of an electronic design automation (EDA) system in accordance with some embodiments.

FIG. 11 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

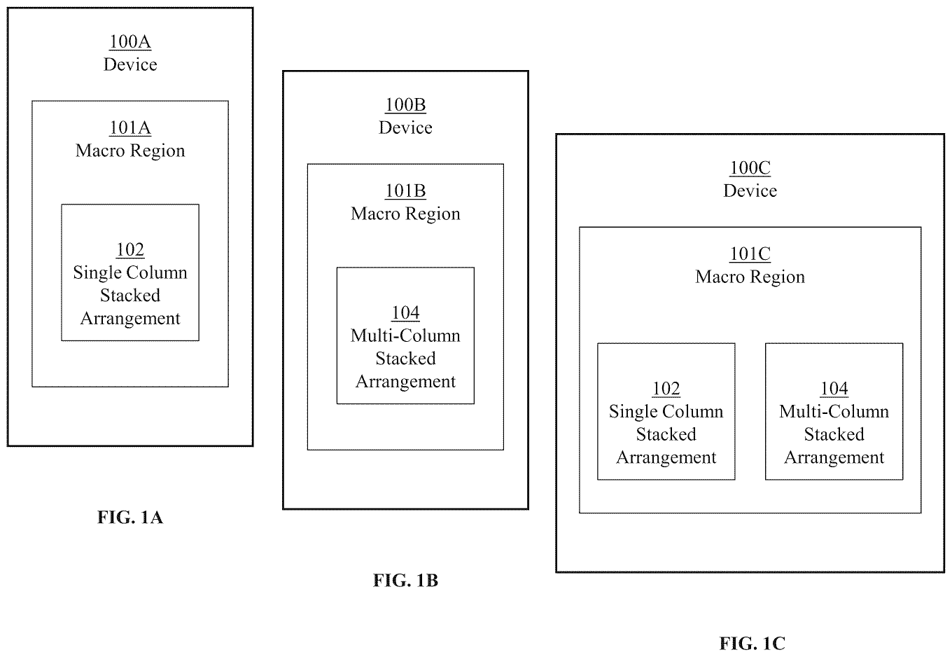

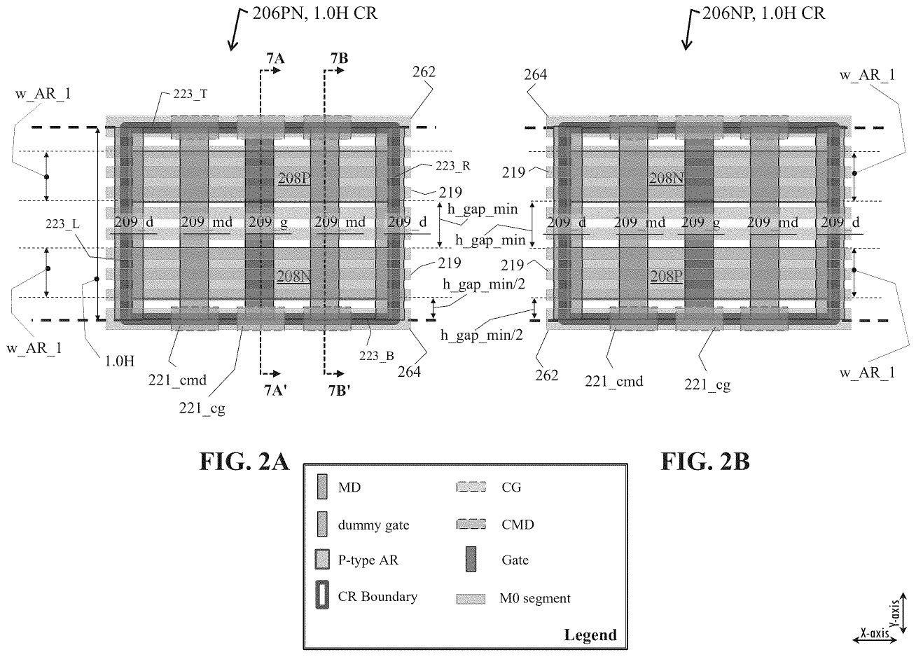

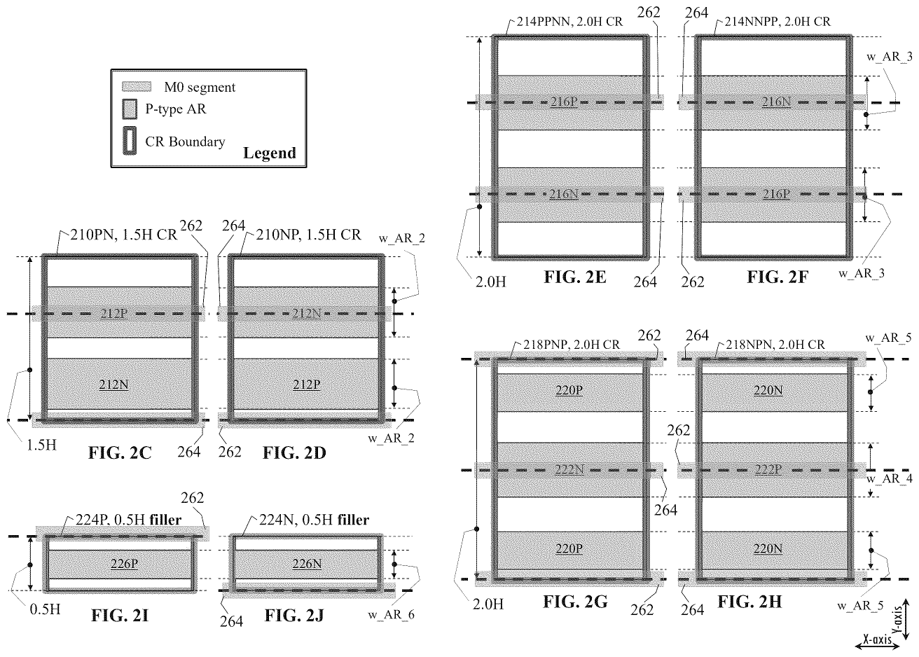

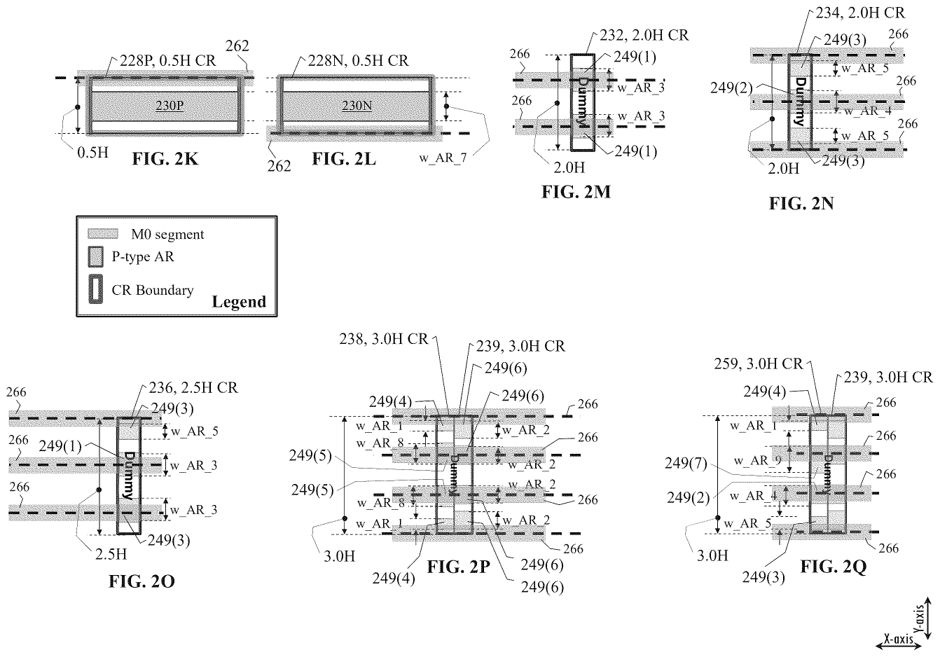

In some embodiments, a library of standard cell regions is comprised of a first subset of the library having members which are standard CMOS cell regions and a second subset of the library having members which are standard non-CMOS standard cell regions. For example, cell regions 206PN, 206NP, 210PN, 210NP, 214PPNN, 214NNPP and 218PNP of corresponding FIGS. 2A-2L, and dummy CRs 232, 234, 236, 238, 239 and 259 of corresponding FIGS. 2M-2Q represent standard CMOS cell regions of such a library whereas each of filler cell regions 224P and 224N of corresponding FIGS. 2I-2J and cell regions 228P and 228N of corresponding FIGS. 2K-2L represent standard non-CMOS cell regions. At least some of the present embodiments provide a library of standard CMOS cell regions, e.g., FIGS. 2A-2H and 2M-2Q, and standard non-CMOS cell regions (where the latter includes half-height non-CMOS standard cell regions, e.g., FIGS. 2I-2J and 2K-2L). Among other things, single column stacked arrangements and/or multi-column stacked arrangements based on a library of standard CMOS cell regions and standard non-CMOS cell regions (the latter including half-height non-CMOS standard cell regions) exhibit increased transistor densities as compared to other approaches that have a library of only standard CMOS cell regions; accordingly, a macro region (see discussion of FIGS. 1A-1C) which includes such embodiments consumes a smaller area, is faster, consumes less power, exhibits improved placement flexibility and/or improved pin accessibility as compared to the another approach.

In some embodiments, a semiconductor device includes: a semiconductor device includes: active regions (ARs) extending in a first direction and correspondingly configured with a first dopant type (first-type AR) or a second dopant type (second-type AR); gate segments and isolation dummy gate (IDG) segments extending in a perpendicular second direction and being over one or more of the ARs; and in a first metallization (M_1st) layer, M_1st segments extending in the first direction, the M_1st segments configured for a reference voltage or routing signals; cell regions including complementary cell regions and non-complementary cell regions; wherein each of the complementary cell regions including at least one of the first-type ARs and at least one of the second-type ARs; wherein each of the non-complementary cell regions including one of the first-type ARs or the second-type ARs and being free of including another of the second-type ARs or the first-type ARs; wherein, relative to the first direction, left and right boundaries of each cell region being corresponding first and second ones of the IDG segments; and wherein, relative to the second direction: top and bottom boundaries of each of the cell regions being proximal to or overlapping of corresponding ones of the M_1st segments; the complementary cell regions having a height of at least about one unit, and the non-complementary cell regions having a height of about one-half unit; and a first one of the non-complementary cell regions being arranged one of above or under a first one of the complementary cell regions.

FIGS. 1A-1C are block diagrams of corresponding devices 100A, 100B and 100C, in accordance with some embodiments.

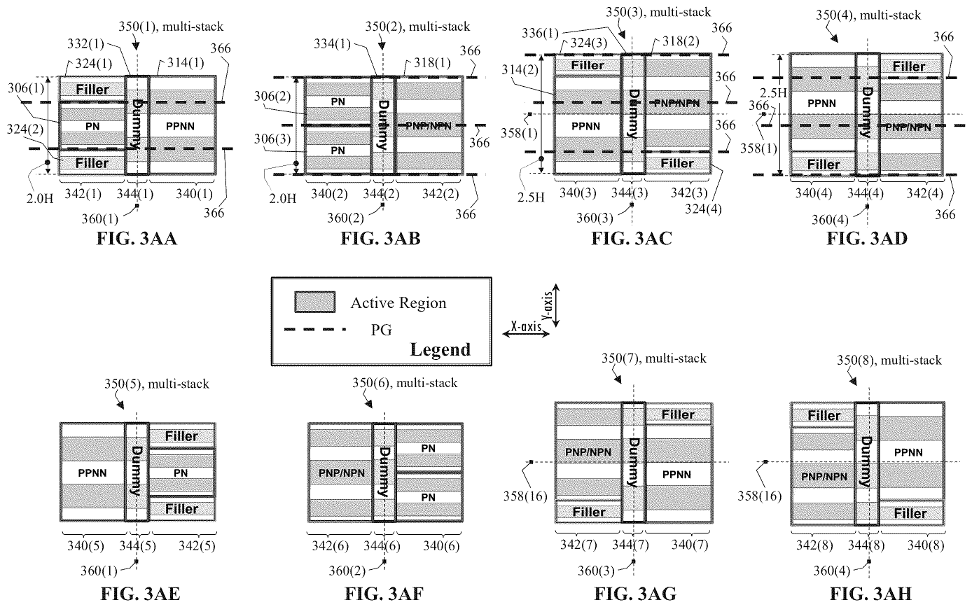

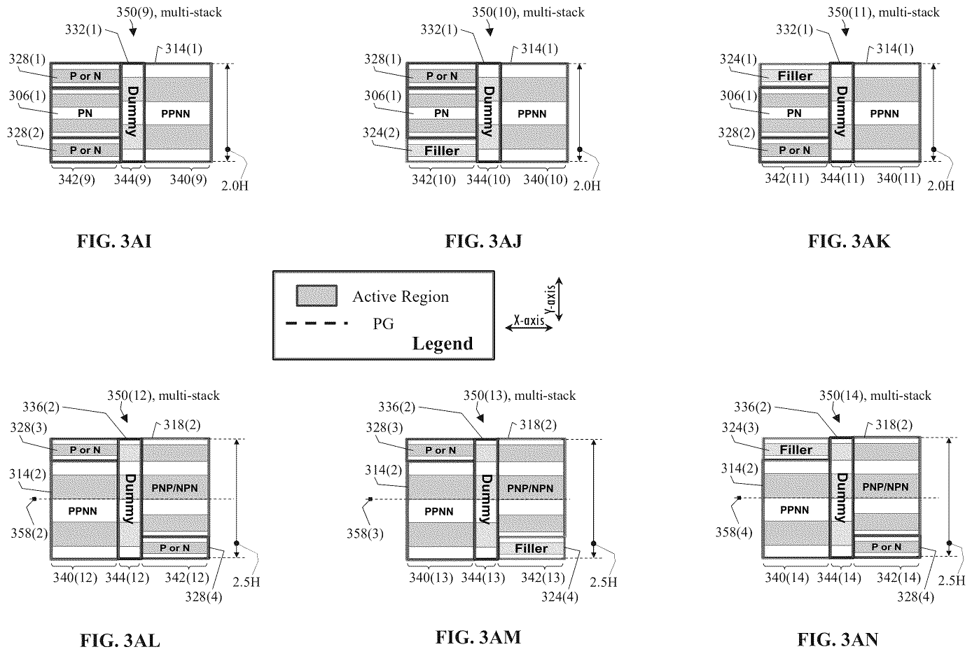

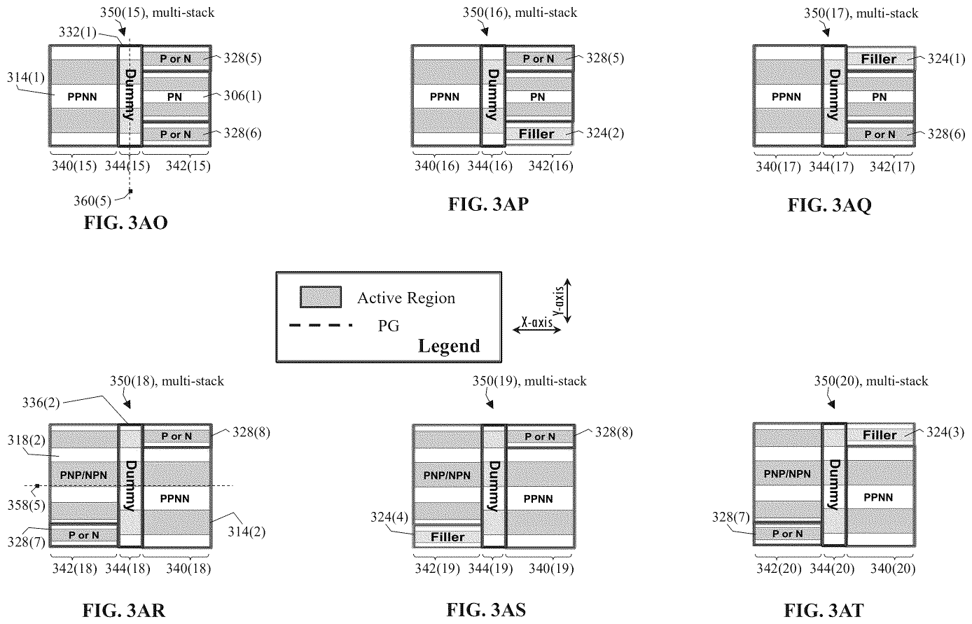

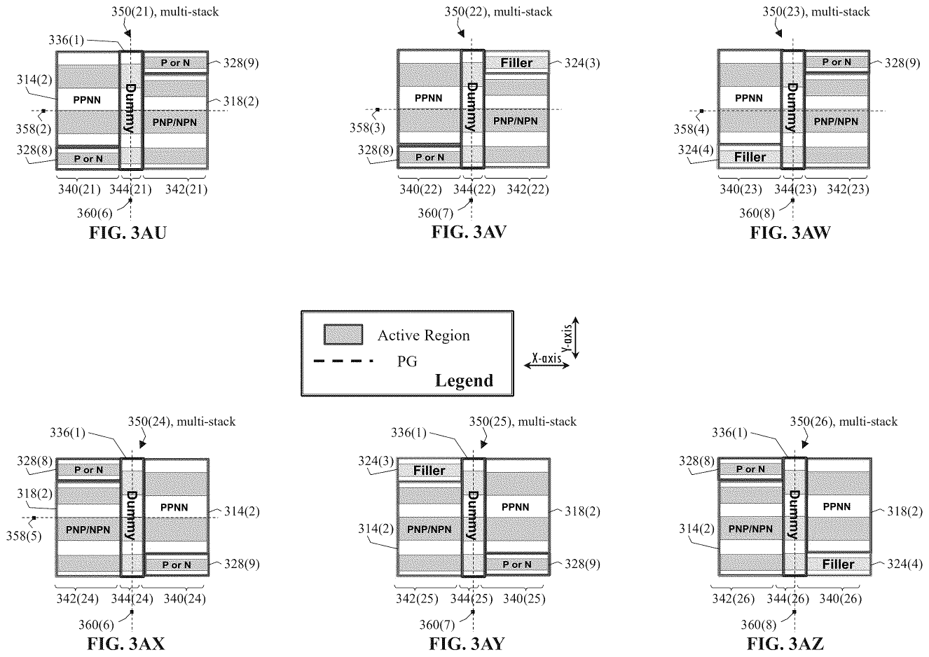

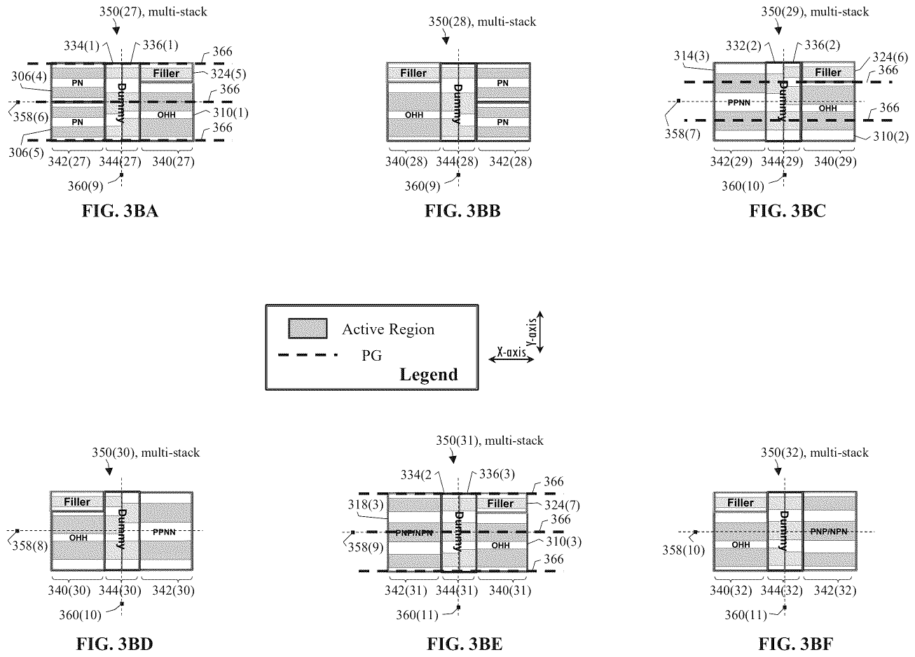

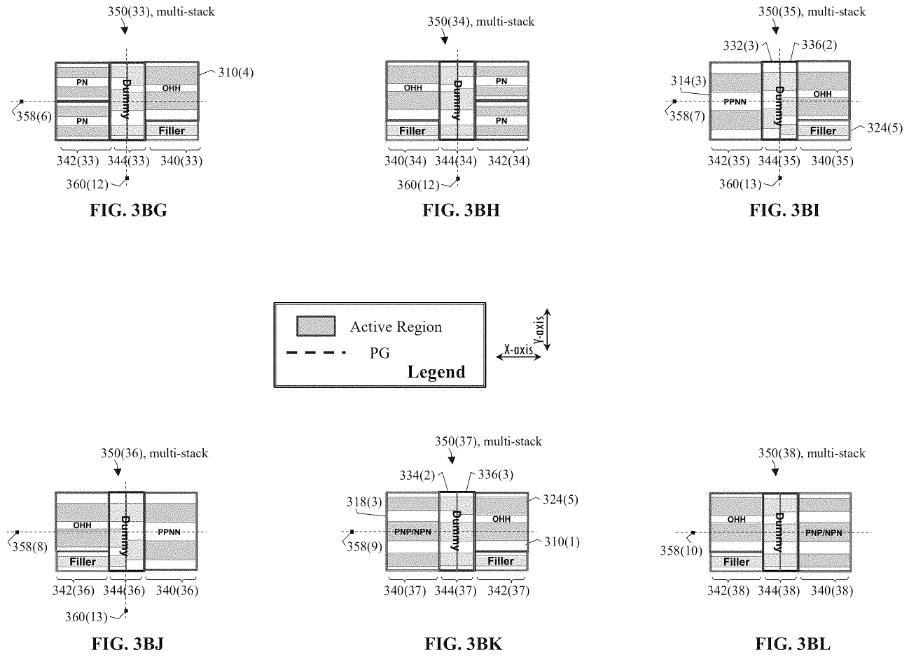

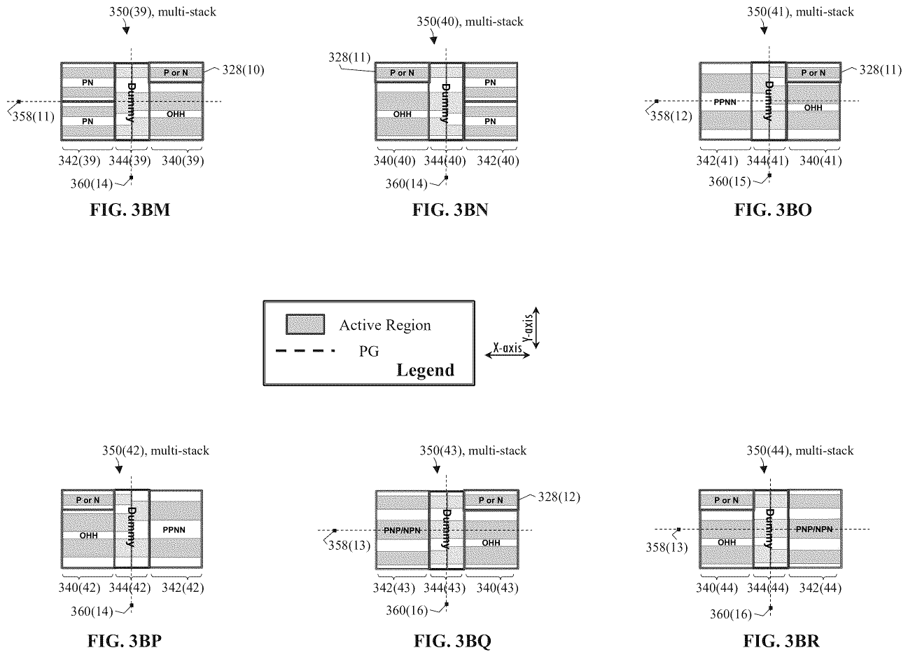

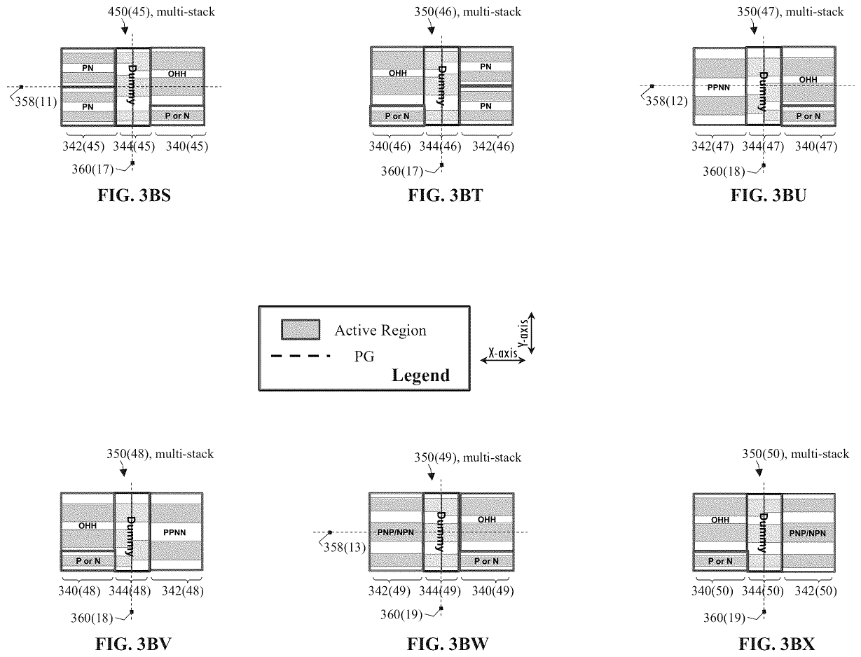

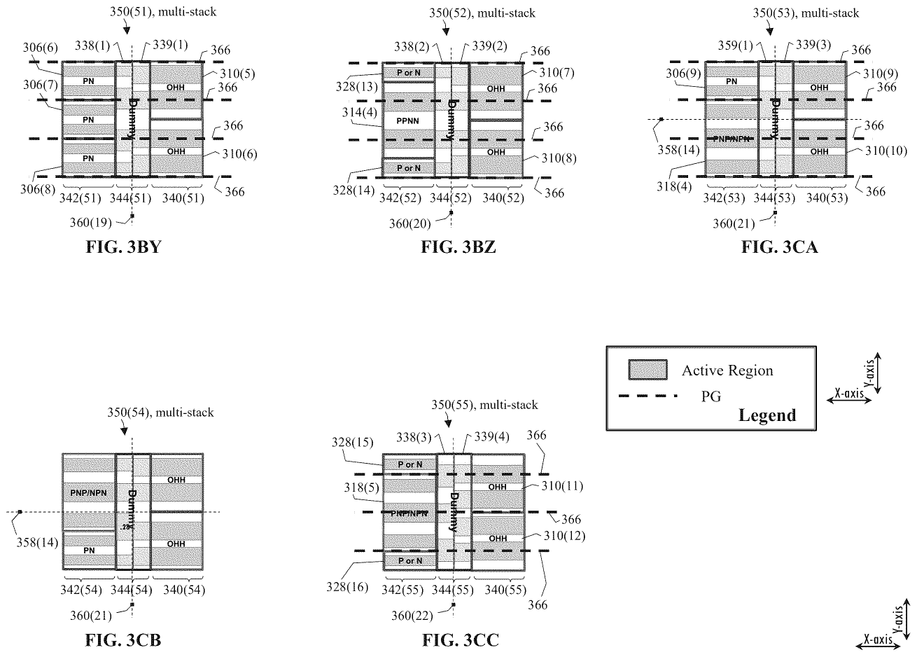

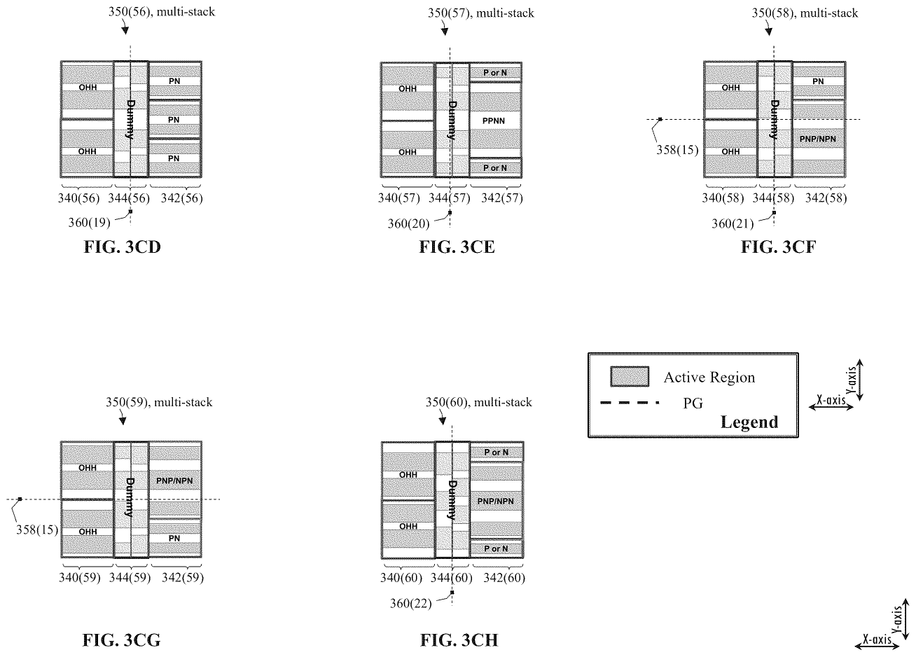

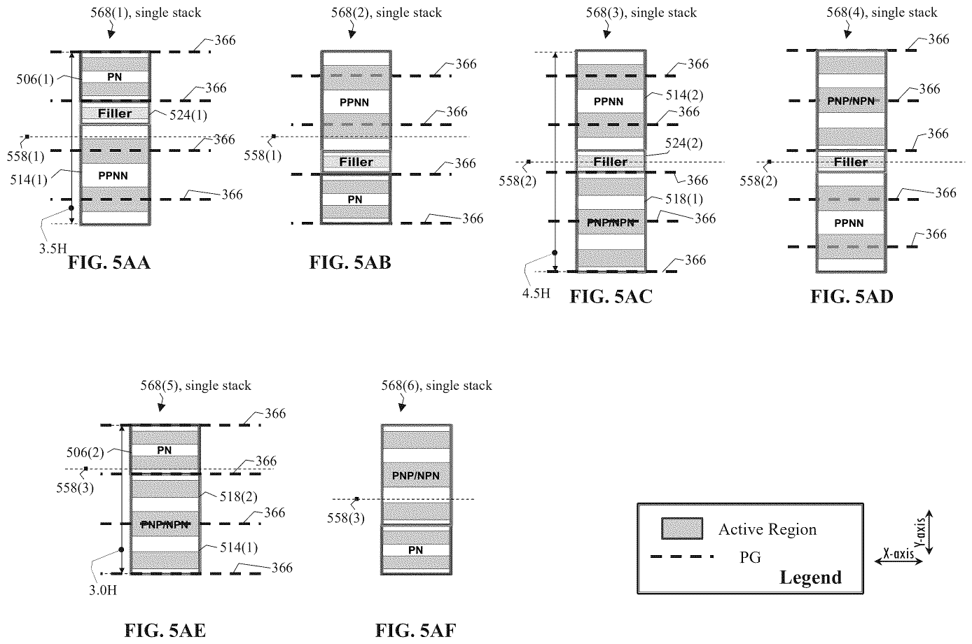

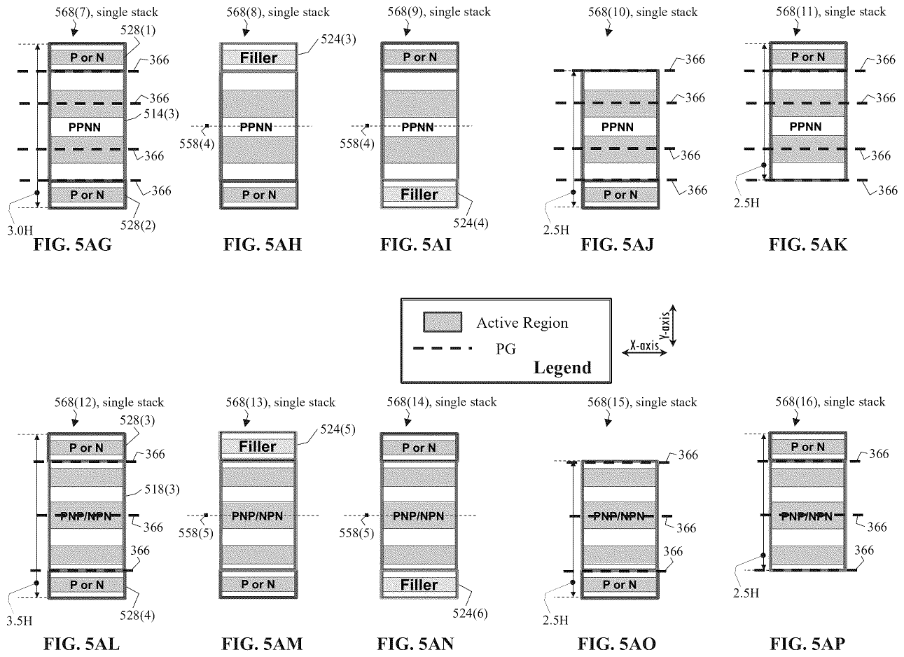

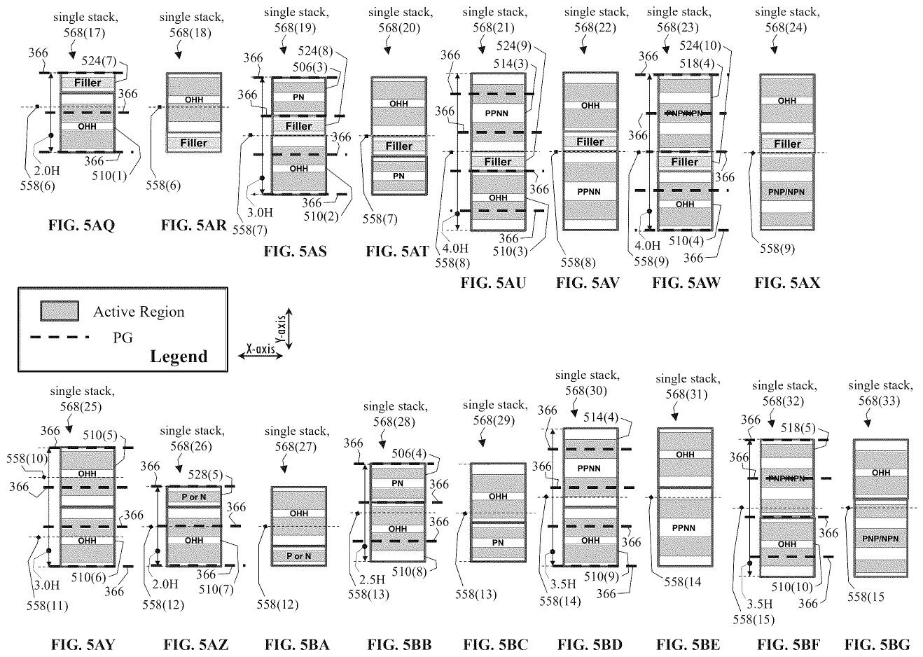

Each of devices 100A-100C is an example of an integrated circuit (IC). In some embodiments, each of devices 100A-100C is referred to as a semiconductor device. Devices 100A, 100B and 100C correspondingly include macro regions 101A, 101B and 101C. Macro region 101A of FIG. 1A includes an arrangement 102 of cell regions stacked on each other in a single column arrangement (e.g., FIG. 5AA-5AZ and 5BA-5BI, or the like). That is, i.e., macro region 101A of FIG. 1A includes a single column stacked arrangement 102 of cell regions. Macro region 101B of FIG. 1B includes an arrangement 104 of cell regions stacked on each other in a multi column arrangement 104 of cell regions (e.g., FIG. 3AA-3AZ, 3BA-3BZ, 3CA-3CH, 4AA-4AZ, 4BA-4BZ and 4CA-4CH, or the like). That is, macro region 101B of FIG. 1B includes a multi-column stacked arrangement 104 of cell regions. Macro region 101C includes single column stacked arrangement 102 and multi-column stacked arrangement 104.

In some embodiments, one or more cell regions in each of single column stacked arrangement 102 and multi-column stacked arrangement 104 include one or more active devices, passive devices, or the like. Examples of active devices or active elements include, but are not limited to, transistors, diodes, or the like. Examples of passive elements include, but are not limited to, capacitors, inductors, fuses, resistors, or the like.

In some embodiments, macro regions 101A and/or 101B and/or 101C, e.g., correspondingly single column stacked arrangement 102 and multi-column stacked arrangement 104, are comprised of one or more instances of a functional cell region. In such embodiments, macro region 101A is configured to provide/execute a given computational function which is comprised of less complicated functions provided correspondingly by the one or more instances of cell regions, e.g., including the cell regions in single column stacked arrangement 104. In some embodiments, one or more instances of such cell regions represent intercoupled building blocks which comprise macro region 101A. In some embodiments, macro regions 101A and/or 101B and/or 101C, e.g., correspondingly single column stacked arrangement 102 and multi-column stacked arrangement 104, are further comprised of one or more dummy cell regions (e.g., FIGS. 2M-2Q).

In some embodiments, each of macro regions 101A-101C is understood in the context of an analogy to the architectural hierarchy of modular programming, in which subroutines/procedures are called by a main program (or by other subroutines) to carry out a given computational function. In this context, devices 100A-100C correspondingly use macro regions 101A-101 to perform one or more given functions. Accordingly, in this context and in terms of architectural hierarchy, each of devices 100A-100C is analogous to the main program and each of macro regions 101A-101C is analogous to subroutines/procedures. In some embodiments, each of macro regions 101A-101C is a soft macro. In some embodiments, each of macro regions 101A-101C is a hard macro. In some embodiments, each of macro regions 101A-101C is a soft macro which is described digitally in register-transfer level (RTL) code. In some embodiments, synthesis, placement, and routing have yet to have been performed on each of macro regions 101A-101C such that the corresponding soft macro can be synthesized, placed, and routed for a variety of process technology nodes. In some embodiments, each of macro regions 101A-101C is a hard macro which is described digitally in a binary file format (e.g., Graphic Database System II (GDSII) stream format), where the binary file format represents planar geometric shapes, text labels, other information, and the like of one or more layouts correspondingly of each of macro regions 101A-101C in hierarchical form. In some embodiments, a binary file format is referred to as a non-text file format. In some embodiments, synthesis, placement, and routing have been performed on macro region 101 such that the hard macro is specific to a particular process technology node.

In some embodiments, examples of functions provided by a macro region (e.g., macro region 101A, 101B and/or 101C) include a memory, a power grid, a clock tree, an adder, a phase-locked loop (PLL), a delay-locked loop (DLL), a flip-flop, a shift register, an analog-to-digital converter (ADC), a digital-to-analog converter (DAC), interfaces, higher-level Boolean logic, or the like. Example memories include a static random access memory (SRAM), a dynamic RAM (DRAM), a resistive RAM, a magnetoresistive RAM (MRAM), a read only memory (ROM), or the like. An example of a flip-flop is a scan-insertion type of D flip-flop (SDFQ), or the like. In some embodiments, examples of functions provided by functional cell regions (e.g., functional cell region 102) include an inverter, a tri-state inverter, a buffer, a latch a multiplexer (MUX), a driver, a latch, delay, a half adder, a full adder, a compressor, lower-level Boolean logic, or the like, Examples of lower-level Boolean logic include AND, OR, NAND, NOR, XOR, INV, AND-OR-Invert (AOI), OR-AND-Invert (OAI), or the like.,

Cell regions in each of macro regions 101A-101C include corresponding segments in one or more metallization layers. Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In such embodiments, boundaries of functional cell region 102 are described in terms of the first and second directions.

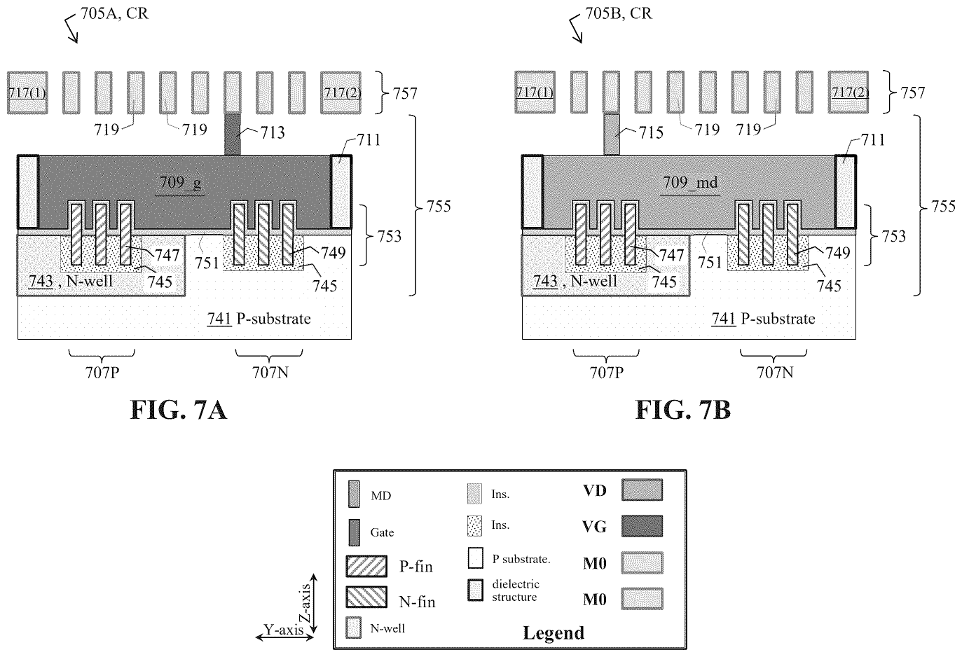

In some embodiments, each of the cell regions in each of macro regions 101A-101C is comprised of a transistor-components layer (e.g., FIG. 7) having circuitry components, e.g., transistors, formed thereon in a front-end-of-line (FEOL) fabrication. Correspondingly in each of the cell regions in each of macro regions 101A-101C, above and/or below an active region (AR) layer (e.g., FIG. 7), various metal layers are interleaved with corresponding interconnection layers are 306(1 over and/or under insulating layers in a back end of line (BEOL) fabrication. The BEOL fabrication provides a power network and/or routing for circuitry of devices 100A-100C, correspondingly including macro regions 101A-101C and the cell regions correspondingly included therein.

FIGS. 2A-2Q are diagrams of corresponding cell regions, in accordance with some embodiments.

As discussed below, the cell regions of FIGS. 2A-2Q are variously included in instances of single column stacked arrangement 102 (e.g., FIG. 5AA-5BI, or the like) and in instances of multi-column stacked arrangement 104 (e.g., FIG. 3AA-4CH, or the like). More particularly, FIGS. 2A-2B diagrams of corresponding cell regions 206PN and 206NP, in accordance with some embodiments. In some embodiments, FIGS. 2A-2Q are layout diagrams.

Cell regions 206PN and 206NP are examples of one or more cell regions included in corresponding instances of stacked arrangement 102 and/or multi-column stacked arrangement 104. In FIG. 2A: section line 7A-7A′ corresponds to cross-section 705A of FIG. 7A; and section line 7B-7B′ corresponds to cross-section 705B of FIG. 7B.

In FIGS. 2A-2B, and in other layout diagrams disclosed herein, the first and second directions are assumed to be parallel correspondingly to the X-axis and the Y-axis. In some embodiments, the first and second directions are assumed to have orientations other than being parallel correspondingly to the X-axis and the Y-axis. In FIGS. 2A-2B, and in other layout diagrams disclosed herein, rows extend parallel to the X-axis.

A transistor-based device is comprised of cell regions which are representable by layout diagrams of which the layout diagram of FIG. 2A, and other layout diagrams disclosed herein, are examples. Regarding transistors, examples which comprise a transistor-based device include field effect transistors (FETs). An example of an architecture for a transistor-based device is complementary metal-oxide-semiconductor (CMOS) architecture. In a CMOS architecture, the FETs include negative-channel metal-oxide semiconductor (NMOS) FETs (NFETs) and positive-channel metal-oxide semiconductor (PMOS) FETS (PFETs). Regarding CMOS architecture, examples of FET transistor architectures include planar field-effect transistor (FET) transistor architecture, finFET transistor architecture, gate-all-around FET (GAAFET) transistor architectures, or the like. Examples of the GAAFET transistor architecture include as nanowire transistor architecture, nanosheet transistor architecture, forksheet transistor architecture, or the like.

Structures in a transistor-based device are represented by patterns (also known as shapes) in the layout diagram. For simplicity of discussion, elements in the layout diagrams of FIGS. 2A-2B and other layout diagrams disclosed herein will be referred to as if they are structures rather than patterns. For example, shapes in FIGS. 2A-2B representing instances of active regions are referred to as active regions per se rather than as active region shapes.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. The layout diagrams disclosed herein are examples of layout diagrams in which selected layers and/or selected elements of depicted given layers, have been omitted.

Depending upon the numbering convention of the corresponding process technology node by which a device is to be fabricated, on a front side of the device the first layer metallization is either metallization layer zero (MET0) or metallization layer one (MET1), and correspondingly a first interconnection layer on the first metallization layer is either interconnection layer zero (VIA0) or interconnection layer one (VIA1). In such embodiments, again depending upon the numbering convention of the corresponding process technology node, on a back side (not shown) of the device, the first buried metallization layer is either buried metallization layer zero (BMET0) or buried metallization layer one (BMET1), and correspondingly a first buried interconnection layer under the first metallization layer is either interconnection layer zero (VIA0) or interconnection layer one (VIA1).

In general, regarding the figures disclosed herein (unless noted otherwise), the following nomenclature is adopted regarding the front side of a device: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

In general, regarding the figures disclosed herein (unless noted otherwise), or the like, the following nomenclature is adopted regarding the back side of a device: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 (BM0) segments. Via structures in layer BVIA0 are referred to as BV0 structures. Metallization segments in layer BMET1 are referred to as buried M1 (BM1) segments. Via structures in layer BVIA1 are referred to as BV1 structures. Metallization segments in layer BMET2 are referred to as buried M2 (BM2) segments.

In FIG. 2A, cell region (CR) 206PN includes: a positive-type (P-type) active region 208P that extends substantially parallel to the X-axis and is used for corresponding PFETs; a negative-type (N-type) active region 208N that extends substantially parallel to the X-axis and is used for corresponding NFETs; a gate segment 209_g that extends substantially parallel to the Y-axis; dummy gate segments 209_d that extend substantially parallel to the Y-axis; metal-to-source/drain contact (MD) structures 209_md that extend substantially parallel to the Y-axis; cut-gate (CG) shapes 221_cg that extend parallel to the X-axis; and cut-MD (CMD) shapes 221_cmd that extend parallel to the X-axis. Relative to the Y-axis, active region 208P is above active region 208N, i.e., active region 208N is below active region 208P.

Gate segment 209_g, dummy segments 209_d and MD structures 209_md are separated from each other by a center-to-center (midline-to-midline) distance of about 1.0*S relative to the X-axis, i.e., have a pitch of about 1.0*S, where S is a uniform distance for the corresponding semiconductor process technology node. Gate segment 209_g is left-adjacent to a first instance of MD structure 209_md and right-adjacent to a second instance of MD structure 209_md. Gate segment 209_g is separated from each of the first and second instances of MD structure 209_md by a distance about 1.0*S. A first instance of dummy gate segment 209_d is left-adjacent to the first instance of MD structure 209_md is separated therefrom by a distance about 1.0*S. A second instance of dummy gate segment 209_d is right-adjacent to the second instance of MD structure 209_md is separated therefrom by a distance about 1.0*S.

In some embodiments, the term “adjacent” is understood as follows: for a hypothetical structure referred to as a widget, relative to a given direction (e.g., the X-axis), a first widget and second widget are adjacent to each other where the first and second widgets are free from having a third widget therebetween. In some embodiments, in a context of understanding the term “adjacent” as applied to gate segment 209_g, dummy segment 209_d or MD structure 209_md, each of gate segment 209_g, dummy segment 209_d or MD structure 209_md is an example of a widget. In such embodiments, S represents the minimum distance between any two adjacent instances gate segment 209_g, dummy segments 209_d or MD structures 209_md that can be manufactured/achieved by the corresponding semiconductor process technology node.

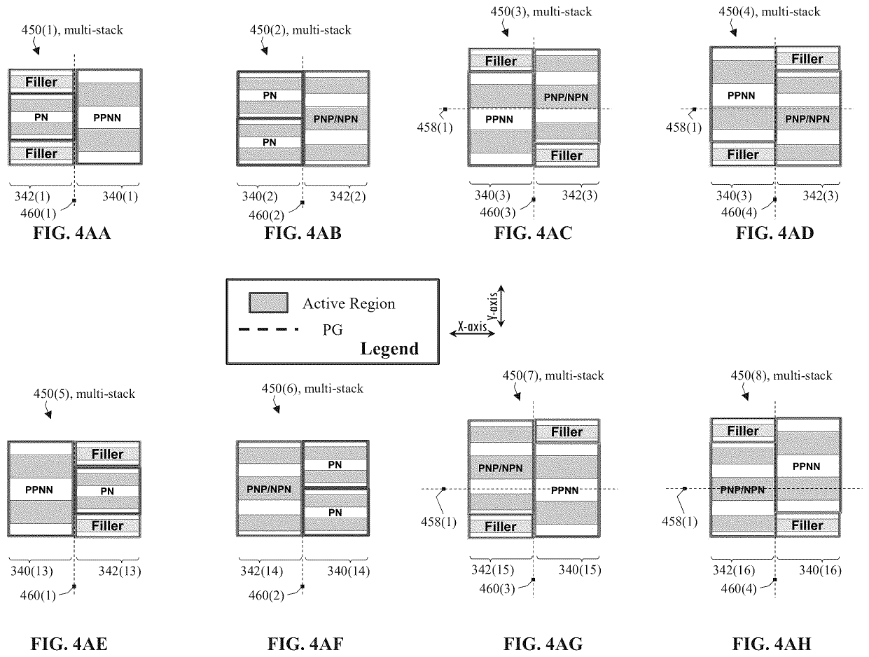

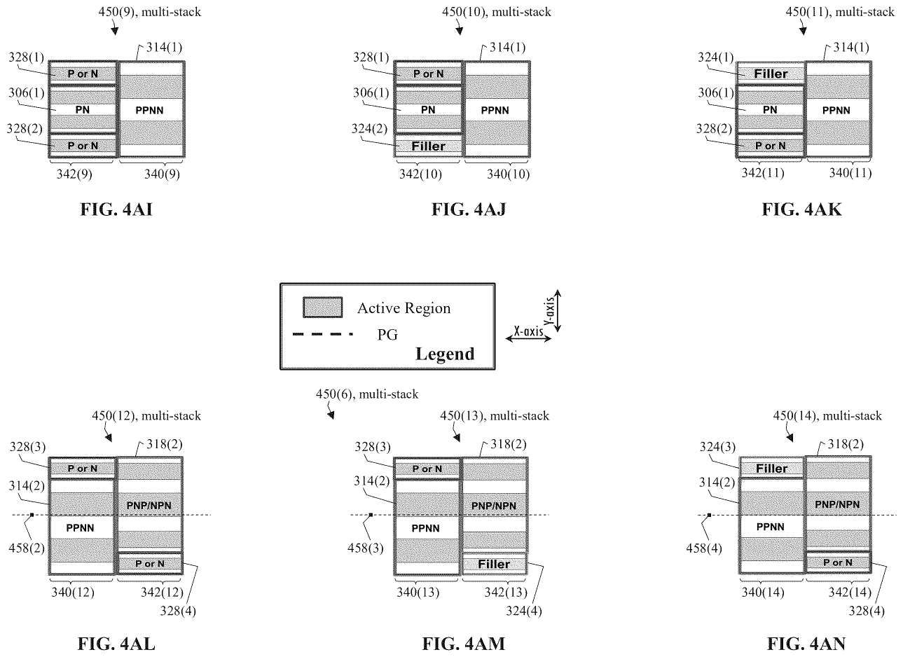

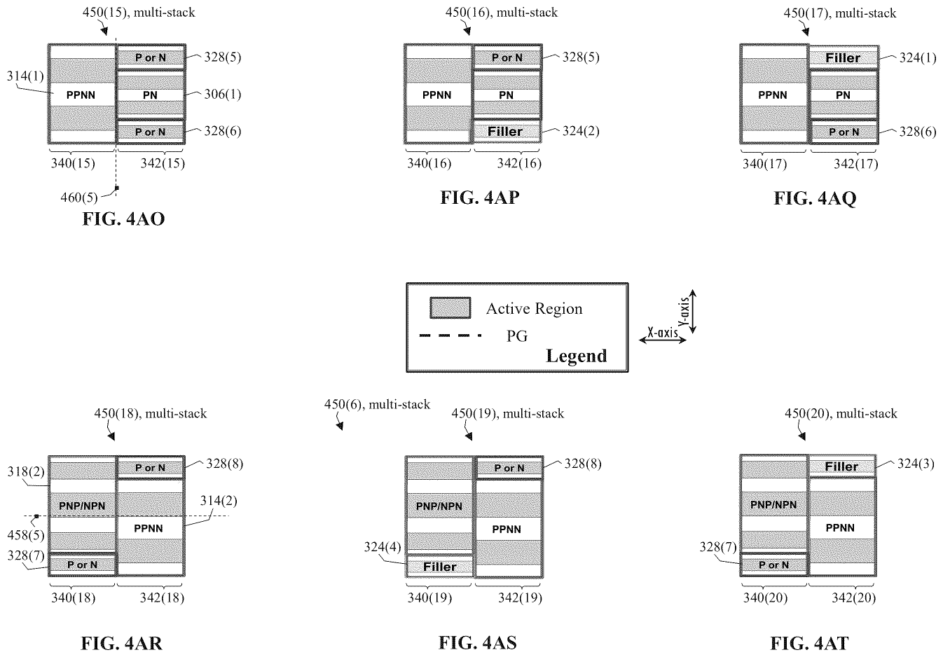

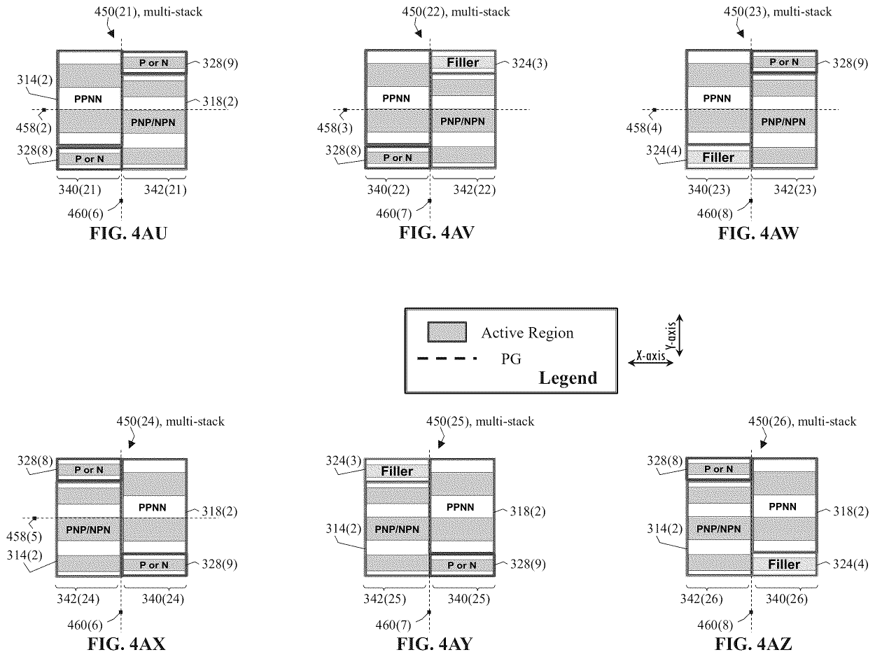

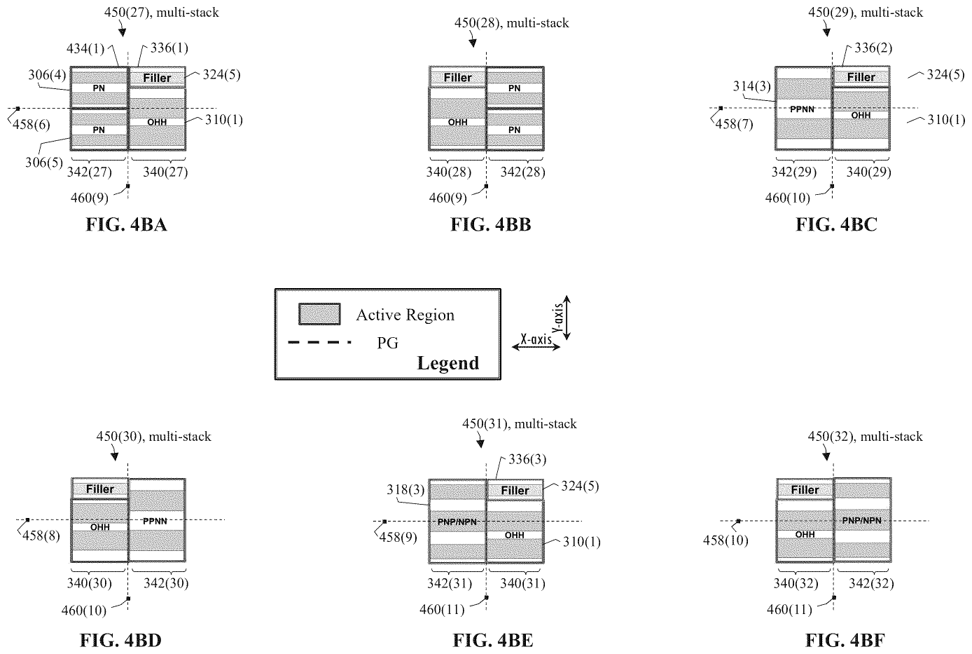

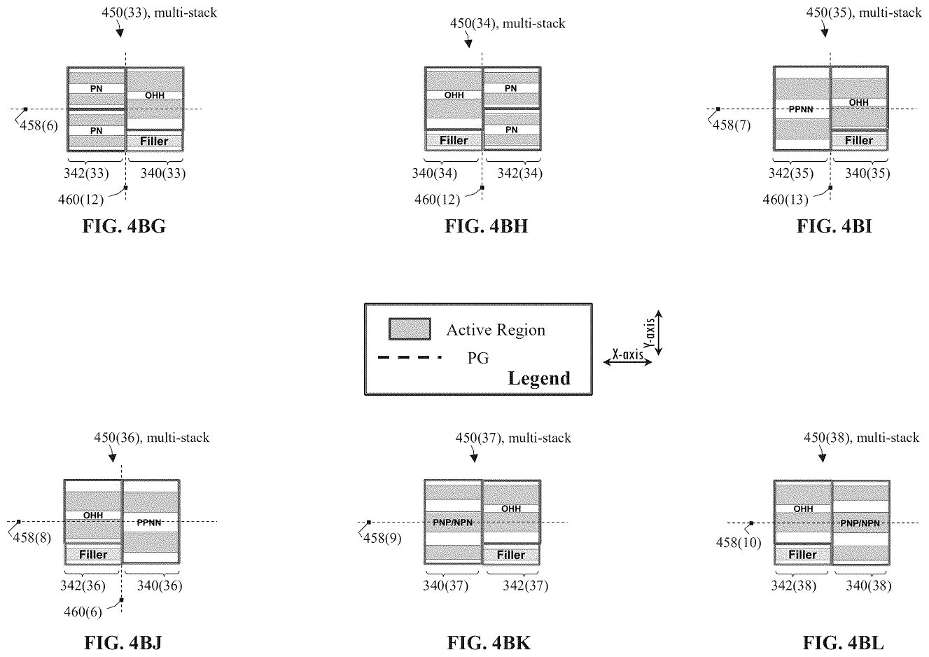

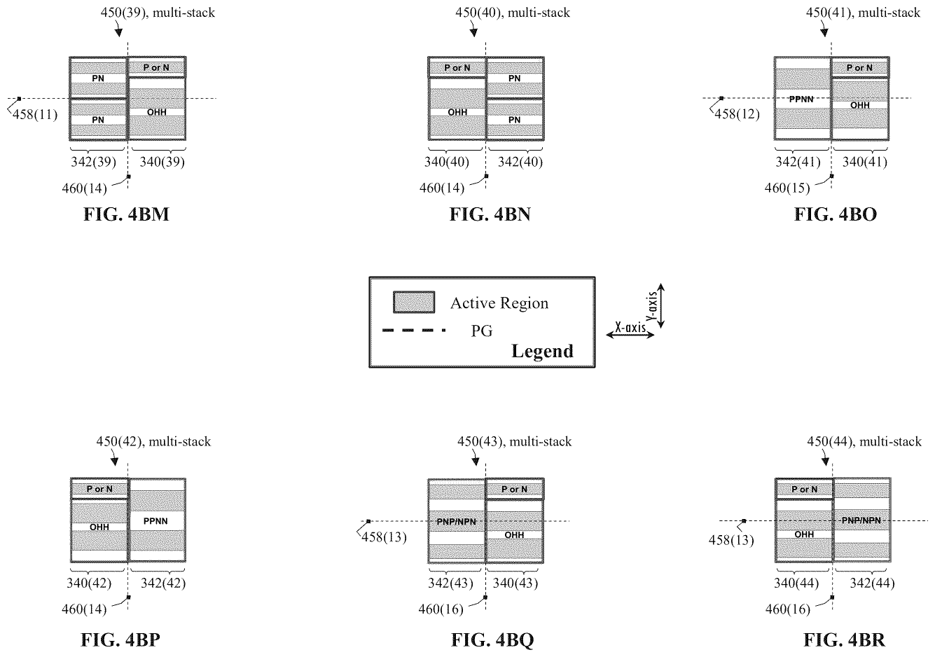

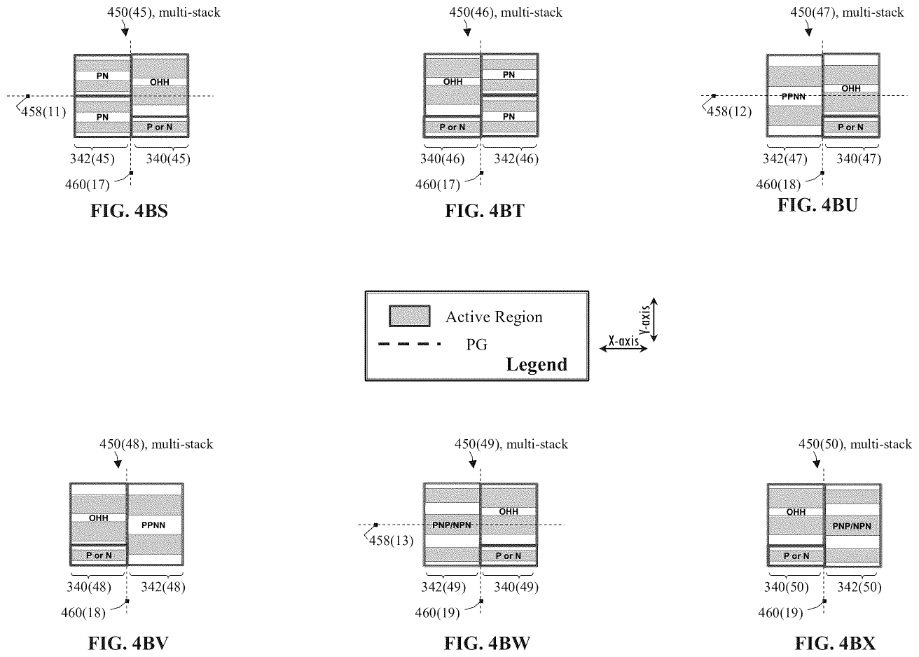

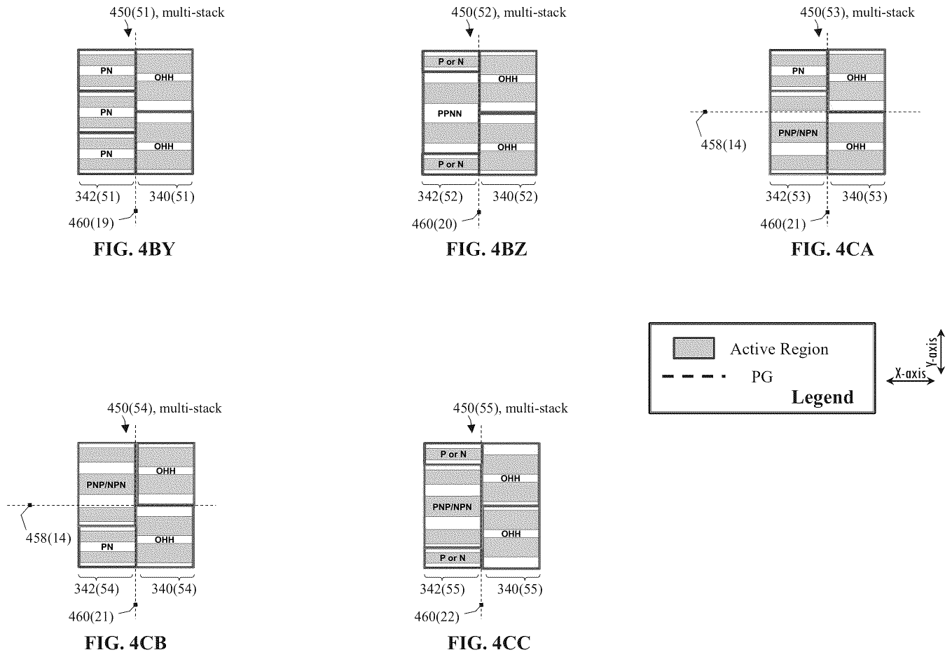

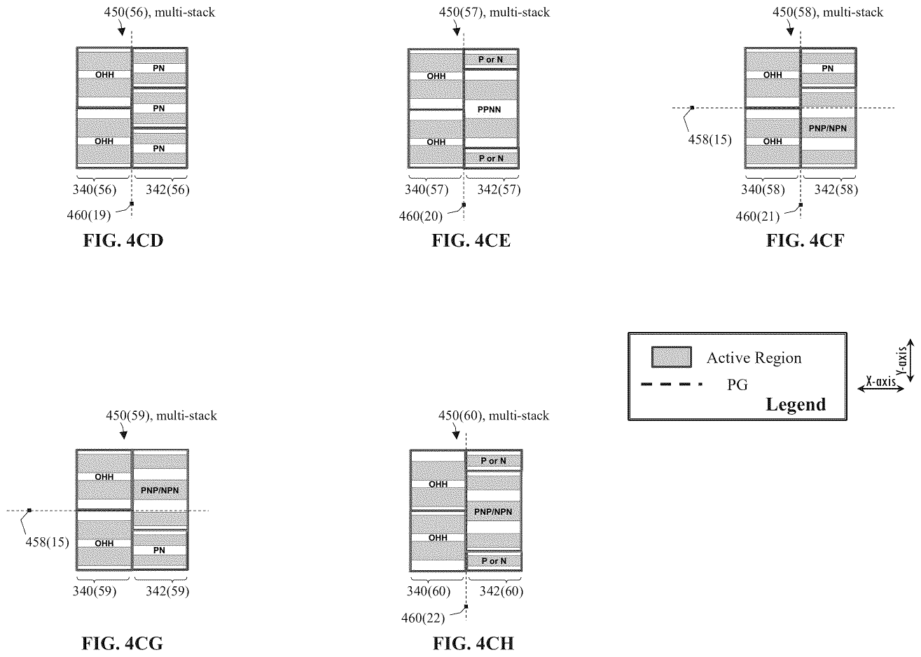

In some embodiments, the uniform distance S represents one-half of one contacted poly pitch (CPP) for the corresponding semiconductor process technology node such that S=0.5*CPP. Here, the word ‘poly’ in the term CPP does not necessarily imply that the gate structures in semiconductor devices based correspondingly on FIG. 4 are to be formed of polysilicon but instead represents a historical convenience, i.e., because gate structures in ICs manufactured according to a predecessor semiconductor process technology node often were formed of polysilicon.

In some embodiments, a dummy gate segment (e.g., 209_d) is a gate segment that is not coupled to a voltage source. In some embodiments, a dummy gate segment is a gate segment that is not coupled to a reference voltage source, e.g., VDD, VSS or the like. In some embodiments, a dummy gate segment is an isolation dummy gate (IDG) structure. In some embodiments, an isolation dummy gate (IDG) structure is a dielectric structure that includes one or more dielectric materials and functions as an electrical isolation structure. Accordingly, an IDG structure is not a structure that is electrically conductive and thus does not function, e.g., as an active gate of a transistor. An IDG structure includes one or more dielectric materials and functions as an electrical isolation structure. In some embodiments, an IDG structure is based on a gate segment as a precursor. In some embodiments, an IDG structure is based on a dummy gate structure. In some embodiments, a dummy gate structure includes a gate segment that is decoupled so as to not function, e.g., as a gate of a transistor, a gate-insulator layer, (optionally) one or more spacers, or the like. In some embodiments, an IDG structure is formed by first forming a gate segment e.g., which is included in a dummy gate structure, sacrificing/removing (e.g., etching) the gate segment to form a trench, (optionally) removing a portion of a substrate that previously had been under or over or around the gate segment to deepen the trench, and then filling the trench with one or more dielectric materials such that the physical dimensions of the resultant electrical isolation structure, i.e., the IDG, are similar to the dimensions of the gate segment which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a continuous polysilicon on oxide diffusion (OD) edge structure, and is referred to as a CPODE structure.

Each of gate segment 209_g, dummy gate segments 209_d and MD structures 209_md correspondingly overlap active regions 208N and 208P. Each of gate segment 209_g, dummy gate segments 209_d and MD structures 209_md is coupled to a corresponding voltage source, e.g., VDD, VSS or a voltage between VDD and VSS. Where a part of one of MD structures 214 overlaps an active region (e.g., active regions 208N and 208P), the correspondingly overlapped sub-region of the active region is relatively more heavily doped to serve as a source/drain (S/D) region of a corresponding transistor. Where a part of gate segment 209_g overlaps an active region (e.g., active regions 208N and 208P), the correspondingly overlapped sub-region of the active region is configured to serve as a channel region of a corresponding transistor. As such, the gate-segment-overlapped sub-region of the active region is free from being relatively more heavily doped as compared, e.g., to an S/D region.

In some embodiments, each instance of CG shape 221_cg represents a dielectric structure that replaces the portion of the corresponding gate segment which is overlapped by the instance of CG shape 221_cg. In some embodiments, dielectric structures 221_cg are formed of a dielectric material (e.g., a dielectric material) that is different than interstitial material (not shown) which fills interstitial space around dielectric structures 221_cg, e.g., the interstitial material is another dielectric material. In some embodiments, dielectric structures 221_cg are formed of a nitride material whereas the interstitial material is an oxide, or vice versa. In some embodiments, dielectric structures 221_cg are formed of a material that is the same as the interstitial material such that dielectric structures 221_cg are more easily discerned (or identified) in the corresponding layout diagram than in the device manufactured according to the layout diagram. In some embodiments, dielectric structures 221_cg are referred to as cut-gate (CG) structures.

In some embodiments, dielectric structures 221_cg are described as byproducts of trimming the lengths of the precursors of gate segments, e.g., 210(1) and 210(2). Relative to the Y-axis, a height of each of dielectric structures 221_cg varies in order to achieve an overhang distance D_G_ovhmin for the corresponding end of the corresponding gate segment as set by one or more design rules of a corresponding semiconductor process technology node. In general, relative to the Y-axis, the width of dielectric structures 221_cg is inversely proportional to the width of the corresponding AR-portion. Width w_CG_min is a minimum width for such dielectric structures (e.g., 221_cg) as set by one or more design rules of a corresponding semiconductor process technology node.

In some embodiments, each instance of CMD shape 221_cmd represents a dielectric structure that replaces the portion of the corresponding MD structure which is overlapped by the instance of CMD shape 221_cmd. In some embodiments, dielectric structures 221_cmd are formed of a dielectric material (e.g., an oxide) that is different than interstitial material (not shown) which fills interstitial space around dielectric structures 221_cmd, e.g., the interstitial material being another dielectric material. In some embodiments, dielectric structures 221_cmd are formed of a nitride material whereas the interstitial material is an oxide, or vice versa. In some embodiments, dielectric structures 221_cmd are formed of a material that is the same as the interstitial material such that dielectric structures 221_cmd are more easily discerned (or identified) in the corresponding layout diagram than in the device manufactured according to the layout diagram. In some embodiments, dielectric structures 221_cmd are referred to as cut-gate (CG) structures.

In some embodiments, dielectric structures 221_cmd are described as byproducts of trimming the lengths of the precursors of MD structures, e.g., 214. Relative to the Y-axis, a height of each of dielectric structures 221_cmd varies in order to achieve an overhang distance D_MD_ovhmin for the corresponding end of the corresponding gate segment as set by one or more design rules of a corresponding semiconductor process technology node. In general, relative to the Y-axis, the width of dielectric structures 221_cmd is inversely proportional to the width of the corresponding AR-portion. Width w_CMD_min is a minimum width for dielectric such structures (e.g., 221_cmd) as set by one or more design rules of a corresponding semiconductor process technology node.

Cell region 206PN is substantially rectangular. In terms of top and bottom as defined relative to the Y-axis, cell region 206PN has top 223_T and bottom 223_B boundaries that extend substantially parallel to the X-axis and thus are substantially parallel to each other. In terms of left and right as defined relative to the X-axis, cell region 206PN has left 223_L and right 223_R boundaries that: extend substantially parallel to the Y-axis and thus are substantially parallel to each other; and are aligned to corresponding instances of dummy gate segment 209_d. Each of active regions 208N and 208P: is substantially rectangular; substantially extends from the left 223_L boundary to the right 223_R boundary of cell region 206PN such that active regions 208N and 208P have substantially the same length relative to the X-axis; and have substantially the same width relative to the Y-axis. In some embodiments, identifying boundaries of cell regions facilitates identifying one or more stacked arrangements of cell regions. In some embodiments, identifying one or more stacked arrangements of cell regions facilitates identifying a macro region which includes the identified one or more stacked arrangements.

In FIG. 2A, again, the first metallization layer is assumed to be MET such that metallization segments therein are referred to as M0 segments. As such, in FIG. 2A, first metallization layer MET0 (see FIGS. 7A-7B) overlies gate segment 209_g, dummy gate segments 209_d and MD structures 209_md. Layer MET0 includes M0 segments. The M0 segments include power grid (PG) segments (M0_PG segments) 262 and 264 and routing (RTE) segments (M0_RTE segments) 219 (see also FIGS. 7A-7B) that are correspondingly aligned to reference alpha tracks (not shown). M0_PG segment 262 is aligned with top boundary 223_T. M0_PG segment 264 is aligned with bottom boundary 223_B. In other words, top boundary 223_T and bottom boundary 223_B of cell region 206PN are overlapped correspondingly by M0_PG segments 262 and 264. In some embodiments, top boundary 223_T and bottom boundary 223_B approximately bisect corresponding M0_PG segments 262 and 264. In some embodiments, top boundary 223_T and bottom boundary 223_B substantially bisect corresponding M0_PG segments 262 and 264. In terms of alignment relative to the Y-axis, each of active regions 208P and 208N is free of being overlapped by an M0_PG segment, e.g., 262 or 264.

Instances of M0_PG segment 264 are configured for a first reference/supply voltage, e.g., VDD; and instances of M0_PG segments 262 are configured for a second reference/supply voltage, e.g., VSS. Instances of the M0_RTE segments (see FIGS. 7A-7B) are configured for corresponding signals. An instance of a VG contact (see FIG. 7A), if present, electrically couples an instance of gate segment 209g to an instance of an M0 segment, e.g., an instance of M0_PG segment 264 or an instance of M0_PG segment 262 or an instance of a M0_RTE segment (see FIG. 7A). An instance of a VD contact (see FIG. 7A), if present, electrically couples an instance of MD structure 209_md to an instance of an M0 segment, e.g., an instance of M0_PG segment 264 or an instance of M0_PG segment 262 or an instance of a M0_RTE segment (see FIGS. 7A-7B). In some embodiments, power is supplied to cell region 206PN or cell region 206NP from the back-side by one or more of BM0 or BM1 power rails and corresponding buried vias (e.g., a BVG contact, a BVD contact, a BV0 structure, or the like).

In some embodiments, each of FIGS. 2A-2B assumes the presence of one or more functional/operative transistors in each of cell regions 206PN and 206NP. In some embodiments, each of FIGS. 2A-2B assumes that each of FIGS. 2A-2B includes one or more functional/operative transistors based on the following: transistor components (e.g., S/D regions, channel regions, or the like) are formed in corresponding active region 224P and/or active region 224N; one or more instances of gate segment 209_g is electrically coupled to one or more of the M0 segments (see FIG. 7B) by one or more instances of a VG contact (see FIG. 7B); and one or more instances of MD structure 209_md is electrically coupled to one or more of the M0 segments (see FIG. 7A) by one or more instances of a VD contact (see FIG. 7A). Accordingly, in some embodiments, FIGS. 2A-2B assume that corresponding cell regions 206PN and 206NP are electrically coupled to one or more of the M0 segments such that one or more transistors included therein are functional/operative. In some embodiments, each of cell regions 206PN and 206NP is referred to as a functioning-transistor type (FT-type) cell region.

M0_PG segments 262-264 have a pitch p_PG. In FIG. 2A, and likewise in other layout diagrams disclosed herein, M0_PG segments 262-264 are shown as phantom (dashed) lines; nevertheless, M0_PG segments 262-264 have a non-zero width relative to the Y-axis. Likewise, M0_rte segments have a non-zero width relative to the Y-axis. In some embodiments, M0_PG segments 262-264 have a width w_PG and M0_rte segments have a smaller width w_rte such that w_rte<w_PG. Between adjacent ones of M0_PG segments 262 and 264, M0_RTE segments (see FIGS. 7A-7B) have a pitch p_rte. Between adjacent ones of the M0_rte segments, the M0_rte segments have pitch p_rte. In some embodiments, p_rte<p_PG.

In some embodiments, a cell region in a semiconductor device based on a layout diagram (e.g., FIG. 2A) is referred to as a fabricated cell region. In some embodiments, top and bottom boundaries of a fabricated cell region (e.g., corresponding to cell region 206PN) are recognizable as intersecting corresponding instances of dielectric structure 221_cg. In some embodiments, top and bottom boundaries of a fabricated cell region (e.g., corresponding to cell region 206PN) are recognizable as intersecting corresponding instances of dielectric structure 221_cmd.

In some embodiments, top and bottom boundaries of a fabricated cap cell (e.g., corresponding to cell region 206PN are recognizable as follows: a first end of gate segment 209_g and first ends of MD structures 209_md are substantially aligned and define a first reference line substantially parallel to the X-axis, the first reference line being at least proximate (if substantially collinear with) top boundary 223_T of cell region 206PN; and a second end of gate segment 209_g and second ends of MD structures 209_md are substantially aligned and define a second reference line substantially parallel to the X-axis, the second reference line being at least proximate (if not substantially collinear with) bottom) boundary 223_B of cell region 206PN. In some embodiments the first and second ends of gate segment 209_g are formed as part of a cut-gate process.

In some embodiments, top and bottom boundaries of a fabricated cell region (e.g., corresponding to cell region 206PN) are recognizable as follows: a CMOS-pair of an N-type active region (e.g., 208N) and adjacent P-type active region (e.g., 208P) which are adjacent in the second direction (e.g., parallel to the Y-axis) are identified in the fabricated cell region; a first reference line is identified in the fabricated cell region, where the first reference line extends in the first direction (e.g., parallel to the X-axis) and is adjacent the upper active region (e.g., 208P) of the CMOS-pair, and where the first reference line intersects the instance of dielectric structure 221_cg and the instances of dielectric structure 221_cmd that are aligned relative to the Y-axis and are adjacent correspondingly to the first ends of gate segment 209_g and MD structures 209_md; a second reference line is identified in the fabricated cell region, where the second reference line extends in the first direction and is adjacent the lower active region (e.g., 208N) of the CMOS-pair, and where the second reference line intersects the instance of dielectric structure 221_cg and the instances of dielectric structure 221_cmd that are aligned to relative to the Y-axis and are adjacent correspondingly to the second ends of gate segment 209_g and MD structures 209_md; the top boundary (e.g., 223_T of the fabricated cell region is regarded as being the first reference line; and the bottom boundary (e.g., 223_B of the fabricated cell region is regarded as being the second reference line. More generally, top and bottom boundaries of a fabricated cell regions corresponding to other cell region regions disclosed herein are recognizable in a manner similar to the manner described regarding a fabricated cell region corresponding to cell region 206PN of FIG. 2A.

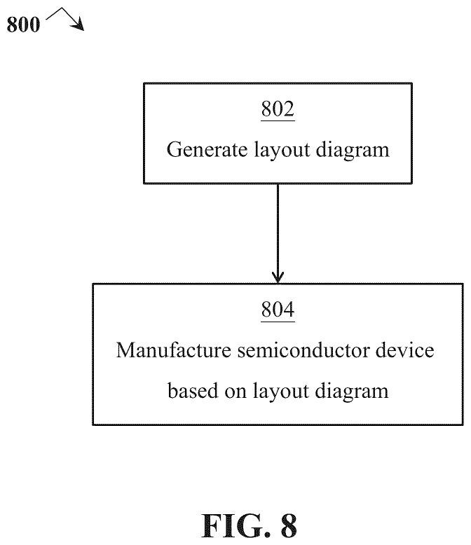

In some embodiments, having a top and/or bottom boundary overlapped by an M0_PG segment, e.g., top boundary 223_T and bottom boundary 223_B correspondingly overlapped by M0_PG segments 262 and 264 in FIG. 2A, facilitates automatic placement and routing (APR) (e.g., FIG. 8).

In some embodiments, relative to the X-axis and relative to another cell region: cell region 206PN is left-adjacent to or leftward abuts the other cell region (e.g., FIG. 3AB, 3AI-3AK, or the like); and/or cell region 206PN is right-adjacent to or rightward abuts another cell region (e.g., FIG. 3AE-3AF, 3AO-3AQ, or the like).

Each of the active regions in cell region 206PN is assumed to have substantially the same width w_AR_1 relative to the Y-axis, width w_AR_1 of the active regions in cell region 206PN is a minimum width of an active region according to one or more design rules of a corresponding semiconductor process technology node. Relative to the Y-axis, cell region 206PN has a height of about 1.0*H, i.e., has a height that is about a 1.0. multiple of the height H of a single height cell region, where height H of the single height cell region is determined according to one or more design rules of a corresponding semiconductor process technology node. For example, relative to the Y-axis, for a given semiconductor process technology node: one or more design rules determine a minimum height of an active region (e.g., 208P and 208N), w_AR_1; and one or more design rules determine a minimum height separation between adjacent instances of (e.g., 208P and 208N), h_gap_min. As such, for the given semiconductor process technology node, in some embodiments, height H would be H=2*w_AR_1+h_gap_min+2*(h_gap_min/2). In FIG. 2A, pitch p_PG is equal to height H such that p_PG=H. In some embodiments, height H would be different than H=2*w_AR_1+h_gap_min+2*(h_gap_min/2). The single height cell region is substantially rectangular and includes two active regions: one P-type, i.e., 208P; and one N-type, i.e., 208N. Each of the active regions in cell region 206PN: is substantially rectangular; and substantially extends from a left boundary 223_L to a right boundary 223_R of cell region 206PN such that active regions of cell region 206PN have substantially the same length relative to the X-axis.

In some embodiments, relative to the Y-axis, a width of the M0_PG segments, w_M0_PG, is about the same as the width of active regions 208P and 208N such that w_M0_PG≈w_AR_1. In some embodiments, relative to the Y-axis, the width of the M0_PG segments, w_M0_PG, is about a 0.96 multiple of w_AR_1 such that w_M0_PG≈0.96*w_AR_1.

In FIG. 2A, cell region 206PN is assumed to have a width of about 4.0*S. Likewise, cell regions 206NP, 210PN, 210NP, 214PPNN, 214NNPP, 218PNP, 218NPN, 224P, 224N, 228P and 228N of corresponding FIGS. 2B-2L, discussed below, are assumed to have a width of about 4.0*S.

In some embodiments, cell region 206PN (and other non-dummy cell regions disclosed herein) includes one or more additional instances of gate segment 209_g. In such embodiments, cell region 206PN includes one or more additional instances of MD structure 209_md. In such embodiments, relative to the X-axis, each instance of gate segment 209_g is between an adjacent instance of MD structure 209_md to the left thereof and an adjacent instance of MD structure 209_md to the right thereof. In such embodiments, the cell regions have correspondingly greater widths than about 4.0*S.

Regarding FIG. 2B, it (FIG. 2B) is similar to FIG. 2A. For purposes of brevity, the discussion will focus on differences of FIG. 2B as compared to FIG. 2A rather than on similarities.

In cell region 206NP of FIG. 2B, relative to the Y-axis, active region 208P is below active region 208N, i.e., active region 208N is above active region 208P. In some embodiments, relative to Y-axis, the locations of active regions 208P and 208N in cell region 206NP are described as being flipped/reversed in comparison to the locations of active regions 208P and 208N in cell region 206PN. Accordingly, in cell region 206NP: M0_PG segment 264 is aligned with top boundary 223_T; and M0_PG segment 262 is aligned with bottom boundary 223_B.

FIGS. 2C-2D layout diagrams of corresponding cell regions 210PN and 210NP, in accordance with some embodiments.

Cell regions 210PN and 210NP are examples of one or more cell regions included in corresponding instances of stacked arrangement 102 and/or multi-column stacked arrangement 104. In some embodiments, cell regions 210PN and 210NP are referred to as FT-type cell regions.

FIGS. 2C-2D are correspondingly similar to FIGS. 2A-2B. That is, cell region 210PN of FIG. 2C and cell region 210NP of FIG. 2D are correspondingly similar to cell region 210PN of FIGS. 2A and 210NP of FIG. 2B. For purposes of brevity, the discussion will focus on differences of FIG. 2C as compared to FIG. 2A rather than on similarities. For simplicity of illustration, gate segments (e.g., 209_g of FIGS. 2A-2B), M0_RTE segments 219, MD structures (e.g., 209_md of FIGS. 2A-2B) and dummy gate segments 209_d (e.g., FIGS. 2A-2B) are omitted from FIGS. 2C-2D (and likewise omitted from FIGS. 2E-2Q, 3AA-3CH, 4AA-4C and 5AA-5BI). Also for simplicity of illustration, top boundary 223_T, bottom boundary 223_B, left boundary 223_L and right boundary 223_R are not called out with reference alphanumerics in FIGS. 2C-2D (and likewise are not called out in FIGS. 2E-2Q, 3AA-3CH, 4AA-4C and 5AA-5BI).

In FIG. 2C, relative to the Y-axis, cell region 210PN has a height of about 1.5*H, i.e., has a height that is about a 1.5 multiple of the height H of the single height cell region, where the height of cell region 210PN is determined according to one or more design rules of a corresponding semiconductor process technology node. In some embodiments, cell region 210PN is referred to as a one-and-one-half height cell region or OHH cell region, where the text string OHH is an acronym for the phrase one-and-one-half height. In some embodiments, cell region 210NP is referred to as a three-halves half height cell region.

Regarding cell region 210PN, it (cell region 210PN) includes active regions 212P and 212N whereas cell region 210PN of FIG. 2A includes active regions 208P and 208N. Active regions 212P and 212N of cell region 210PN have substantially the same length relative to the X-axis; and have substantially the same width w_AR_2 relative to the Y-axis. Relative to the Y-axis, width w_AR_2 of active regions 212P and 212N of cell region 208PN is greater than width w_AR_1 of active regions 208P and 208N of cell region 210PN of FIG. 2A such that w_AR_1<w_AR_2. Relative to the Y-axis, active region 212P is above active region 212N, i.e., active region 212N is below active region 212P.

In FIG. 2C, in terms of alignment relative to the Y-axis, M0_PG segment 262 is aligned with active region 212P. More particularly, in some embodiments, M0_PG segment 262 substantially bisects active region 212P relative to the Y-axis. M0_PG segment 264 is aligned with bottom boundary 223_B. In terms of alignment relative to the Y-axis, active region 212N is free of being overlapped by an M0_PG segment, e.g., 262 or 264.

Regarding FIG. 2D, it (FIG. 2D) is similar to FIG. 2C. For purposes of brevity, the discussion will focus on differences of FIG. 2D as compared to FIG. 2C rather than on similarities.

In cell region 210NP of FIG. 2D, relative to the Y-axis, active region 212P is below active region 212N, i.e., active region 212N is above active region 212P. In some embodiments, relative to Y-axis, the locations of active regions 212P and 212N in cell region 210NP are described as being flipped/reversed in comparison to the locations of active regions 212P and 212N in cell region 210PN. Accordingly, in cell region 210NP: M0_PG segment 264 bisects active region 212N; M0_PG segment 262 is aligned with the bottom boundary; and active region 212P is free of being overlapped by an M0_PG segment, e.g., 262 or 264.

FIGS. 2E-2F layout diagrams of corresponding cell regions 214PPNN and 214NNPP, in accordance with some embodiments.

Cell regions 214PPNN and 214NNPP are examples of one or more cell regions included in corresponding instances of stacked arrangement 102 and/or multi-column stacked arrangement 104. In some embodiments, cell regions 214PPNN and 214NNPP are referred to as FT-type cell regions.

FIGS. 2E-2F are correspondingly similar to FIGS. 2A-2B. That is, cell region 214PPNN of FIG. 2E and cell region 214NNPP of FIG. 2F are correspondingly similar to cell region 206PN of FIGS. 2A and 206NP of FIG. 2B. For purposes of brevity, the discussion will focus on differences of FIG. 2E as compared to FIG. 2A rather than on similarities.

In FIG. 2E, relative to the Y-axis, cell region 214PPNN has a height of about 2.0*H, i.e., has a height that is about a 2.0 multiple of the height H of the single height cell region, where the height of cell region 214PPNN is determined according to one or more design rules of a corresponding semiconductor process technology node. In some embodiments, cell region 214PPNN is referred to as a double height cell region.

Regarding cell region 214PPNN, it (cell region 214PPNN) includes active regions 216P and 216N whereas cell region 206PN of FIG. 2A includes active regions 208P and 208N. Active regions 216P and 216N of cell region 214PPNN have substantially the same length relative to the X-axis; and have substantially the same width w_AR_3 relative to the Y-axis. Relative to the Y-axis, width w_AR_3 of active regions 216P and 216N of cell region 208PN is greater than width w_AR_1 of active regions 208P and 208N of cell region 206PN of FIG. 2A such that w_AR_1<w_AR_3. In some embodiments, the relationship w_AR_1<w_AR_3 is suggested by the alphabetic character string PPNN which comprises reference alphanumeric 214PPNN. In some embodiments, relative to the Y-axis, width w_AR_3 is about twice width w_AR_1 such that such that w_AR_2≈2*w_AR_1. In some embodiments, Relative to the Y-axis, active region 216P is above active region 216N, i.e., active region 216N is below active region 216P.

In FIG. 2E, in terms of alignment relative to the Y-axis: M0_PG segment 262 is aligned with active region 216P; and M0_PG segment 264 is aligned with active region 216N. More particularly, in some embodiments, M0_PG segment 262 substantially bisects active region 216P and M0_PG segment 264 substantially bisects active region 216N relative to the Y-axis.

Regarding FIG. 2F, it (FIG. 2F) is similar to FIG. 2E. For purposes of brevity, the discussion will focus on differences of FIG. 2F as compared to FIG. 2E rather than on similarities.

In cell region 214NNPP of FIG. 2F, relative to the Y-axis, active region 216P is below active region 216N, i.e., active region 216N is above active region 216P. In some embodiments, relative to Y-axis, the locations of active regions 216P and 216N in cell region 214NNPP are described as being flipped/reversed in comparison to the locations of active regions 216P and 216N in cell region 214PN. Accordingly, in cell region 214NNPP: M0_PG segment 264 bisects active region 216N; and M0_PG segment 262 bisects active region 216P.

FIGS. 2G-2H layout diagrams of corresponding cell regions 218PNP and 218NPN, in accordance with some embodiments.

Cell regions 218PNP and 218NPN are examples of one or more cell regions included in corresponding instances of stacked arrangement 102 and/or multi-column stacked arrangement 104. In some embodiments, cell regions 218PNP and 218NPN are referred to as FT-type cell regions.

FIGS. 2G-2H are correspondingly similar to FIGS. 2A-2B. That is, cell region 218PNP of FIG. 2G and cell region 218NPN of FIG. 2H are correspondingly similar to cell region 206PN of FIGS. 2A and 206NP of FIG. 2B. For purposes of brevity, the discussion will focus on differences of FIG. 2G as compared to FIG. 2A rather than on similarities.

In FIG. 2G, relative to the Y-axis, cell region 218PNP has a height of about 2.0*H, i.e., has a height that is about a 2.0 multiple of the height H of the single height cell region, where the height of cell region 218PNP is determined according to one or more design rules of a corresponding semiconductor process technology node. In some embodiments, cell region 218PNP is referred to as a double height cell region.

Regarding cell region 218PNP, it (cell region 218PNP) includes two instances of active region 220P and one instance of active region 222N whereas cell region 206PN of FIG. 2A includes one instance of active region 208P and one instance of active region 208N. Active regions 220P and 222N of cell region 218PNP have substantially the same length relative to the X-axis. The one instance of active region 222N of cell region 218PNP substantially has a width w_AR_4 relative to the Y-axis. Each of the two instances of active region 220P of cell region 218PNP substantially has a width w_AR_5 relative to the Y-axis. Relative to the Y-axis, width w_AR_5 of the instances of active region 220P is smaller than width w_AR_4 of the one instance of active region 222N such that w_AR_5<w_AR_4. In some embodiments, width w_AR_4 of active region 222N is about the same as width w_AR_3 of active regions 216P and 216N of FIGS. 2E-2F such that w_AR_4≈w_AR_3. In some embodiments, relative to the Y-axis, width w_AR_5 of active regions 220P of FIG. 2G is greater than width w_AR_1 of active regions 226P and 226N such that w_AR_1<w_AR_4. Relative to the Y-axis, the one instance of active region 222N is between the two instances of active region 220P. i.e., the two instances of active region 220P correspondingly are above and below the one instance of active region 222N.

In FIG. 2G, in terms of alignment relative to the Y-axis: a first instance of M0_PG segment 262 is aligned with the top boundary of cell region 218PNP; a second instance of M0_PG segment 262 is aligned with the bottom boundary of cell region 218PNP; and a first instance of M0_PG segment 264 is aligned with active region 222N. More particularly, in some embodiments, the first instance of M0_PG segment 264 substantially bisects active region 222N relative to the Y-axis.

Regarding FIG. 2H, it (FIG. 2H) is similar to FIG. 2G. For purposes of brevity, the discussion will focus on differences of FIG. 2H as compared to FIG. 2G rather than on similarities.

Regarding cell region 218NPN, it (cell region 218NPN) includes two instances of active region 220N and one instance of active region 222P whereas cell region 218PNP of FIG. 2G includes one instance of active region 222N and two instances of active region 220P. Active regions 220N and 222P of cell region 218NPN have substantially the same length relative to the X-axis. The one instance of active region 222P of cell region 218NPN substantially has width w_AR_4 relative to the Y-axis. Each of the two instances of active region 220N of cell region 218NPN substantially has width w_AR_5 relative to the Y-axis.

In FIG. 2G, in terms of alignment relative to the Y-axis: a first instance of M0_PG segment 264 is aligned with the top boundary of cell region 218NPN; a second instance of M0_PG segment 264 is aligned with the bottom boundary of cell region 218NPN; and a first instance of M0_PG segment 262 is aligned with active region 222P. More particularly, in some embodiments, the first instance of M0_PG segment 262 substantially bisects active region 222P relative to the Y-axis.

In cell region 218NPN of FIG. 2H, relative to the Y-axis, the one instance of active region 222P is between the two instances of active region 220N. i.e., the two instances of active region 220N correspondingly are above and below the one instance of active region 222P. As such, in some embodiments, relative to Y-axis, the locations of P-type and N-type active regions in cell region 218NPN are described as being flipped/reversed in comparison to the locations of P-type and N-type active regions in cell region 214PN.

FIGS. 2I-2J layout diagrams of corresponding cell regions 224P and 224N, in accordance with some embodiments.

Cell regions 224P and 224N are examples of one or more cell regions included in corresponding instances of stacked arrangement 102 and/or multi-column stacked arrangement 104. In some embodiments, each of cell regions 224P and 224N is referred to as a no-functioning-transistor type (NFT-type) cell region, as discussed below. In some embodiments, each of cell regions 224P and 224N is referred to as a filler cell region.

FIGS. 2I-2J are correspondingly similar to FIGS. 2A-2B. That is, cell region 224P of FIG. 2I and cell region 224N of FIG. 2J are correspondingly similar to cell region 224P of FIGS. 2A and 224N of FIG. 2B. For purposes of brevity, the discussion will focus on differences of FIGS. 2I-2J as compared to corresponding FIGS. 2A-2B rather than on similarities.

In FIGS. 2I-2J, relative to the Y-axis, each of cell region 224P and 224N has a height of about 0.5*H, i.e., has a height that is about a 0.5 multiple of the height H of the single height cell region, where the height of cell regions 224P and 224N is determined according to one or more design rules of a corresponding semiconductor process technology node. In some embodiments, each of cell regions 224P and 224N is referred to as half height cell region.

Regarding cell region 224P of FIG. 2I, it (cell region 224P) includes an active region 226P and is free from including an instance of active region 226N (see FIG. 2J) whereas cell region 206PN of FIG. 2A includes active regions 208P and 208N. Regarding cell region 224N of FIG. 2J, it (cell region 224N) includes an active region 226N and is free from including an instance of active region 226P (see FIG. 2I) whereas cell region 206NP of FIG. 2B includes active regions 208P and 208N. Active regions 226P and 226N have substantially the same length relative to the X-axis; and have substantially the same width w_AR_6 relative to the Y-axis. Relative to the Y-axis, width w_AR_6 of active regions 226P and 226N is smaller than width w_AR_5 of active regions 220P of FIG. 2G and active regions 220N of FIG. 2H such w_AR_6<w_AR_5. In some embodiments, width w_AR_6 of active region 226P and 226N is about the same as width w_AR_1 of active regions 208P and 208N of FIGS. 2A-2B such that w_AR_6≈w_AR_1.

In FIG. 2I, in terms of alignment relative to the Y-axis, M0_PG segment 262 of cell region 224P is aligned with the top boundary of cell region 224P whereas the bottom boundary of cell region 224P is free from being overlapped by an instance of an M0_PG segment, e.g., 264. In some embodiments, in terms of alignment relative to the Y-axis, M0_PG segment 264 of cell region 224P is aligned with the bottom boundary of cell region 224P whereas the top boundary of cell region 224P is free from being overlapped by an instance of an M0_PG segment, e.g., 262.

In FIG. 2J, in terms of alignment relative to the Y-axis, M0_PG segment 264 of cell region 224N is aligned with the bottom boundary of cell region 224N whereas the top boundary of cell region 224N is free from being overlapped by an instance of an M0_PG segment, e.g., 262. In some embodiments, in terms of alignment relative to the Y-axis, M0_PG segment 264 of cell region 224N is aligned with the top boundary of cell region 224N whereas the bottom boundary of cell region 224N is free from being overlapped by an instance of an M0_PG segment, e.g., 262.

In some embodiments in which transistor components (e.g., S/D regions, channel regions, or the like) are formed in active region 226P of cell region 224P and active region 226N of cell region 224N, nevertheless no functional/operative transistors are present in cell regions 224P and 224N because corresponding active regions 226P and 226N are free from being electrically coupled to the M0 segments (see FIGS. 7A-7B) in a manner that would otherwise result in one or more functional/operative transistors. Hence, in some embodiments, each of cell regions 224P and 224N is referred to as an NFT-type cell region. Hence, in some embodiments, each of cell regions 224P and 224N is referred to as a filler cell region.

In some embodiments, regarding one or more first gate segments that overlie filler cell regions 224P and 224N and extend beyond the boundaries thereof, no instances of a VG contact (see FIG. 7A) are formed between the first gate segments and an overlying M0 segment (see FIG. 7A). In some embodiments, (1) one or more second gate segments that overlie filler cell regions 224P and 224N are cut so as not to extend substantially beyond the top and bottom boundaries of corresponding filler cell regions 224P and 224N and (2) no instances of a VG contact (see FIG. 7A) are formed between the second gate segments and an overlying M0 segment (see FIG. 7A). In some embodiments, regarding one or more third gate segments having portions that otherwise would overlie filler cell regions 224P and 224N, the otherwise overlapping portions of the third gate segments are removed. In some embodiments, regarding one or more first MD structures that overlie filler cell regions 224P and 224N and extend beyond the boundaries thereof, no instances of a VD contact (see FIG. 7B) are formed between the first MD structures and an overlying M0 segment (see FIG. 7B). In some embodiments, (1) one or more second MD structures that overlie filler cell regions 224P and 224N are cut so as not to extend substantially beyond the top and bottom boundaries of corresponding filler cell regions 224P and 224N and (2) no instances of a VD contact (see FIG. 7B) are formed between the second MD structures and an overlying M0 segment (see FIG. 7B). In some embodiments, regarding one or more third MD structures having portions that otherwise would overlie filler cell regions 224P and 224N, the otherwise overlapping portions of the third MD structures are removed.

FIGS. 2K-2L layout diagrams of corresponding cell regions 228P and 228N, in accordance with some embodiments.

Cell regions 228P and 228N are examples of one or more cell regions included in corresponding instances of stacked arrangement 102 and/or multi-column stacked arrangement 104. In some embodiments, cell regions 228P and 228N are referred to as FT-type cell regions.

FIGS. 2K-2L are correspondingly similar to FIGS. 2I-2J. That is, cell region 228P of FIG. 2K and cell region 228N of FIG. 2L are correspondingly similar to cell region 224P of FIGS. 2I and 224N of FIG. 2J. For purposes of brevity, the discussion will focus on differences of FIGS. 2K-2L as compared to corresponding FIGS. 2I-2J rather than on similarities.

Relative to the Y-axis, each of cell region 228P of FIG. 2K and cell region 228N of FIG. 2L has a height of about 0.5*H, i.e., has a height that is about a 0.5 multiple of the height H of the single height cell region, where the height of cell regions 228P and 228N is determined according to one or more design rules of a corresponding semiconductor process technology node. In some embodiments, each of cell regions 228P and 228N is referred to as half height cell region.

In FIGS. 2K-2L, none of the one or more gate segments (see FIGS. 2A-2B) nor the one or more MD segments (see FIGS. 2A-2B) in cell regions 228P and 228N is coupled to a voltage source, i.e., not VDD nor VSS nor a voltage between VDD and VSS. As such, in some embodiments, each of cell regions 228P and 228N is referred to as a dummy cell region (dummy CR).

Regarding dummy CR 228P, it (dummy CR 228P) includes an active region 230P and is free from including an instance of active region 230N (see FIG. 2L). Regarding dummy CR 228N, it (dummy CR 228N) includes an active region 230N and is free from including an instance of active region 230P (see FIG. 2K). Active regions 230P and 230N have substantially the same length relative to the X-axis; and have substantially the same width w_AR_7 relative to the Y-axis. Relative to the Y-axis, width w_AR_7 of active regions 230P and 230N is smaller than width w_AR_5 of active regions 220P of FIG. 2G and active regions 220N of FIG. 2H such w_AR_7<w_AR_5. In some embodiments, width w_AR_7 of active region 230P and 230N is about the same as width w_AR_6 of active regions 226P of FIGS. 2I and 226N of FIG. 2J such that w_AR_7≈w_AR_6. In some embodiments, width w_AR_7 of active region 230P and 230N is about the same as width w_AR_1 of active regions 208P and 208N of FIGS. 2A-2B such that w_AR_7≈w_AR_1.

In FIG. 2K, in terms of alignment relative to the Y-axis, M0_PG segment 262 of dummy CR 228P is aligned with the top boundary of dummy CR 228P whereas the bottom boundary of dummy CR 228P is free from being overlapped by an instance of an M0_PG segment, e.g., 264. In some embodiments, in terms of alignment relative to the Y-axis, M0_PG segment 264 of dummy CR 228P is aligned with the bottom boundary of dummy CR 228P whereas the top boundary of dummy CR 228P is free from being overlapped by an instance of an M0_PG segment, e.g., 262.

In FIG. 2L, in terms of alignment relative to the Y-axis, M0_PG segment 264 of dummy CR 228N is aligned with the bottom boundary of dummy CR 228N whereas the top boundary of dummy CR 228N is free from being overlapped by an instance of an M0_PG segment, e.g., 262. In some embodiments, in terms of alignment relative to the Y-axis, M0_PG segment 264 of dummy CR 228N is aligned with the top boundary of dummy CR 228N whereas the bottom boundary of dummy CR 228N is free from being overlapped by an instance of an M0_PG segment, e.g., 262.

FIG. 2M is a layout diagram of a dummy cell region 232, in accordance with some embodiments.

Cell region 232 is an example of one or more cell regions included in corresponding instances of stacked arrangement 102 and/or multi-column stacked arrangement 104. In some embodiments, cell region 232 is referred to as an NFT-type cell region, as discussed below. In some embodiments, cell region 232 is referred to as a dummy cell region, as discussed below.

FIG. 2M is similar to FIG. 2E or FIG. 2F. That is, cell region 232 of FIG. 2M is similar to cell region 214PPNN of FIG. 2E or cell region 214NNPP of FIG. 2F. For purposes of brevity, the discussion will focus on differences of FIG. 2M as compared to FIG. 2E or FIG. 2F rather than on similarities.

In FIG. 2M, relative to the Y-axis, cell region 232 has a height of about 2.0*H, i.e., has a height that is about a 2.0 multiple of the height H of the single height cell region, where the height of cell region 232 is determined according to one or more design rules of a corresponding semiconductor process technology node. In some embodiments, cell region 232 is referred to as a double height cell region.

Typically, cell region 232 is abutted to one or more cell regions relative to the X-axis (e.g., FIG. 3AA, or the like). Active regions (discussed below) included in cell region 232 have P-type/N-type configurations that corresponds to the active regions of the one or more cell regions to which cell region 232 is abutted.

Regarding cell region 232, it (cell region 232) includes first and second instances of an active region 249(1). In some embodiments in which cell region 232 is similar to cell region 214PPNN of FIG. 2E, the first and second instances of active region 249(1) correspond to active regions 216P and 216N of FIG. 2E. In some embodiments in which cell region 232 is similar to cell region 214NNPP of FIG. 2F, the first and second instances of active region 249(1) correspond to active regions 216N and 216P of FIG. 2F.

In FIG. 2M, none of the one or more gate segments (see FIGS. 2A-2B) nor the one or more MD segments (see FIGS. 2A-2B) in cell region 232 is coupled to one of the M0 segments (see FIGS. 7A-7B). Though cell region 232 includes instances of active region 249(1), nevertheless the instances of active region 249(1) are free from being electrically coupled to one of the M0 segments (see FIGS. 7A-7B). Hence, in some embodiments, cell region 232 is referred to as an NFT-type cell region. Hence, in some embodiments, cell region 232 is referred to as a dummy CR. The first and second instances of active region 249(1) of dummy CR 232 have substantially the same length relative to the X-axis; and have substantially the same width w_AR_3 relative to the Y-axis.

In FIG. 2M, the M0 segments include instances of M0_PG segment 266. Depending upon the P-type/N-type configuration of the active regions in dummy CR 232, an instance of M0_PG segment 266 is: configured for the first reference voltage, e.g., VDD, and so represents an example of M0_PG segment 264; or is configured for the second reference voltage, e.g., VSS, and so represents an example of M0_PG segment 262.

In FIG. 2M, in terms of alignment relative to the Y-axis: the first instance of M0_PG segment 266 is aligned with the first instance of active region 249(1) in dummy CR 232; and the second instance of M0_PG segment 266 is aligned with the second instance of active region 249(1) in dummy CR 232. More particularly, in some embodiments, the first instance of M0_PG segment 266 substantially bisects the first instance of active region 249(1) in dummy CR 232, relative to the Y-axis. In some embodiments, the second instance of M0_PG segment 266 substantially bisects the second instance of active region 249(1) in dummy CR 232, relative to the Y-axis.

In FIG. 2M, dummy CR 232 is assumed to have a width equal to or greater than about 1.0*S. Likewise, cell regions 234-239 and 259 of corresponding FIGS. 2N-2Q, discussed below, are assumed to have a width equal to or greater than about 1.0*S.

FIG. 2N is a layout diagram of a dummy cell region 234, in accordance with some embodiments.

Cell region 234 is an example of one or more cell regions included in corresponding instances of stacked arrangement 102 and/or multi-column stacked arrangement 104.

FIG. 2N is similar to FIG. 2G or FIG. 2H. That is, cell region 234 of FIG. 2N is similar to cell region 218PNP of FIG. 2G or cell region 218NPN of FIG. 2H. For purposes of brevity, the discussion will focus on differences of FIG. 2N as compared to FIG. 2G or FIG. 2H rather than on similarities.

In FIG. 2G, relative to the Y-axis, cell region 234 has a height of about 2.0*H, i.e., has a height that is about a 2.0 multiple of the height H of the single height cell region, where the height of cell region 234 is determined according to one or more design rules of a corresponding semiconductor process technology node. In some embodiments, cell region 234 is referred to as a double height cell region.

Typically, cell region 234 is abutted to one or more cell regions relative to the X-axis (e.g., FIG. 3AB, or the like). Active regions (discussed below) included in cell region 234 have P-type/N-type configurations that corresponds to the active regions of the one or more cell regions to which cell region 234 is abutted.

Regarding cell region 234, it (cell region 234) includes a first instance of an active region 249(2) and first and second instances of an active region 249(3). In some embodiments in which cell region 234 is similar to cell region 234 of FIG. 2G, the first instance of active region 249(2) corresponds to the first instance of active region 222N of FIG. 2G and the first and second instances of active region 249(3) correspond to the first and second instances of active region 220P of FIG. 2G. In some embodiments in which cell region 234 is similar to cell region 218NPN of FIG. 2H, the first instance of active region 249(2) corresponds to the first instance of active region 222P of FIG. 2H and the first and second instances of active region 249(3) correspond to the first and second instances of active region 220N of FIG. 2H.

In FIG. 2N, none of the one or more gate segments (see FIGS. 2A-2B) nor the one or more MD segments (see FIGS. 2A-2B) in cell region 234 is coupled to a voltage source, i.e., not VDD nor VSS nor a voltage between VDD and VSS. As such, in some embodiments, cell region 234 is referred to as a dummy CR.

The first instance of active region 249(2) and the first and second instances of active region 249(3) of dummy CR 234 have substantially the same length relative to the X-axis. The first instance of active region 249(2) has width w_AR_4 relative to the Y-axis. The first and second instances of active region 249(3) have width w_AR_5 relative to the Y-axis.

In FIG. 2N, in terms of alignment relative to the Y-axis: a first instance of M0_PG segment 266 is aligned with the top boundary of dummy CR 234; a second instance of M0_PG segment 266 is aligned with the first instance of active region 249(2) in dummy CR 234; and a third instance of M0_PG segment 266 is aligned with the bottom boundary of dummy CR 234. More particularly, in some embodiments, the second instance of M0_PG segment 266 substantially bisects the first instance of active region 249(2) in dummy CR 234, relative to the Y-axis.

FIG. 2O is a layout diagram of a dummy cell region 236, in accordance with some embodiments.

Cell region 236 is an example of one or more cell regions included in corresponding instances of stacked arrangement 102 and/or multi-column stacked arrangement 104.

FIG. 2O is similar to FIG. 2N. That is, cell region 236 of FIG. 2O is similar to cell region 234 of FIG. 2N. For purposes of brevity, the discussion will focus on differences of FIG. 2O as compared to FIG. 2N rather than on similarities.

In FIG. 2O, relative to the Y-axis, cell region 236 has a height of about 2.5*H, i.e., has a height that is about a 2.5 multiple of the height H of the single height cell region, where the height of cell region 236 is determined according to one or more design rules of a corresponding semiconductor process technology node.

Typically, cell region 236 is abutted to one or more cell regions relative to the X-axis (e.g., FIG. 3AC, or the like). Active regions (discussed below) included in cell region 236 have P-type/N-type configurations that corresponds to the active regions of the one or more cell regions to which cell region 236 is abutted.

Regarding cell region 236, it (cell region 236) includes a first instance of active region 249(1) (see FIG. 2M) and first and second instances of active region 249(3) (see FIG. 2N). Relative to the Y-axis, the first instance of active region 249(1) in cell region 236 is between the first and second instances of active region 249(3). In FIG. 2O, none of the one or more gate segments (see FIGS. 2A-2B) nor the one or more MD segments (see FIGS. 2A-2B) in cell region 236 is coupled to a voltage source, i.e., not VDD nor VSS nor a voltage between VDD and VSS. As such, in some embodiments, cell region 236 is referred to as a dummy CR.

The first instance of active region 249(1) and the first and second instances of active region 249(3) of dummy CR 236 have substantially the same length relative to the X-axis. The first instance of active region 249(1) has width w_AR_3 relative to the Y-axis. The first and second instances of active region 249(3) have width w_AR_5 relative to the Y-axis.

In FIG. 2O , the M0 segments include instances of M0_PG segment 266. Depending upon the P-type/N-type configuration of the active regions in dummy CR 236, an instance of M0_PG segment 266 is: configured for the first reference voltage, e.g., VDD, and so represents an example of M0_PG segment 264; or is configured for the second reference voltage, e.g., VSS, and so represents an example of M0_PG segment 262.

In terms of alignment relative to the Y-axis: a first instance of M0_PG segment 266 is aligned with the top boundary of dummy CR 236; a second instance of M0_PG segment 266 is aligned with the first instance of active region 249(1) in dummy CR 236; and a third instance of M0_PG segment 266 is aligned with the bottom boundary of dummy CR 236. More particularly, in some embodiments, the second instance of M0_PG segment 266 substantially bisects the first instance of active region 249(1) in dummy CR 236, relative to the Y-axis.

FIG. 2P is a layout diagram of abutted dummy cell regions 238 and 239, in accordance with some embodiments.

Each of cell regions 238 and 239 is an example of one or more cell regions included in corresponding instances of stacked arrangement 102 and/or multi-column stacked arrangement 104.

In FIG. 2P, relative to the Y-axis, each of cell regions 238 and 239 has a height of about 3.0*H, i.e., has a height that is about a 3.0 multiple of the height H of the single height cell region, where the height of each of cell regions 238 and 239 is determined according to one or more design rules of a corresponding semiconductor process technology node. In some embodiments, each of cell regions 238 and 239 is referred to as a triple height cell region.

Typically, in addition to being abutted to each other, each of cell region 238 and cell region 239 is abutted to first and second other cell regions relative to the X-axis (e.g., FIG. 3BY, or the like). Correspondingly abutting active regions (discussed below) in cell regions 238 and 239 have the same P-type/N-type configuration. Furthermore, the active regions included in cell regions 238 and 239 have P-type/N-type configurations that corresponds to the active regions of the first and second other cells region to which cell regions 238 and 239 are abutted.

Regarding cell region 238, it (cell region 238) includes first and second instances of an active region 249(4) and first and second instances of an active region 249(5). In FIG. 2P, none of the one or more gate segments (see FIGS. 2A-2B) nor the one or more MD segments (see FIGS. 2A-2B) in cell region 238 is coupled to a voltage source, i.e., not VDD nor VSS nor a voltage between VDD and VSS. As such, in some embodiments, cell region 238 is referred to as a dummy CR.

Regarding cell region 239, it (cell region 239) includes first, second, third and fourth instances of an active region 249(6). As such, none of the one or more gate segments (see FIGS. 2A-2B) nor the one or more MD segments (see FIGS. 2A-2B) in cell region 239 is coupled to a voltage source, i.e., not VDD nor VSS nor a voltage between VDD and VSS. As such, in some embodiments, cell region 239 is referred to as a dummy CR.

The first and second instances of active region 249(4) and the first and second instances of active region 249(5) of dummy CR 234 have substantially the same length relative to the X-axis. The first and second instances of active region 249(4) have width w_AR_1 relative to the Y-axis. The first and second instances of active region 249(5) have width w_AR_8 relative to the Y-axis. The first to fourth instances of active region 249(6) of dummy CR 239 have substantially the same length relative to the X-axis. The first to fourth instances of active region 249(4) of dummy CR 239 have width w_AR_2 relative to the Y-axis.

In FIG. 2P, in terms of alignment relative to the Y-axis: a first instance of M0_PG segment 266 is aligned with the top boundary of each of dummy CRs 238 and 239; a second instance of M0_PG segment 266 is aligned with the first instance of active region 249(5) in dummy CR 238 and the second instance of active region 249(6) in dummy CR 239; a third instance of M0_PG segment 266 is aligned with the second instance of active region 249(5) in dummy CR 238 and the third instance of active region 249(6) in dummy CR 239; and a fourth instance of M0_PG segment 266 is aligned with the bottom boundary of each of dummy CRs 238 and 239. More particularly, in some embodiments, the second instance of M0_PG segment 266 intersects a central area of the first instance of active region 249(5) in dummy CR 238 and substantially bisects the second instance of active region 249(6) in dummy CR 239, relative to the Y-axis. In some embodiments, the third instance of M0_PG segment 266 intersects a central area of the second instance of active region 249(5) in dummy CR 238 and substantially bisects the third instance of active region 249(6) in dummy CR 239, relative to the Y-axis.

FIG. 2Q is a layout diagram of abutted cell region 259 and dummy CR 239, in accordance with some embodiments.

Dummy CR 239 is discussed above in the context of FIG. 2P. Cell region is an example of one or more cell regions included in corresponding instances of stacked arrangement 102 and/or multi-column stacked arrangement 104.

In FIG. 2Q, relative to the Y-axis, cell region 259 has a height of about 3.0*H, i.e., has a height that is about a 3.0 multiple of the height H of the single height cell region, where the height of cell region 259 is determined according to one or more design rules of a corresponding semiconductor process technology node. In some embodiments, cell region 259 is referred to as a triple height cell region.

Typically, in addition to being abutted to each other, each of cell region 259 and dummy CR 239 is abutted to first and second other cell regions relative to the X-axis (e.g., FIG. 3AC, or the like). Correspondingly abutting active regions (discussed below) in cell region 259 and dummy CR 239 have the same P-type/N-type configuration. Furthermore, the active regions included in cell region 259 and dummy CR 239 have P-type/N-type configurations that corresponds to the active regions of the first and second other cells region to which cell region 259 and dummy CR 239 are abutted.

Regarding cell region 259, it (cell region 259) includes a first instance of active region 249(4), a first instance of an active region 249(7), a first instance of active region 249(2) and a first instance of active region 249(3). In FIG. 2Q, none of the one or more gate segments (see FIGS. 2A-2B) nor the one or more MD segments (see FIGS. 2A-2B) in cell region 259 is coupled to a voltage source, i.e., not VDD nor VSS nor a voltage between VDD and VSS. As such, in some embodiments, cell region 259 is referred to as a dummy CR.

The first instance of active region 249(4), the first instance of active region 249(7), the first instance of active region 249(2) and the first instance of active region 249(3) of dummy CR 234 have substantially the same length relative to the X-axis. The first instance of active region 249(4) in dummy CR 259 has width w_AR_1 relative to the Y-axis. The first instance of active region 249(7) in dummy CR 259 has width w_AR_9. The first instance of active region 249(2) in dummy CR 259 has width w_AR_4. The first instance of active region 249(3) in dummy CR 259 has width w_AR_5.

In FIG. 2Q, in terms of alignment relative to the Y-axis: a first instance of M0_PG segment 266 is aligned with the top boundary of each of dummy CRs 259 and 239; a second instance of M0_PG segment 266 is aligned with the first instance of active region 249(7) in dummy CR 259 and the second instance of active region 249(6) in dummy CR 239; a third instance of M0_PG segment 266 is aligned with the first instance of active region 249(2) in dummy CR 259 and the third instance of active region 249(6) in dummy CR 239; and a fourth instance of M0_PG segment 266 is aligned with the bottom boundary of each of dummy CRs 259 and 239. More particularly, in some embodiments, the second instance of M0_PG segment 266 intersects an interior area of the first instance of active region 249(5) in dummy CR 259 and substantially bisects the second instance of active region 249(6) in dummy CR 239, relative to the Y-axis. In some embodiments, the third instance of M0_PG segment 266 substantially bisects the first instance of active region 249(2) in dummy CR 259 and substantially bisects the third instance of active region 249(6) in dummy CR 239, relative to the Y-axis.

Regarding FIGS. 2A-2Q in some embodiments, corresponding cell regions 206PN, 206NP, 210PN, 210NP, 214PPNN, 214NNPP and 218PNP, 218NPN, filler cell regions 224P and 224N, cell regions 228P and 228N, and dummy CRs 232, 234, 236, 238, 239 and 259 comprise a library of standard cell regions, i.e., a first subset of the library being standard CMOS cell regions and a second subset of the library being standard non-CMOS standard cell regions. That is, in some embodiments, cell regions 206PN, 206NP, 210PN, 210NP, 214PPNN, 214NNPP and 218PNP, and dummy CRs 232, 234, 236, 238, 239 and 259 of corresponding FIGS. 2A-2H and 2M-2Q represent standard CMOS cell regions whereas each of filler cell regions 224P and 224N of corresponding FIGS. 2I-2J and cell regions 228P and 228N of corresponding FIGS. 2K-2L represent standard non-CMOS cell regions.

At least some of the present embodiments provide a library of standard CMOS cell regions, e.g., FIGS. 2A-2H and 2M-2Q, and standard non-CMOS standard cell regions (where the latter includes half-height non-CMOS standard cell regions, e.g., FIGS. 2I-2J and 2K-2L). Among other things, single column stacked arrangements and/or multi-column stacked arrangements based on a library of standard CMOS cell regions and standard non-CMOS cell regions (the latter including half-height non-CMOS standard cell regions) according to at least some embodiments exhibit increased transistor densities as compared to other approaches that have a library of only standard CMOS cell regions; accordingly, such embodiments reduce the areas consumed by corresponding macro regions, improve the speed of corresponding macro region, reduce the power consumption of corresponding macro regions, improve macro region placement flexibility and improve pin accessibility as compared to other approaches.

In some embodiments, single column stacked arrangements and/or multi-column stacked arrangements that include standard CMOS cell regions, e.g., FIGS. 2A-2H and 2M-2Q, and standard non-CMOS standard cell regions (where the latter includes half-height non-CMOS standard cell regions, e.g., FIGS. 2I-2J and 2K-2L), are referred to as mixed arrangements.

In some embodiments, single column stacked arrangements and/or multi-column stacked arrangements that include standard CMOS cell regions, e.g., FIGS. 2A-2H and 2M-2Q, and but do not include standard non-CMOS standard cell regions (where the latter includes half-height non-CMOS standard cell regions, e.g., FIGS. 2I-2J and 2K-2L), are referred to as hybrid arrangements.

FIG. 3AA-3CH are diagrams of multi-column stacked arrangements (multi-stacks) 350(1)-350(60) of cell regions, in accordance with some embodiments, and are discussed below. In some embodiments, FIG. 3AA-3CH are layout diagrams. Examples of multi-stacks which include half-height non-CMOS standard cell regions and thereby facilitate increased transistor densities within macro regions of which the multi-stacks comprise corresponding parts include multi-stacks 350(1), 350(3)-350(52), 350(55), 350(77) and 350(60) of corresponding FIG. 3AA, 3AC-3AE, 3AG-3BX, 3BZ, 3CC, 3CE and 3CH. By facilitating increased transistor densities, macro regions of which the multi-stacks comprise corresponding parts exhibit reductions in areas consumed by the macro regions, improvements in the speeds of the macro regions, reductions in power consumed by the macro regions, improvements in macro region placement flexibility and improvements in pin accessibility as compared to the other approaches.

FIG. 3AA is a layout diagram of a multi-column stacked arrangement (multi-stack) 350(1), in accordance with some embodiments.

Multi-stack 350(1) is an example of multi-column stacked arrangement 104 of FIGS. 1B and 1C. Relative to the Y-axis, multi-stack 350(1) has a height of about 2.0*H.

Multi-stack 350(1) includes end column 342(1), middle column 344(1) and end column 340(1). Middle column 344(1) is abutted between end column 342(1) and end column 340(1). Multi-stack 350(1) has a vertical axis of symmetry 360(1) which is parallel to the Y-axis and bisects middle column 344(1) and thus bisects multi-stack 350(1). In some embodiments, multi-stack 350(1), and each of the other multi-stacks shown correspondingly in FIG. 3AB-3AZ, 3BA-3BZ and 3CA-3CH, is referred to as a three column multi-stack. In such embodiments, other multi-stacks shown correspondingly in FIG. 3AB-3AZ, 3BA-3BZ and 3CA-3CH are referred to as a three column multi-stacks.

Middle column 344(1) includes dummy CR 332(1). Dummy CR 332(1) is an example of dummy CR 232 of FIG. 2M. More generally, in FIG. 3AA and in other figures disclosed herein, a reference number of the type “332(x),” where x represents an index number, e.g., 332(1), denotes an example of dummy CR 232.

End column 342(1) includes filler cell regions 324(1) and 324(2) and a cell region 306(1). Cell region 306(1) is example of either cell region 206PN of FIG. 2A or cell region 206NP of FIG. 2B. For simplicity of illustration, cell region 306(1) is depicted with the legend “PN” rather than the legend “PN or NP.” More generally, in FIG. 3AA and in other figures disclosed herein, a reference number of the type “306(x),” where x represents an index number, e.g., 306(1), denotes an example of either cell region 206PN of FIG. 2A or cell region 206NP of FIG. 2B. Each of filler cell region 324(1) and 324(2) correspondingly is an example of filler cell region 224P of FIG. 2I or filler cell region 224N of FIG. 2J. More generally, in FIG. 3AA and in other figures disclosed herein, a reference number of the type “324(x),” where x represents an index number, e.g., 324(1), denotes an example of either cell region 224P of FIG. 2I or filler cell region 224N of FIG. 2J. Filler cell region 324(1) is stacked on cell region 306(1). Cell region 306(1) is stacked on filler cell region 324(2). In other words, filler cell region 324(2) is stacked under cell region 306(1). Regarding the term “stacked,” as used herein, a stacked arrangement of a first widget and a second widget connotes either that the first widget is above (if not on) the second widget or that the second widget is above (if not on) the first widget.

End column 340(1) includes cell region 314(1). Cell region 314(1) is example of either cell region 214PPNN of FIG. 2E or cell region 214NNPP of FIG. 2F. For simplicity of illustration, cell region 314(1) is depicted with the legend “PPNN” rather than the legend “PPNN or NNPP.” More generally, in FIG. 3AA and in other figures disclosed herein, a reference number of the type “314(x),” where x represents an index number, e.g., 314(1), denotes an example of either cell region 206PN of FIG. 2A or cell region 206NP of FIG. 2B. Each of filler cell region 324(1) and 324(2) correspondingly is an example of filler cell region 224P of FIG. 2I or filler cell region 224N of FIG. 2J. More generally, in FIG. 3AA and in other figures disclosed herein, a reference number of the type “324(x),” where x represents an index number, e.g., 324(1), denotes an example of either cell region 214PPNN of FIG. 2E or cell region 214NNPP of FIG. 2F.

In some embodiments, relative to the X-axis, the left side/boundary of multi-stack 350(1) is abutted to a corresponding side of another instance of multi-stack 350(1) or a corresponding side of one of multi-stacks 350(2)-350(60) of FIG. 3AB-3CH or 450(1)-450(60) of FIG. 4AA-4CH or a corresponding side of one of uni-stacks 568(1)-568(35) of FIG. 5AA-5BI. In some embodiments, relative to the X-axis, the right side/boundary of multi-stack 350(1) is abutted to a corresponding side of another instance of multi-stack 350(1) or a corresponding side of one of multi-stacks 350(2)-350(60 of FIG. 3AB-3CH or 450(1)-450(60) of FIG. 4AA-4CH or a corresponding side of one of uni-stacks 568(1)-568(35) of FIG. 5AA-5BI.

In multi-stack 350(1) and in other multi-stacks disclosed herein, for simplicity of illustration, the various P-type/N-type configurations of the active regions in the multi-stack are not depicted. Rather, relative to the X-axis, regarding the multi-stacks, it is to understood that active regions which abut relative to the X-axis have the same P-type configuration or the same N-type configuration. Also, relative to the Y-axis, the various P-type/N-type configurations of the active regions in the multi-stack are informed according to the architecture of the transistor-based device, e.g., CMOS architecture, of which the multi-stack comprises a part.

In FIG. 3AA, and in FIG. 3AB-3CH, 4AA-4CH and 5AA-5AF, the M0 segments include instances of M0_PG segment 366. Depending upon the P-type/N-type configuration of the active regions in the various cell regions and or filler cell regions, an instance of M0_PG segment 366 is: configured for the first reference voltage, e.g., VDD, and so represents an example of M0_PG segment 264; or is configured for the second reference voltage, e.g., VSS, and so represents an example of M0_PG segment 262.

In some figures which exhibit similarities to other figures, for simplicity of illustration, M0_PG segments are omitted. In some figures which exhibit similarities to other figures, for simplicity of illustration, some of the reference numbers are omitted.

FIG. 3AB is a layout diagram of a multi-stack 350(2), in accordance with some embodiments.

Multi-stack 350(2) is an example of multi-column stacked arrangement 104 of FIGS. 1B and 1C. Relative to the Y-axis, multi-stack 350(2) has a height of about 2.0*H.

Multi-stack 350(2) includes end column 342(2), middle column 344(2) and end column 340(2). Middle column 344(2) is abutted between end column 342(2) and end column 340(2). Multi-stack 350(2) has a vertical axis of symmetry 360(2) that bisects middle column 344(2) and thus bisects multi-stack 350(2).

Middle column 344(2) includes dummy CR 334(1). Dummy CR 334(1) is an example of dummy CR 234 of FIG. 2N. More generally, in FIG. 3AB and in other figures disclosed herein, a reference number of the type “334(x),” where x represents an index number, e.g., 334(1), denotes an example of dummy CR 234. End column 340(2) includes cell regions 306(2) and 306(3). Cell region 306(2) is stacked on cell region 306(3). End column 342(2) includes cell region 318(1). Cell region 318(1) is example of either cell region 218PNP of FIG. 2G or cell region 218NPN of FIG. 2H. More generally, in FIG. 3AB and in other figures disclosed herein, a reference number of the type “318(x),” where x represents an index number, e.g., 318(1), denotes an example of either cell region 218PNP of FIG. 2G or cell region 218NPN of FIG. 2H.

FIG. 3AC is a layout diagram of a multi-stack 350(3), in accordance with some embodiments.

Multi-stack 350(3) is an example of multi-column stacked arrangement 104 of FIGS. 1B and 1C. Relative to the Y-axis, multi-stack 350(3) has a height of about 2.5*H.

Multi-stack 350(3) includes end column 342(3), middle column 344(3) and end column 340(3). Middle column 344(3) is abutted between end column 342(3) and end column 340(3). Multi-stack 350(3) has: a vertical axis of symmetry 360(3) that bisects middle column 344(3) and thus bisects multi-stack 350(3); and a horizontal axis of symmetry 358(1) which is parallel to the X-axis and bisects multi-stack 350(3).

Middle column 344(3) includes dummy CR 336(1). Dummy CR 336(1) is an example of dummy CR 236 of FIG. 2O. More generally, in FIG. 3AC and in other figures disclosed herein, a reference number of the type “336(x),” where x represents an index number, e.g., 336(1), denotes an example of dummy CR 236. End column 340(3) includes filler cell region 324(3) and cell region 314(2). Filler cell region 324(3) is stacked on cell region 314(2). End column 342(3) includes cell region 318(2) and filler cell region 324(4). Cell region 318(2) is stacked on filler cell region 324(4).

FIG. 3AD is a layout diagram of a multi-stack 350(4), in accordance with some embodiments.

FIG. 3AD is similar to FIG. 3AC. For purposes of brevity, the discussion will focus on differences of FIG. 3AD as compared to FIG. 3AC rather than on similarities.

Multi-stack 350(4) is an example of multi-column stacked arrangement 104 of FIGS. 1B and 1C. Relative to the Y-axis, multi-stack 350(4) has a height of about 2.5*H.

Multi-stack 350(4) includes end column 342(4), middle column 344(4) and end column 340(4). Middle column 344(4) is abutted between end column 342(4) and end column 340(4). Middle column 344(4) of FIG. 3AD corresponds to middle column 344(3) of FIG. 3AC. End column 340(4) of FIG. 3AD corresponds to end column 340(3) of FIG. 3AC. End column 342(4) of FIG. 3AD corresponds to end column 342(3) of FIG. 3AC.

Multi-stack 350(4) has: a vertical axis of symmetry 360(4) that bisects middle column 344(4) and thus bisects multi-stack 350(4); and horizontal axis of symmetry 358(1) that bisects multi-stack 350(4). Multi-stack 350(4) of FIG. 3AD is a version of multi-stack 350(3) of FIG. 3AC which has been rotated 180 degrees (180°) about horizontal axis of symmetry 358(1) with respect to the orientation of multi-stack 350(3).

FIG. 3AE is a layout diagram of a multi-stack 350(5), in accordance with some embodiments.

FIG. 3AE is similar to FIG. 3AA. For purposes of brevity, the discussion will focus on differences of FIG. 3AE as compared to FIG. 3AA rather than on similarities.

Multi-stack 350(5) is an example of multi-column stacked arrangement 104 of FIGS. 1B and 1C. Relative to the Y-axis, multi-stack 350(5) has a height of about 2.0*H.

Multi-stack 350(5) includes end column 342(5), middle column 344(5) and end column 340(5). Middle column 344(5) is abutted between end column 342(5) and end column 340(5). Middle column 344(5) of FIG. 3AE corresponds to middle column 344(1) of FIG. 3AA. End column 340(5) of FIG. 3AE corresponds to end column 340(1) of FIG. 3AA. End column 342(5) of FIG. 3AE corresponds to end column 342(1) of FIG. 3AA.

Multi-stack 350(5) has vertical axis of symmetry 360(5) that bisects middle column 344(5) and thus bisects multi-stack 350(5). Multi-stack 350(5) of FIG. 3AE is a version of multi-stack 350(1) of FIG. 3AA which has been rotated 180 degrees (180°) about vertical axis of symmetry 360(1) with respect to the orientation of multi-stack 350(1).

FIG. 3AF is a layout diagram of a multi-stack 350(6), in accordance with some embodiments.

FIG. 3AF is similar to FIG. 3AB. For purposes of brevity, the discussion will focus on differences of FIG. 3AF as compared to FIG. 3AB rather than on similarities.

Multi-stack 350(6) is an example of multi-column stacked arrangement 104 of FIGS. 1B and 1C. Relative to the Y-axis, multi-stack 350(6) has a height of about 2.0*H.

Multi-stack 350(6) includes end column 342(6), middle column 344(6) and end column 340(6). Middle column 344(6) is abutted between end column 342(6) and end column 340(6). Middle column 344(6) of FIG. 3AF corresponds to middle column 344(2) of FIG. 3AB. End column 340(6) of FIG. 3AF corresponds to end column 340(2) of FIG. 3AB. End column 342(6) of FIG. 3AF corresponds to end column 342(2) of FIG. 3AB.

Multi-stack 350(6) has vertical axis of symmetry 360(2) that bisects middle column 344(6) and thus bisects multi-stack 350(6). Multi-stack 350(6) of FIG. 3AF is a version of multi-stack 350(2) of FIG. 3AB which has been rotated 180 degrees (180°) about vertical axis of symmetry 360(2) with respect to the orientation of multi-stack 350(2).

FIG. 3AG is a layout diagram of a multi-stack 350(7), in accordance with some embodiments.

FIG. 3AG is similar to FIG. 3AC. For purposes of brevity, the discussion will focus on differences of FIG. 3AG as compared to FIG. 3AC rather than on similarities.

Multi-stack 350(7) is an example of multi-column stacked arrangement 104 of FIGS. 1B and 1C. Relative to the Y-axis, multi-stack 350(7) has a height of about 2.5*H.

Multi-stack 350(7) includes end column 342(7), middle column 344(7) and end column 340(7). Middle column 344(7) is abutted between end column 342(7) and end column 340(7). Middle column 344(7) of FIG. 3AG corresponds to middle column 344(3) of FIG. 3AC. End column 340(7) of FIG. 3AG corresponds to end column 340(3) of FIG. 3AC. End column 342(7) of FIG. 3AG corresponds to end column 342(3) of FIG. 3AC.

Multi-stack 350(7) has: vertical axis of symmetry 360(3) that bisects middle column 344(7) and thus bisects multi-stack 350(7); and horizontal axis of symmetry 358(16) that bisects multi-stack 350(7). Multi-stack 350(7) of FIG. 3AG is a version of multi-stack 350(3) of FIG. 3AC which has been rotated 180 degrees (180°) about vertical axis of symmetry 360(3) with respect to the orientation of multi-stack 350(3).

FIG. 3AG also is similar to FIG. 3AD. For purposes of brevity, the discussion will focus on differences of FIG. 3AG as compared to FIG. 3AD rather than on similarities. Multi-stack 350(7) of FIG. 3AG also is a version of multi-stack 350(4) of FIG. 3AD which has been rotated 180 degrees (180°) about horizontal axis of symmetry 358(1) with respect to the orientation of multi-stack 350(4).

FIG. 3AH is a layout diagram of a multi-stack 350(8), in accordance with some embodiments.

FIG. 3AH is similar to FIG. 3AG. For purposes of brevity, the discussion will focus on differences of FIG. 3AH as compared to FIG. 3AG rather than on similarities.

Multi-stack 350(8) is an example of multi-column stacked arrangement 104 of FIGS. 1B and 1C. Relative to the Y-axis, multi-stack 350(8) has a height of about 2.5*H.

Multi-stack 350(8) includes end column 342(8), middle column 344(8) and end column 340(8). Middle column 344(8) is abutted between end column 342(8) and end column 340(8). Middle column 344(8) of FIG. 3AH corresponds to middle column 344(7) of FIG. 3AG. End column 340(8) of FIG. 3AH corresponds to end column 340(7) of FIG. 3AG. End column 342(8) of FIG. 3AH corresponds to end column 342(7) of FIG. 3AG.

Multi-stack 350(8) has: a vertical axis of symmetry 360(4) that bisects middle column 344(8) and thus bisects multi-stack 350(8); and horizontal axis of symmetry 358(16) that bisects multi-stack 350(8). Multi-stack 350(8) of FIG. 3AH is a version of multi-stack 350(7) of FIG. 3AG which has been rotated 180 degrees (180°) about horizontal axis of symmetry 358(16) with respect to the orientation of multi-stack 350(7).

FIG. 3AH also is similar to FIG. 3AD. For purposes of brevity, the discussion will focus on differences of FIG. 3AH as compared to FIG. 3AD rather than on similarities. Multi-stack 350(8) of FIG. 3AH also is a version of multi-stack 350(4) of FIG. 3AD which has been rotated 180 degrees (180°) about vertical axis of symmetry 360(4) with respect to the orientation of multi-stack 350(4).

FIG. 3AI is a layout diagram of a multi-stack 350(9), in accordance with some embodiments.

FIG. 3AI is similar to FIG. 3AA. For purposes of brevity, the discussion will focus on differences of FIG. 3AI as compared to FIG. 3AA rather than on similarities.

Multi-stack 350(9) is an example of multi-column stacked arrangement 104 of FIGS. 1B and 1C. Relative to the Y-axis, multi-stack 350(9) has a height of about 2.0*H.

Multi-stack 350(9) includes end column 342(9), middle column 344(9) and end column 340(9). Middle column 344(9) is abutted between end column 342(9) and end column 340(9). Middle column 344(9) of FIG. 3AI corresponds to middle column 344(1) of FIG. 3AA. End column 340(9) of FIG. 3AI corresponds to end column 340(1) of FIG. 3AA. End column 342(9) of FIG. 3AI corresponds to end column 342(1) of FIG. 3AA.

As compared to end column 342(1) of FIG. 3AA, end column 342(9) of FIG. 3AI includes cell regions 328(1) and 328(2) and correspondingly omits filler cell regions 324(1) and 324(2). That is, in multi-stack 350(9), cell regions 328(1) and 328(2) of multi-stack 350(9) correspondingly replace filler cell regions 324(1) and 324(2) of multi-stack 350(1). In end column 342(9), cell region 328(1) is stacked on cell region 306(1). Cell region 306(1) is stacked on cell region 328(2).

Each of cell region 328(1) and 328(2) correspondingly is an example of cell region 228P of FIG. 2K or cell region 228N of FIG. 2L. More generally, in FIG. 3AA and in other figures disclosed herein, a reference number of the type “328(x),” where x represents an index number, e.g., 328(1), denotes an example of either cell region 228P of FIG. 2K or cell region 228N of FIG. 2L.

FIG. 3AJ is a layout diagram of a multi-stack 350(10), in accordance with some embodiments.

FIG. 3AJ is similar to FIG. 3AI and thus also to FIG. 3AA. For purposes of brevity, the discussion will focus on differences of FIG. 3AJ as compared to FIG. 3AI rather than on similarities.

Multi-stack 350(10) is an example of multi-column stacked arrangement 104 of FIGS. 1B and 1C. Relative to the Y-axis, multi-stack 350(10) has a height of about 2.0*H.

Multi-stack 350(10) includes end column 342(10), middle column 344(10) and end column 340(10). Middle column 344(10) is abutted between end column 342(10) and end column 340(10). Middle column 344(10) of FIG. 3AJ corresponds to middle column 344(9) of FIG. 3AI. End column 340(10) of FIG. 3AJ corresponds to end column 340(9) of FIG. 3AI. End column 342(10) of FIG. 3AJ corresponds to end column 342(9) of FIG. 3AI.

As compared to end column 342(9) of FIG. 3AI, end column 342(10) of FIG. 3AJ includes filler cell region 324(2) of FIG. 3AA and omits cell region 328(2) of FIG. 3AI. That is, in multi-stack 350(10), filler cell region 324(2) of multi-stack 350(1) replaces cell region 328(2) of multi-stack 350(9). In end column 342(10) of FIG. 3AJ, cell region 306(1) is stacked on cell region 324(2)).

FIG. 3AK is a layout diagram of a multi-stack 350(11), in accordance with some embodiments.

FIG. 3AK is similar to FIG. 3AJ and thus also to FIG. 3AA. For purposes of brevity, the discussion will focus on differences of FIG. 3AK as compared to FIG. 3AJ rather than on similarities.

Multi-stack 350(11) is an example of multi-column stacked arrangement 104 of FIGS. 1B and 1C. Relative to the Y-axis, multi-stack 350(11) has a height of about 2.0*H.

Multi-stack 350(11) includes end column 342(11), middle column 344(11) and end column 340(11). Middle column 344(11) is abutted between end column 342(11) and end column 340(11). Middle column 344(11) of FIG. 3AK corresponds to middle column 344(10) of FIG. 3AJ. End column 340(11) of FIG. 3AK corresponds to end column 340(10) of FIG. 3AJ. End column 342(11) of FIG. 3AK corresponds to end column 342(10) of FIG. 3AJ.

As compared to end column 342(9) of FIG. 3AI, end column 342(11) of FIG. 3AK includes filler cell region 324(1) of FIG. 3AA and omits cell region 328(1) of FIG. 3AI. That is, in multi-stack 350(11), filler cell region 324(1) of multi-stack 350(1) replaces cell region 328(1) of multi-stack 350(10). In end column 342(11) of FIG. 3AK, filler cell region 324(1) is stacked on cell region 306(1).

FIG. 3AL is a layout diagram of a multi-stack 350(12), in accordance with some embodiments.

FIG. 3AL is similar to FIG. 3AC. For purposes of brevity, the discussion will focus on differences of FIG. 3AL as compared to FIG. 3AC rather than on similarities.

Multi-stack 350(12) is an example of multi-column stacked arrangement 104 of FIGS. 1B and 1C. Relative to the Y-axis, multi-stack 350(12) has a height of about 2.5*H.

Multi-stack 350(12) includes end column 342(12), middle column 344(12) and end column 340(12). Middle column 344(12) is abutted between end column 342(12) and end column 340(12). Middle column 344(12) of FIG. 3AL corresponds to middle column 344(3) of FIG. 3AC. Multi-stack 350(12) has a horizontal axis of symmetry 358(2) that bisects multi-stack 350(12). End column 340(12) of FIG. 3AL corresponds to end column 340(3) of FIG. 3AC. End column 342(12) of FIG. 3AL corresponds to end column 342(3) of FIG. 3AC.

As compared to end column 340(3) of FIG. 3AC, end column 340(12) of FIG. 3AL includes cell region 328(3) and omits filler cell region 324(3) of FIG. 3AC. That is, cell region 328(3) of multi-stack 350(12) replaces filler cell region 324(3) of multi-stack 350(3). In end column 340(12) of FIG. 3AL, cell region 328(3) is stacked on cell region 314(2).

As compared to end column 342(3) of FIG. 3AC, end column 342(12) of FIG. 3AL includes cell region 328(4) and omits filler cell region 324(4) of FIG. 3AC. That is, in multi-stack 350(12), cell region 328(4) of multi-stack 350(12) replaces filler cell region 324(4) of multi-stack 350(3). In end column 342(12) of FIG. 3AL, cell region 318(2) is stacked on cell region 324(4).

FIG. 3AM is a layout diagram of a multi-stack 350(13), in accordance with some embodiments.

FIG. 3AM is similar to FIG. 3AL and thus also to FIG. 3AC. For purposes of brevity, the discussion will focus on differences of FIG. 3AM as compared to FIG. 3AL rather than on similarities.

Multi-stack 350(13) is an example of multi-column stacked arrangement 104 of FIGS. 1B and 1C. Relative to the Y-axis, multi-stack 350(13) has a height of about 2.5*H.

Multi-stack 350(13) includes end column 342(13), middle column 344(13) and end column 340(13). Middle column 344(13) is abutted between end column 342(13) and end column 340(13). Middle column 344(13) of FIG. 3AM corresponds to middle column 344(12) of FIG. 3AL. Multi-stack 350(13) has a horizontal axis of symmetry 358(3) that bisects multi-stack 350(13). End column 340(13) of FIG. 3AM corresponds to end column 340(12) of FIG. 3AL. End column 342(13) of FIG. 3AM corresponds to end column 342(12) of FIG. 3AL.

As compared to end column 342(12) of FIG. 3AL, end column 342(13) of FIG. 3AM includes filler cell region 324(4) of FIG. 3AC and omits cell region 328(4) of FIG. 3AL. That is, in multi-stack 350(13), filler cell region 324(4) of multi-stack 350(3) replaces cell region 328(4) of multi-stack 350(12). In end column 342(13), cell region 318(2) is stacked on filler cell region 328(4).

FIG. 3AN is a layout diagram of a multi-stack 350(14), in accordance with some embodiments.

FIG. 3AN is similar to FIG. 3AM and thus also to FIG. 3AC. For purposes of brevity, the discussion will focus on differences of FIG. 3AN as compared to FIG. 3AM rather than on similarities.

Multi-stack 350(14) is an example of multi-column stacked arrangement 104 of FIGS. 1B and 1C. Relative to the Y-axis, multi-stack 350(14) has a height of about 2.5*H.

Multi-stack 350(14) includes end column 342(14), middle column 344(14) and end column 340(14). Middle column 344(14) is abutted between end column 342(14) and end column 340(14). Middle column 344(14) of FIG. 3AN corresponds to middle column 344(13) of FIG. 3AM. Multi-stack 350(14) has a horizontal axis of symmetry 358(4) that bisects multi-stack 350(14). End column 340(14) of FIG. 3AN corresponds to end column 340(13) of FIG. 3AM. End column 342(14) of FIG. 3AN corresponds to end column 342(13) of FIG. 3AM.

As compared to end column 340(13) of FIG. 3AM, end column 340(13) of FIG. 3AN includes filler cell region 324(3) of FIG. 3AL and omits cell region 328(3) of FIG. 3AM. That is, in multi-stack 350(14), filler cell region 324(3) of multi-stack 350(3) replaces cell region 328(3) of multi-stack 350(13). In end column 340(14), filler cell region 324(3) is stacked on cell region 314(2).

FIG. 3A0 is a layout diagram of a multi-stack 350(15), in accordance with some embodiments.

FIG. 3A0 is similar to FIG. 3AE. For purposes of brevity, the discussion will focus on differences of FIG. 3A0 as compared to FIG. 3AE rather than on similarities.

Multi-stack 350(15) is an example of multi-column stacked arrangement 104 of FIGS. 1B and 1C. Relative to the Y-axis, multi-stack 350(15) has a height of about 2.0*H.

Multi-stack 350(15) includes end column 342(15), middle column 344(15) and end column 340(15). Middle column 344(15) is abutted between end column 342(15) and end column 340(15). Middle column 344(15) of FIG. 3A0 corresponds to middle column 344(5) of FIG. 3AE. End column 340(15) of FIG. 3A0 corresponds to end column 340(5) of FIG. 3AE. End column 342(15) of FIG. 3A0 corresponds to end column 342(5) of FIG. 3AE.

As compared to end column 342(5) of FIG. 3AE, end column 342(15) of FIG. 3A0 includes cell regions 328(5) and 328(6) and correspondingly omits filler cell regions 324(1) and 324(2). That is, in multi-stack 350(15), cell regions 328(5) and 328(6) of multi-stack 350(15) correspondingly replace filler cell regions 324(1) and 324(2) of multi-stack 350(5). In end column 342(15), cell region 328(5) is stacked on cell region 306(1). Cell region 306(1) is stacked on cell region 328(6).

FIG. 3AP is a layout diagram of a multi-stack 350(16), in accordance with some embodiments.

FIG. 3AP is similar to FIG. 3AO and thus also to FIG. 3AE. For purposes of brevity, the discussion will focus on differences of FIG. 3AP as compared to FIG. 3AO rather than on similarities.

Multi-stack 350(16) is an example of multi-column stacked arrangement 104 of FIGS. 1B and 1C. Relative to the Y-axis, multi-stack 350(16) has a height of about 2.0*H.

Multi-stack 350(16) includes end column 342(16), middle column 344(16) and end column 340(16). Middle column 344(16) is abutted between end column 342(16) and end column 340(16). Middle column 344(16) of FIG. 3AP corresponds to middle column 344(15) of FIG. 3AO. End column 340(16) of FIG. 3AP corresponds to end column 340(15) of FIG. 3AO. End column 342(16) of FIG. 3AP corresponds to end column 342(15) of FIG. 3AO.

As compared to end column 342(15) of FIG. 3AO, end column 342(16) of FIG. 3AP includes filler cell region 324(2) of FIG. 3AE and omits cell region 328(2) of FIG. 3AO. That is, in multi-stack 350(16), filler cell region 324(2) of multi-stack 350(5) replaces cell region 328(6) of multi-stack 350(15). In end column 342(16) of FIG. 3AP, cell region 306(1) is stacked on filler cell region 324(2)).

FIG. 3AQ is a layout diagram of a multi-stack 350(17), in accordance with some embodiments.

FIG. 3AQ is similar to FIG. 3AP and thus also to FIG. 3AE. For purposes of brevity, the discussion will focus on differences of FIG. 3AQ as compared to FIG. 3AP rather than on similarities.

Multi-stack 350(17) is an example of multi-column stacked arrangement 104 of FIGS. 1B and 1C. Relative to the Y-axis, multi-stack 350(17) has a height of about 2.0*H.

Multi-stack 350(17) includes end column 342(17), middle column 344(17) and end column 340(17). Middle column 344(17) is abutted between end column 342(17) and end column 340(17). Middle column 344(17) of FIG. 3AQ corresponds to middle column 344(16) of FIG. 3AP. End column 340(17) of FIG. 3AQ corresponds to end column 340(16) of FIG. 3AP. End column 342(17) of FIG. 3AQ corresponds to end column 342(16) of FIG. 3AP.

As compared to end column 342(15) of FIG. 3AO, end column 342(17) of FIG. 3AQ includes filler cell region 324(1) of FIG. 3AE and omits cell region 328(5) of FIG. 3AO. That is, in multi-stack 350(17), filler cell region 324(1) of multi-stack 350(5) replaces cell region 328(5) of multi-stack 350(16). In end column 342(17) of FIG. 3AQ, filler cell region 324(1) is stacked on cell region 306(1).

FIG. 3AR is a layout diagram of a multi-stack 350(18), in accordance with some embodiments.

FIG. 3AR is similar to FIG. 3AG. For purposes of brevity, the discussion will focus on differences of FIG. 3AR as compared to FIG. 3AG rather than on similarities.

Multi-stack 350(18) is an example of multi-column stacked arrangement 104 of FIGS. 1B and 1C. Relative to the Y-axis, multi-stack 350(18) has a height of about 2.5*H.

Multi-stack 350(18) includes end column 342(18), middle column 344(18) and end column 340(18). Middle column 344(18) is abutted between end column 342(18) and end column 340(18). Middle column 344(18) of FIG. 3AR corresponds to middle column 344(7) of FIG. 3AG. Multi-stack 350(18) has a horizontal axis of symmetry 358(5) that bisects multi-stack 350(18). End column 340(18) of FIG. 3AR corresponds to end column 340(7) of FIG. 3AG. End column 342(18) of FIG. 3AR corresponds to end column 342(7) of FIG. 3AG.

As compared to end column 340(7) of FIG. 3AG, end column 340(18) of FIG. 3AR includes cell region 328(8) and omits filler cell region 324(3) of FIG. 3AG. That is, cell region 328(8) of multi-stack 350(18) replaces filler cell region 324(3) of multi-stack 350(7). In end column 340(18) of FIG. 3AR, cell region 328(8) is stacked on cell region 314(2).

As compared to end column 342(7) of FIG. 3AG, end column 342(18) of FIG. 3AR includes cell region 328(7) and omits filler cell region 324(4) of FIG. 3AG. That is, in multi-stack 350(18), cell region 328(7) of multi-stack 350(18) replaces filler cell region 324(4) of multi-stack 350(7). In end column 342(18) of FIG. 3AR, cell region 318(2) is stacked on cell region 324(7).

FIG. 3AS is a layout diagram of a multi-stack 350(19), in accordance with some embodiments.

FIG. 3AS is similar to FIG. 3AR and thus also to FIG. 3AG. For purposes of brevity, the discussion will focus on differences of FIG. 3AS as compared to FIG. 3AR rather than on similarities.

Multi-stack 350(19) is an example of multi-column stacked arrangement 104 of FIGS. 1B and 1C. Relative to the Y-axis, multi-stack 350(19) has a height of about 2.5*H.

Multi-stack 350(19) includes end column 342(19), middle column 344(19) and end column 340(19). Middle column 344(19) is abutted between end column 342(19) and end column 340(19). Middle column 344(19) of FIG. 3AS corresponds to middle column 344(18) of FIG. 3AR. End column 340(19) of FIG. 3AS corresponds to end column 340(18) of FIG. 3AR. End column 342(19) of FIG. 3AS corresponds to end column 342(18) of FIG. 3AR.

As compared to end column 342(18) of FIG. 3AR, end column 342(19) of FIG. 3AS includes filler cell region 324(4) of FIG. 3AG and omits cell region 328(7) of FIG. 3AR. That is, in multi-stack 350(19), filler cell region 324(4) of multi-stack 350(7) replaces cell region 328(7) of multi-stack 350(18). In end column 342(19), cell region 318(2) is stacked on filler cell region 328(4).

FIG. 3AT is a layout diagram of a multi-stack 350(20), in accordance with some embodiments.

FIG. 3AT is similar to FIG. 3AS and thus also to FIG. 3AG. For purposes of brevity, the discussion will focus on differences of FIG. 3AT as compared to FIG. 3AS rather than on similarities.

Multi-stack 350(20) is an example of multi-column stacked arrangement 104 of FIGS. 1B and 1C. Relative to the Y-axis, multi-stack 350(20) has a height of about 2.5*H.

Multi-stack 350(20) includes end column 342(20), middle column 344(20) and end column 340(20). Middle column 344(20) is abutted between end column 342(20) and end column 340(20). Middle column 344(20) of FIG. 3AT corresponds to middle column 344(19) of FIG. 3AS. End column 340(20) of FIG. 3AT corresponds to end column 340(19) of FIG. 3AS. End column 342(20) of FIG. 3AT corresponds to end column 342(19) of FIG. 3AS.

As compared to end column 340(18) of FIG. 3AS, end column 340(20) of FIG. 3AT includes filler cell region 324(3) of FIG. 3AG and omits cell region 328(8) of FIG. 3AS. That is, in multi-stack 350(20), filler cell region 324(3) of multi-stack 350(7) replaces cell region 328(8) of multi-stack 350(19). In end column 340(20), filler cell region 324(3) is stacked on cell region 314(2).

FIG. 3AU is a layout diagram of a multi-stack 350(21), in accordance with some embodiments.

FIG. 3AU is similar to FIG. 3AL. For purposes of brevity, the discussion will focus on differences of FIG. 3AU as compared to FIG. 3AL rather than on similarities.

Multi-stack 350(21) is an example of multi-column stacked arrangement 104 of FIGS. 1B and 1C. Relative to the Y-axis, multi-stack 350(21) has a height of about 2.5*H.

Multi-stack 350(21) includes end column 342(21), middle column 344(21) and end column 340(21). Middle column 344(21) is abutted between end column 342(21) and end column 340(21). Middle column 344(21) of FIG. 3AU corresponds to middle column 344(12) of FIG. 3AL. End column 340(21) of FIG. 3AU corresponds to end column 340(12) of FIG. 3AL. End column 342(21) of FIG. 3AU corresponds to end column 342(12) of FIG. 3AL. Multi-stack 350(21) has a vertical axis of symmetry 360(6).

Multi-stack 350(21) has horizontal axis of symmetry 358(2) that bisect multi-stack 350(21). Multi-stack 350(21) of FIG. 3AU is a version of multi-stack 350(12) of FIG. 3AL which has been rotated 180 degrees (180°) about horizontal axis of symmetry 358(2) with respect to the orientation of multi-stack 350(12).

FIG. 3AV is a layout diagram of a multi-stack 350(22), in accordance with some embodiments.

FIG. 3AV is similar to FIG. 3AM. For purposes of brevity, the discussion will focus on differences of FIG. 3AV as compared to FIG. 3AM rather than on similarities.

Multi-stack 350(22) is an example of multi-column stacked arrangement 104 of FIGS. 1B and 1C. Relative to the Y-axis, multi-stack 350(22) has a height of about 2.5*H.

Multi-stack 350(22) includes end column 342(22), middle column 344(22) and end column 340(22). Middle column 344(22) is abutted between end column 342(22) and end column 340(22). Middle column 344(22) of FIG. 3AV corresponds to middle column 344(13) of FIG. 3AM. End column 340(22) of FIG. 3AV corresponds to end column 340(13) of FIG. 3AM. End column 342(22) of FIG. 3AV corresponds to end column 342(13) of FIG. 3AM.

Multi-stack 350(22) has a vertical axis of symmetry 360(7). Multi-stack 350(22) has horizontal axis of symmetry 358(3) that bisects multi-stack 350(22). Multi-stack 350(22) of FIG. 3AV is a version of multi-stack 350(13) of FIG. 3AM which has been rotated 180 degrees (180°) about horizontal axis of symmetry 358(3) with respect to the orientation of multi-stack 350(13).

FIG. 3AW is a layout diagram of a multi-stack 350(23), in accordance with some embodiments.

FIG. 3AW is similar to FIG. 3AN. For purposes of brevity, the discussion will focus on differences of FIG. 3AW as compared to FIG. 3AN rather than on similarities.

Multi-stack 350(23) is an example of multi-column stacked arrangement 104 of FIGS. 1B and 1C. Relative to the Y-axis, multi-stack 350(23) has a height of about 2.5*H.

Multi-stack 350(23) includes end column 342(23), middle column 344(23) and end column 340(23). Middle column 344(23) is abutted between end column 342(23) and end column 340(23). Middle column 344(23) of FIG. 3AW corresponds to middle column 344(14) of FIG. 3AN. End column 340(23) of FIG. 3AW corresponds to end column 340(14) of FIG. 3AN. End column 342(23) of FIG. 3AW corresponds to end column 342(14) of FIG. 3AN. Multi-stack 350(26) has a vertical axis of symmetry 360(8).

Multi-stack 350(23) has horizontal axis of symmetry 358(4) that bisects multi-stack 350(23). Multi-stack 350(23) of FIG. 3AW is a version of multi-stack 350(14) of FIG. 3AN which has been rotated 180 degrees (180°) about horizontal axis of symmetry 358(4) with respect to the orientation of multi-stack 350(14).

FIG. 3AX is a layout diagram of a multi-stack 350(24), in accordance with some embodiments.

FIG. 3AX is similar to FIG. 3AU. For purposes of brevity, the discussion will focus on differences of FIG. 3AX as compared to FIG. 3AU rather than on similarities.

Multi-stack 350(24) is an example of multi-column stacked arrangement 104 of FIGS. 1B and 1C. Relative to the Y-axis, multi-stack 350(24) has a height of about 2.5*H.

Multi-stack 350(24) includes end column 342(24), middle column 344(24) and end column 340(24). Middle column 344(24) is abutted between end column 342(24) and end column 340(24). Middle column 344(24) of FIG. 3AX corresponds to middle column 344(22) of FIG. 3AU. End column 342(24) of FIG. 3AX corresponds to end column 342(22) of FIG. 3AU. End column 340(24) of FIG. 3AX corresponds to end column 340(22) of FIG. 3AU.

Multi-stack 350(24) has vertical axis of symmetry 360(6). Multi-stack 350(24) of FIG. 3AX is a version of multi-stack 350(22) of FIG. 3AU which has been rotated 180 degrees (180°) about vertical axis of symmetry 360(6) with respect to the orientation of multi-stack 350(22).

FIG. 3AY is a layout diagram of a multi-stack 350(25), in accordance with some embodiments.

FIG. 3AY is similar to FIG. 3AV. For purposes of brevity, the discussion will focus on differences of FIG. 3AY as compared to FIG. 3AV rather than on similarities.

Multi-stack 350(25) is an example of multi-column stacked arrangement 104 of FIGS. 1B and 1C. Relative to the Y-axis, multi-stack 350(25) has a height of about 2.5*H.

Multi-stack 350(25) includes end column 342(25), middle column 344(25) and end column 340(25). Middle column 344(25) is abutted between end column 342(25) and end column 340(25). Middle column 344(25) of FIG. 3AY corresponds to middle column 344(22) of FIG. 3AV. End column 342(25) of FIG. 3AY corresponds to end column 342(22) of FIG. 3AV. End column 340(25) of FIG. 3AY corresponds to end column 340(22) of FIG. 3AV.

Multi-stack 350(25) has vertical axis of symmetry 360(7). Multi-stack 350(25) of FIG. 3AY is a version of multi-stack 350(22) of FIG. 3AV which has been rotated 180 degrees (180°) about vertical axis of symmetry 360(7) with respect to the orientation of multi-stack 350(22).

FIG. 3AZ is a layout diagram of a multi-stack 350(26), in accordance with some embodiments.

FIG. 3AZ is similar to FIG. 3AW. For purposes of brevity, the discussion will focus on differences of FIG. 3AZ as compared to FIG. 3AW rather than on similarities.

Multi-stack 350(26) is an example of multi-column stacked arrangement 104 of FIGS. 1B and 1C. Relative to the Y-axis, multi-stack 350(26) has a height of about 2.5*H.

Multi-stack 350(26) includes end column 342(26), middle column 344(26) and end column 340(26). Middle column 344(26) is abutted between end column 342(26) and end column 340(26). Middle column 344(26) of FIG. 3AZ corresponds to middle column 344(23) of FIG. 3AW. End column 342(26) of FIG. 3AZ corresponds to end column 342(23) of FIG. 3AW. End column 340(26) of FIG. 3AZ corresponds to end column 340(23) of FIG. 3AW.

Multi-stack 350(26) has vertical axis of symmetry 360(8). Multi-stack 350(26) of FIG. 3AZ is a version of multi-stack 350(23) of FIG. 3AW which has been rotated 180 degrees (180°) about vertical axis of symmetry 360(8) with respect to the orientation of multi-stack 350(23).

FIG. 3BA is a layout diagram of a multi-stack 350(27), in accordance with some embodiments.

Multi-stack 350(27) is an example of multi-column stacked arrangement 104 of FIGS. 1B and 1C. Relative to the Y-axis, multi-stack 350(27) has a height of about 2.0*H.

Multi-stack 350(27) includes end column 342(27), middle column 344(27) and end column 340(27). Middle column 344(27) is abutted between end column 342(27) and end column 340(27). Multi-stack 350(27) has a vertical axis of symmetry 360(9) that bisects middle column 344(27) and thus bisects multi-stack 350(27); and a horizontal axis of symmetry 358(6) that bisects multi-stack 350(27).

Middle column 344(27) includes abutted dummy CRs 334(1) and 336(1). Dummy CR 334(1) is abutted to end column 342(27). Dummy CR 336(1) is abutted to end column 340(27). End column 342(27) includes cell regions 306(4) and 306(5). Cell region 306(4) is stacked on cell region 306(3).

End column 342(27) includes filler cell region 324(5) and cell region 310(1). Cell region 310(1) is example of either cell region 210PN of FIG. 2C or cell region 210NP of FIG. 2D. More generally, in FIG. 3BA and in other figures disclosed herein, a reference number of the type “310(x),” where x represents an index number, e.g., 310(1), denotes an example of either 210PN of FIG. 2C or cell region 210NP of FIG. 2D.

FIG. 3BB is a layout diagram of a multi-stack 350(28), in accordance with some embodiments.

FIG. 3BB is similar to FIG. 3BA. For purposes of brevity, the discussion will focus on differences of FIG. 3BB as compared to FIG. 3BA rather than on similarities.

Multi-stack 350(28) is an example of multi-column stacked arrangement 104 of FIGS. 1B and 1C. Relative to the Y-axis, multi-stack 350(28) has a height of about 2.0*H.

Multi-stack 350(28) includes end column 342(28), middle column 344(28) and end column 340(28). Middle column 344(28) is abutted between end column 342(28) and end column 340(28). Middle column 344(28) of FIG. 3BB corresponds to middle column 344(27) of FIG. 3BA. End column 342(28) of FIG. 3BB corresponds to end column 342(27) of FIG. 3BA. End column 340(28) of FIG. 3BB corresponds to end column 340(27) of FIG. 3BA.

Multi-stack 350(28) has vertical axis of symmetry 360(9). Multi-stack 350(28) of FIG. 3BB is a version of multi-stack 350(27) of FIG. 3BA which has been rotated 180 degrees (180°) about vertical axis of symmetry 360(9) with respect to the orientation of multi-stack 350(27).

FIG. 3BC is a layout diagram of a multi-stack 350(29), in accordance with some embodiments.

Multi-stack 350(29) is an example of multi-column stacked arrangement 104 of FIGS. 1B and 1C. Relative to the Y-axis, multi-stack 350(29) has a height of about 2.5*H.

Multi-stack 350(29) includes end column 342(29), middle column 344(29) and end column 340(29). Middle column 344(29) is abutted between end column 342(29) and end column 340(29).

Multi-stack 350(29) has: a vertical axis of symmetry 360(10) that bisects middle column 344(29) and thus bisects multi-stack 350(29); and a horizontal axis of symmetry 358(7) that bisects multi-stack 350(29).

Middle column 344(29) includes dummy CRs 332(2) and 336(2). Dummy CR 332(2) is abutted to end column 342(29). Dummy CR 336(2) is abutted to end column 340(29). End column 340(29) includes filler cell region 324(6) and cell region 310(2). Filler cell region 324(6) is stacked on cell region 310(2). End column 342(29) includes cell region 314(3).

FIG. 3BD is a layout diagram of a multi-stack 350(30), in accordance with some embodiments.

FIG. 3BD is similar to FIG. 3BC. For purposes of brevity, the discussion will focus on differences of FIG. 3BD as compared to FIG. 3BC rather than on similarities.

Multi-stack 350(30) is an example of multi-column stacked arrangement 104 of FIGS. 1B and 1C. Relative to the Y-axis, multi-stack 350(30) has a height of about 2.0*H.

Multi-stack 350(30) includes end column 342(30), middle column 344(30) and end column 340(30). Middle column 344(30) is abutted between end column 342(30) and end column 340(30). Middle column 344(30) of FIG. 3BD corresponds to middle column 344(29) of FIG. 3BC. End column 342(30) of FIG. 3BD corresponds to end column 342(29) of FIG. 3BC. End column 340(30) of FIG. 3BD corresponds to end column 340(29) of FIG. 3BC.

Multi-stack 350(30) has: vertical axis of symmetry 360(10); and a horizontal axis of symmetry 358(8) that bisects multi-stack 350(30). Multi-stack 350(30) of FIG. 3BD is a version of multi-stack 350(29) of FIG. 3BC which has been rotated 180 degrees (180°) about vertical axis of symmetry 360(10) with respect to the orientation of multi-stack 350(29).

FIG. 3BE is a layout diagram of a multi-stack 350(31), in accordance with some embodiments.

Multi-stack 350(31) is an example of multi-column stacked arrangement 104 of FIGS. 1B and 1C. Relative to the Y-axis, multi-stack 350(31) has a height of about 2.5*H.

Multi-stack 350(31) includes end column 342(31), middle column 344(31) and end column 340(31). Middle column 344(31) is abutted between end column 342(31) and end column 340(31).

Multi-stack 350(31) has: a vertical axis of symmetry 360(11) that bisects middle column 344(31) and thus bisects multi-stack 350(31); and a horizontal axis of symmetry 358(9) that bisects multi-stack 350(31).

Middle column 344(31) includes dummy CRs 334(2) and 336(3). Dummy CR 332(3) is abutted to end column 342(31). Dummy CR 336(3) is abutted to end column 340(31). End column 340(31) includes filler cell region 324(7) and cell region 310(3). Filler cell region 324(7) is stacked on cell region 310(3). End column 342(31) includes cell region 318(3).

FIG. 3BF is a layout diagram of a multi-stack 350(32), in accordance with some embodiments.

FIG. 3BF is similar to FIG. 3BE. For purposes of brevity, the discussion will focus on differences of FIG. 3BF as compared to FIG. 3BE rather than on similarities.

Multi-stack 350(32) is an example of multi-column stacked arrangement 104 of FIGS. 1B and 1C. Relative to the Y-axis, multi-stack 350(32) has a height of about 2.0*H.

Multi-stack 350(32) includes end column 342(32), middle column 344(32) and end column 340(32). Middle column 344(32) is abutted between end column 342(32) and end column 340(32). Middle column 344(32) of FIG. 3BF corresponds to middle column 344(31) of FIG. 3BE. End column 342(32) of FIG. 3BF corresponds to end column 342(31) of FIG. 3BE. End column 340(32) of FIG. 3BF corresponds to end column 340(31) of FIG. 3BE.

Multi-stack 350(32) has: vertical axis of symmetry 360(10); and a horizontal axis of symmetry 358(10) that bisects multi-stack 350(32). Multi-stack 350(32) of FIG. 3BF is a version of multi-stack 350(31) of FIG. 3BE which has been rotated 180 degrees (180°) about vertical axis of symmetry 360(10) with respect to the orientation of multi-stack 350(31).

FIG. 3BG is a layout diagram of a multi-stack 350(33), in accordance with some embodiments.

FIG. 3BG is similar to FIG. 3BA. For purposes of brevity, the discussion will focus on differences of FIG. 3BG as compared to FIG. 3BA rather than on similarities.

Multi-stack 350(33) is an example of multi-column stacked arrangement 104 of FIGS. 1B and 1C. Relative to the Y-axis, multi-stack 350(33) has a height of about 2.0*H.

Multi-stack 350(33) includes end column 342(33), middle column 344(33) and end column 340(33). Middle column 344(33) is abutted between end column 342(33) and end column 340(33). Middle column 344(33) of FIG. 3BG corresponds to middle column 344(27) of FIG. 3BA. End column 342(33) of FIG. 3BG corresponds to end column 342(27) of FIG. 3BA. End column 340(33) of FIG. 3BG corresponds to end column 340(27) of FIG. 3BA.

Multi-stack 350(33) has: a vertical axis of symmetry 360(12) that bisects middle column 344(33) and thus bisects multi-stack 350(33); and horizontal axis of symmetry 358(6) that bisects multi-stack 350(33). Multi-stack 350(33) of FIG. 3BG is a version of multi-stack 350(27) of FIG. 3BA which has been rotated 180 degrees (180°) about vertical axis of symmetry 360(10) with respect to the orientation of multi-stack 350(27).

FIG. 3BH is a layout diagram of a multi-stack 350(34), in accordance with some embodiments.

FIG. 3BH is similar to FIG. 3BG. For purposes of brevity, the discussion will focus on differences of FIG. 3BH as compared to FIG. 3BG rather than on similarities.

Multi-stack 350(34) is an example of multi-column stacked arrangement 104 of FIGS. 1B and 1C. Relative to the Y-axis, multi-stack 350(34) has a height of about 2.0*H.

Multi-stack 350(34) includes end column 342(34), middle column 344(34) and end column 340(34). Middle column 344(34) is abutted between end column 342(34) and end column 340(34). Middle column 344(34) of FIG. 3BH corresponds to middle column 344(33) of FIG. 3BG. End column 342(34) of FIG. 3BH corresponds to end column 342(33) of FIG. 3BG. End column 340(34) of FIG. 3BH corresponds to end column 340(33) of FIG. 3BG.

Multi-stack 350(34) has vertical axis of symmetry 360(12). Multi-stack 350(34) of FIG. 3BH is a version of multi-stack 350(33) of FIG. 3BG which has been rotated 180 degrees (180°) about vertical axis of symmetry 360(12) with respect to the orientation of multi-stack 350(33).

FIG. 3BI is a layout diagram of a multi-stack 350(35), in accordance with some embodiments.

FIG. 3BI is similar to FIG. 3BC. For purposes of brevity, the discussion will focus on differences of FIG. 3BI as compared to FIG. 3BC rather than on similarities.

Multi-stack 350(35) is an example of multi-column stacked arrangement 104 of FIGS. 1B and 1C. Relative to the Y-axis, multi-stack 350(35) has a height of about 2.0*H.

Multi-stack 350(35) includes end column 342(35), middle column 344(35) and end column 340(35). Middle column 344(35) is abutted between end column 342(35) and end column 340(35). Middle column 344(35) of FIG. 3BI corresponds to middle column 344(29) of FIG. 3BC. End column 342(35) of FIG. 3BI corresponds to end column 342(29) of FIG. 3BC. End column 340(35) of FIG. 3BI corresponds to end column 340(29) of FIG. 3BC.

Multi-stack 350(35) has: a vertical axis of symmetry 360(13) that bisects middle column 344(35) and thus bisects multi-stack 350(35); and horizontal axis of symmetry 358(7) that bisects multi-stack 350(35). Multi-stack 350(35) of FIG. 3BI is a version of multi-stack 350(29) of FIG. 3BC which has been rotated 180 degrees (180°) about horizontal axis of symmetry 358(7) with respect to the orientation of multi-stack 350(29).

FIG. 3BJ is a layout diagram of a multi-stack 350(36), in accordance with some embodiments.

FIG. 3BJ is similar to FIG. 3BI. For purposes of brevity, the discussion will focus on differences of FIG. 3BJ as compared to FIG. 3BI rather than on similarities.

Multi-stack 350(36) is an example of multi-column stacked arrangement 104 of FIGS. 1B and 1C. Relative to the Y-axis, multi-stack 350(36) has a height of about 2.0*H.

Multi-stack 350(36) includes end column 342(36), middle column 344(36) and end column 340(36). Middle column 344(36) is abutted between end column 342(36) and end column 340(36). Middle column 344(36) of FIG. 3BJ corresponds to middle column 344(35) of FIG. 3BI. End column 342(36) of FIG. 3BJ corresponds to end column 342(35) of FIG. 3BI. End column 340(36) of FIG. 3BJ corresponds to end column 340(35) of FIG. 3BI.

Multi-stack 350(36) has vertical axis of symmetry 360(13). Multi-stack 350(36) of FIG. 3BJ is a version of multi-stack 350(35) of FIG. 3BI which has been rotated 180 degrees (180°) about vertical axis of symmetry 360(13) with respect to the orientation of multi-stack 350(35).

FIG. 3BK is a layout diagram of a multi-stack 350(37), in accordance with some embodiments.

FIG. 3BK is similar to FIG. 3BE. For purposes of brevity, the discussion will focus on differences of FIG. 3BK as compared to FIG. 3BE rather than on similarities.

Multi-stack 350(37) is an example of multi-column stacked arrangement 104 of FIGS. 1B and 1C. Relative to the Y-axis, multi-stack 350(37) has a height of about 2.0*H.

Multi-stack 350(37) includes end column 342(37), middle column 344(37) and end column 340(37). Middle column 344(37) is abutted between end column 342(37) and end column 340(37). Middle column 344(37) of FIG. 3BK corresponds to middle column 344(31) of FIG. 3BE. End column 342(37) of FIG. 3BK corresponds to end column 342(31) of FIG. 3BE. End column 340(37) of FIG. 3BK corresponds to end column 340(31) of FIG. 3BE.

Multi-stack 350(37) has horizontal axis of symmetry 358(9) that bisects multi-stack 350(37). Multi-stack 350(37) of FIG. 3BK is a version of multi-stack 350(31) of FIG. 3BE which has been rotated 180 degrees (180°) about horizontal axis of symmetry 358(9) with respect to the orientation of multi-stack 350(31).

FIG. 3BL is a layout diagram of a multi-stack 350(38), in accordance with some embodiments.

FIG. 3BL is similar to FIG. 3BF. FIG. 3BL is also similar to FIG. 3BK. For purposes of brevity, the discussion will focus on differences of FIG. 3BL as compared to FIG. 3BF rather than on similarities.

Multi-stack 350(38) is an example of multi-column stacked arrangement 104 of FIGS. 1B and 1C. Relative to the Y-axis, multi-stack 350(38) has a height of about 2.0*H.

Multi-stack 350(38) includes end column 342(38), middle column 344(38) and end column 340(38). Middle column 344(38) is abutted between end column 342(38) and end column 340(38). Middle column 344(38) of FIG. 3BL corresponds to middle column 344(32) of FIG. 3BF. End column 342(38) of FIG. 3BL corresponds to end column 342(32) of FIG. 3BF. End column 340(38) of FIG. 3BL corresponds to end column 340(32) of FIG. 3BF.

Multi-stack 350(38) has horizontal axis of symmetry 358(10) that bisects multi-stack 350(38). Multi-stack 350(38) of FIG. 3BL is a version of multi-stack 350(32) of FIG. 3BF which has been rotated 180 degrees (180°) about horizontal axis of symmetry 358(10) with respect to the orientation of multi-stack 350(32).

FIG. 3BM is a layout diagram of a multi-stack 350(39), in accordance with some embodiments.

FIG. 3BM is similar to FIG. 3BA. For purposes of brevity, the discussion will focus on differences of FIG. 3BM as compared to FIG. 3BA rather than on similarities.

Multi-stack 350(39) is an example of multi-column stacked arrangement 104 of FIGS. 1B and 1C. Relative to the Y-axis, multi-stack 350(39) has a height of about 2.0*H.

Multi-stack 350(39) includes end column 342(39), middle column 344(39) and end column 340(39). Middle column 344(39) is abutted between end column 342(39) and end column 340(39). Middle column 344(39) of FIG. 3BM corresponds to middle column 344(27) of FIG. 3BA. End column 340(39) of FIG. 3BM corresponds to end column 340(27) of FIG. 3BA. End column 342(39) of FIG. 3BM corresponds to end column 342(27) of FIG. 3BA.

Multi-stack 350(39) has: a vertical axis of symmetry 360(14) that bisects middle column 344(39) and thus bisects multi-stack 350(39); and a horizontal axis of symmetry 358(11) that bisects multi-stack 350(39).

As compared to end column 342(27) of FIG. 3BA, end column 342(39) of FIG. 3BM includes cell region 328(10) and correspondingly omits filler cell region and 324(5). That is, in multi-stack 350(39), cell region 328(10) of multi-stack 350(39) correspondingly replaces filler cell region 324(5) of multi-stack 350(27). In end column 342(39), cell region 328(10) is stacked on cell region 310(1).

FIG. 3BN is a layout diagram of a multi-stack 350(40), in accordance with some embodiments.

FIG. 3BN is similar to FIG. 3BM. For purposes of brevity, the discussion will focus on differences of FIG. 3BN as compared to FIG. 3BM rather than on similarities.

Multi-stack 350(40) is an example of multi-column stacked arrangement 104 of FIGS. 1B and 1C. Relative to the Y-axis, multi-stack 350(40) has a height of about 2.0*H.

Multi-stack 350(40) includes end column 342(40), middle column 344(40) and end column 340(40). Middle column 344(40) is abutted between end column 342(40) and end column 340(40). Middle column 344(40) of FIG. 3BN corresponds to middle column 344(39) of FIG. 3BM. End column 342(40) of FIG. 3BN corresponds to end column 342(39) of FIG. 3BM. End column 340(40) of FIG. 3BN corresponds to end column 340(39) of FIG. 3BM.

Multi-stack 350(40) has vertical axis of symmetry 360(14). Multi-stack 350(40) of FIG. 3BN is a version of multi-stack 350(39) of FIG. 3BM which has been rotated 180 degrees (180°) about vertical axis of symmetry 360(14) with respect to the orientation of multi-stack 350(39).

FIG. 3BO is a layout diagram of a multi-stack 350(41), in accordance with some embodiments.

FIG. 3BO is similar to FIG. 3BC. For purposes of brevity, the discussion will focus on differences of FIG. 3BO as compared to FIG. 3BC rather than on similarities.

Multi-stack 350(41) is an example of multi-column stacked arrangement 104 of FIGS. 1B and 1C. Relative to the Y-axis, multi-stack 350(41) has a height of about 2.0*H.

Multi-stack 350(41) includes end column 342(41), middle column 344(41) and end column 340(41). Middle column 344(41) is abutted between end column 342(41) and end column 340(41). Middle column 344(41) of FIG. 3BO corresponds to middle column 344(29) of FIG. 3BC. End column 340(41) of FIG. 3BO corresponds to end column 340(29) of FIG. 3BC. End column 342(41) of FIG. 3BO corresponds to end column 342(29) of FIG. 3BC.

Multi-stack 350(41) has: a vertical axis of symmetry 360(15) that bisects middle column 344(41) and thus bisects multi-stack 350(41); and a horizontal axis of symmetry 358(12) that bisects multi-stack 350(41).

As compared to end column 340(29) of FIG. 3BC, end column 342(41) of FIG. 3BO includes cell region 328(11) and correspondingly omits filler cell region and 324(6). That is, in multi-stack 350(41), cell region 328(11) of multi-stack 350(41) correspondingly replaces filler cell region 324(6) of multi-stack 350(29). In end column 340(41), cell region 328(11) is stacked on cell region 310(2).

FIG. 3BP is a layout diagram of a multi-stack 350(42), in accordance with some embodiments.

FIG. 3BP is similar to FIG. 3BO. For purposes of brevity, the discussion will focus on differences of FIG. 3BP as compared to FIG. 3BO rather than on similarities.

Multi-stack 350(42) is an example of multi-column stacked arrangement 104 of FIGS. 1B and 1C. Relative to the Y-axis, multi-stack 350(42) has a height of about 2.0*H.

Multi-stack 350(42) includes end column 342(42), middle column 344(42) and end column 340(42). Middle column 344(42) is abutted between end column 342(42) and end column 340(42). Middle column 344(42) of FIG. 3BP corresponds to middle column 344(41) of FIG. 3BO. End column 342(42) of FIG. 3BP corresponds to end column 342(41) of FIG. 3BO. End column 340(42) of FIG. 3BP corresponds to end column 340(41) of FIG. 3BO.

Multi-stack 350(42) has vertical axis of symmetry 360(15). Multi-stack 350(42) of FIG. 3BP is a version of multi-stack 350(41) of FIG. 3BO which has been rotated 180 degrees (180°) about vertical axis of symmetry 360(15) with respect to the orientation of multi-stack 350(41).

FIG. 3BQ is a layout diagram of a multi-stack 350(43), in accordance with some embodiments.

FIG. 3BQ is similar to FIG. 3BE. For purposes of brevity, the discussion will focus on differences of FIG. 3BQ as compared to FIG. 3BE rather than on similarities.

Multi-stack 350(43) is an example of multi-column stacked arrangement 104 of FIGS. 1B and 1C. Relative to the Y-axis, multi-stack 350(43) has a height of about 2.0*H.

Multi-stack 350(43) includes end column 342(43), middle column 344(43) and end column 340(43). Middle column 344(43) is abutted between end column 342(43) and end column 340(43). Middle column 344(43) of FIG. 3BQ corresponds to middle column 344(31) of FIG. 3BE. End column 340(43) of FIG. 3BQ corresponds to end column 340(31) of FIG. 3BE. End column 342(43) of FIG. 3BQ corresponds to end column 342(31) of FIG. 3BE.

Multi-stack 350(43) has: a vertical axis of symmetry 360(15) that bisects middle column 344(43) and thus bisects multi-stack 350(43); and a horizontal axis of symmetry 358(13) that bisects multi-stack 350(43).

As compared to end column 340(31) of FIG. 3BE, end column 342(43) of FIG. 3BQ includes cell region 328(12) and correspondingly omits filler cell region and 324(7). That is, in multi-stack 350(43), cell region 328(12) of multi-stack 350(43) correspondingly replaces filler cell region 324(7) of multi-stack 350(31). In end column 340(43), cell region 328(12) is stacked on cell region 310(3).

FIG. 3BR is a layout diagram of a multi-stack 350(44), in accordance with some embodiments.

FIG. 3BR is similar to FIG. 3BQ. For purposes of brevity, the discussion will focus on differences of FIG. 3BR as compared to FIG. 3BQ rather than on similarities.

Multi-stack 350(44) is an example of multi-column stacked arrangement 104 of FIGS. 1B and 1C. Relative to the Y-axis, multi-stack 350(44) has a height of about 2.0*H.

Multi-stack 350(44) includes end column 342(44), middle column 344(44) and end column 340(44). Middle column 344(44) is abutted between end column 342(44) and end column 340(44). Middle column 344(44) of FIG. 3BR corresponds to middle column 344(43) of FIG. 3BQ. End column 342(44) of FIG. 3BR corresponds to end column 342(43) of FIG. 3BQ. End column 340(44) of FIG. 3BR corresponds to end column 340(43) of FIG. 3BQ.

Multi-stack 350(44) has vertical axis of symmetry 360(16). Multi-stack 350(44) of FIG. 3BR is a version of multi-stack 350(43) of FIG. 3BQ which has been rotated 180 degrees (180°) about vertical axis of symmetry 360(16) with respect to the orientation of multi-stack 350(43).

FIG. 3BS is a layout diagram of a multi-stack 350(45), in accordance with some embodiments.

FIG. 3BS is similar to FIG. 3BM. FIG. 3BS is also similar to FIG. 3BK. For purposes of brevity, the discussion will focus on differences of FIG. 3BS as compared to FIG. 3BM rather than on similarities.

Multi-stack 350(45) is an example of multi-column stacked arrangement 104 of FIGS. 1B and 1C. Relative to the Y-axis, multi-stack 350(45) has a height of about 2.0*H.

Multi-stack 350(45) includes end column 342(45), middle column 344(45) and end column 340(45). Middle column 344(45) is abutted between end column 342(45) and end column 340(45). Middle column 344(45) of FIG. 3BS corresponds to middle column 344(39) of FIG. 3BM. End column 342(45) of FIG. 3BS corresponds to end column 342(39) of FIG. 3BM. End column 340(45) of FIG. 3BS corresponds to end column 340(39) of FIG. 3BM.

Multi-stack 350(45) has: a vertical axis of symmetry 360(17) that bisects middle column 344(45) and thus bisects multi-stack 350(45); and horizontal axis of symmetry 358(11) that bisects multi-stack 350(45). Multi-stack 350(45) of FIG. 3BS is a version of multi-stack 350(39) of FIG. 3BM which has been rotated 180 degrees (180°) about horizontal axis of symmetry 358(11) with respect to the orientation of multi-stack 350(39).

FIG. 3BT is a layout diagram of a multi-stack 350(46), in accordance with some embodiments.

FIG. 3BT is similar to FIG. 3BS. For purposes of brevity, the discussion will focus on differences of FIG. 3BT as compared to FIG. 3BS rather than on similarities.

Multi-stack 350(46) is an example of multi-column stacked arrangement 104 of FIGS. 1B and 1C. Relative to the Y-axis, multi-stack 350(46) has a height of about 2.0*H.

Multi-stack 350(46) includes end column 342(46), middle column 344(46) and end column 340(46). Middle column 344(46) is abutted between end column 342(46) and end column 340(46). Middle column 344(46) of FIG. 3BT corresponds to middle column 344(45) of FIG. 3BS. End column 342(46) of FIG. 3BT corresponds to end column 342(45) of FIG. 3BS. End column 340(46) of FIG. 3BT corresponds to end column 340(45) of FIG. 3BS.

Multi-stack 350(46) has vertical axis of symmetry 360(17). Multi-stack 350(46) of FIG. 3BT is a version of multi-stack 350(45) of FIG. 3BS which has been rotated 180 degrees (180°) about vertical axis of symmetry 360(17) with respect to the orientation of multi-stack 350(45).

FIG. 3BU is a layout diagram of a multi-stack 350(47), in accordance with some embodiments.

FIG. 3BU is similar to FIG. 3BO. FIG. 3BU is also similar to FIG. 3BP. For purposes of brevity, the discussion will focus on differences of FIG. 3BU as compared to FIG. 3BO rather than on similarities.

Multi-stack 350(47) is an example of multi-column stacked arrangement 104 of FIGS. 1B and 1C. Relative to the Y-axis, multi-stack 350(47) has a height of about 2.0*H.

Multi-stack 350(47) includes end column 342(47), middle column 344(47) and end column 340(47). Middle column 344(47) is abutted between end column 342(47) and end column 340(47). Middle column 344(47) of FIG. 3BU corresponds to middle column 344(41) of FIG. 3BO. End column 342(47) of FIG. 3BU corresponds to end column 342(41) of FIG. 3BO. End column 340(47) of FIG. 3BU corresponds to end column 340(41) of FIG. 3BO.

Multi-stack 350(47) has: a vertical axis of symmetry 360(18) that bisects middle column 344(47) and thus bisects multi-stack 350(47); and horizontal axis of symmetry 358(12) that bisects multi-stack 350(47). Multi-stack 350(47) of FIG. 3BU is a version of multi-stack 350(41) of FIG. 3BO which has been rotated 180 degrees (180°) about horizontal axis of symmetry 358(11) with respect to the orientation of multi-stack 350(41).

FIG. 3BV is a layout diagram of a multi-stack 350(48), in accordance with some embodiments.

FIG. 3BV is similar to FIG. 3BU. FIG. 3BV is also similar to FIG. 3BP. For purposes of brevity, the discussion will focus on differences of FIG. 3BV as compared to FIG. 3BU rather than on similarities.

Multi-stack 350(48) is an example of multi-column stacked arrangement 104 of FIGS. 1B and 1C. Relative to the Y-axis, multi-stack 350(48) has a height of about 2.0*H.

Multi-stack 350(48) includes end column 342(48), middle column 344(48) and end column 340(48). Middle column 344(48) is abutted between end column 342(48) and end column 340(48). Middle column 344(48) of FIG. 3BV corresponds to middle column 344(47) of FIG. 3BU. End column 342(48) of FIG. 3BV corresponds to end column 342(47) of FIG. 3BU. End column 340(48) of FIG. 3BV corresponds to end column 340(47) of FIG. 3BU.

Multi-stack 350(48) has vertical axis of symmetry 360(18) that bisects middle column 344(48) and thus bisects multi-stack 350(48). Multi-stack 350(48) of FIG. 3BV is a version of multi-stack 350(47) of FIG. 3BU which has been rotated 180 degrees (180°) about vertical axis of symmetry 360(18) with respect to the orientation of multi-stack 350(47).

FIG. 3BW is a layout diagram of a multi-stack 350(49), in accordance with some embodiments.

FIG. 3BW is similar to FIG. 3BQ. FIG. 3BW is also similar to FIG. 3BP. For purposes of brevity, the discussion will focus on differences of FIG. 3BW as compared to FIG. 3BQ rather than on similarities.

Multi-stack 350(49) is an example of multi-column stacked arrangement 104 of FIGS. 1B and 1C. Relative to the Y-axis, multi-stack 350(49) has a height of about 2.0*H.

Multi-stack 350(49) includes end column 342(49), middle column 344(49) and end column 340(49). Middle column 344(49) is abutted between end column 342(49) and end column 340(49). Middle column 344(49) of FIG. 3BW corresponds to middle column 344(43) of FIG. 3BQ. End column 342(49) of FIG. 3BW corresponds to end column 342(43) of FIG. 3BQ. End column 340(49) of FIG. 3BW corresponds to end column 340(43) of FIG. 3BQ.

Multi-stack 350(49) has: a vertical axis of symmetry 360(19) that bisects middle column 344(49) and thus bisects multi-stack 350(49); and horizontal axis of symmetry 358(13) that bisects multi-stack 350(49). Multi-stack 350(49) of FIG. 3BW is a version of multi-stack 350(43) of FIG. 3BQ which has been rotated 180 degrees (180°) about horizontal axis of symmetry 358(13) with respect to the orientation of multi-stack 350(43).

FIG. 3BX is a layout diagram of a multi-stack 350(50), in accordance with some embodiments.

FIG. 3BX is similar to FIG. 3BW. FIG. 3BX is also similar to FIG. 3BW. For purposes of brevity, the discussion will focus on differences of FIG. 3BX as compared to FIG. 3BW rather than on similarities.

Multi-stack 350(50) is an example of multi-column stacked arrangement 104 of FIGS. 1B and 1C. Relative to the Y-axis, multi-stack 350(50) has a height of about 2.0*H.

Multi-stack 350(50) includes end column 342(50), middle column 344(50) and end column 340(50). Middle column 344(50) is abutted between end column 342(50) and end column 340(50). Middle column 344(50) of FIG. 3BX corresponds to middle column 344(49) of FIG. 3BW. End column 342(50) of FIG. 3BX corresponds to end column 342(49) of FIG. 3BW. End column 340(50) of FIG. 3BX corresponds to end column 340(49) of FIG. 3BW.

Multi-stack 350(50) has vertical axis of symmetry 360(19) that bisects middle column 344(50) and thus bisects multi-stack 350(50). Multi-stack 350(50) of FIG. 3BX is a version of multi-stack 350(49) of FIG. 3BW which has been rotated 180 degrees (180°) about vertical axis of symmetry 360(19) with respect to the orientation of multi-stack 350(49).

FIG. 3BY is a layout diagram of a multi-stack 350(51), in accordance with some embodiments.

Multi-stack 350(51) is an example of multi-column stacked arrangement 104 of FIGS. 1B and 1C. Relative to the Y-axis, multi-stack 350(51) has a height of about 3.0*H.

Multi-stack 350(51) includes end column 342(51), middle column 344(51) and end column 340(51). Middle column 344(51) is abutted between end column 342(51) and end column 340(51). Multi-stack 350(51) has a vertical axis of symmetry 360(19) that bisects middle column 344(51) and thus bisects multi-stack 350(51).

Middle column 344(51) includes abutted dummy CRs 338(1) and 339(1). Dummy CR 338(1) is abutted to end column 342(51). Dummy CR 339(1) is abutted to end column 340(51). Dummy CR 338(1) is an example of dummy CR 238 of FIG. 2P. More generally, in FIG. 3BY and in other figures disclosed herein, a reference number of the type “338(x),” where x represents an index number, e.g., 338(1), denotes an example of dummy CR 238 of FIG. 2P. Dummy CR 339(1) is an example of dummy CR 239(1) of FIG. 2P. More generally, in FIG. 3BY and in other figures disclosed herein, a reference number of the type “339(x),” where x represents an index number, e.g., 339(1), denotes an example of dummy CR 239(1) of FIG. 2P. End column 342(51) includes cell regions 306(6), 306(7) and 306(8) stacked on each other. Cell region 306(7) is stacked on cell region 306(8). Cell region 306(6) is stacked on cell region 306(7). End column 340(51) includes cell regions 310(5) and 310(6). Cell region 310(5) is stacked on cell region 310(6).

FIG. 3BZ is a layout diagram of a multi-stack 350(52), in accordance with some embodiments.

Multi-stack 350(52) is an example of multi-column stacked arrangement 104 of FIGS. 1B and 1C. Relative to the Y-axis, multi-stack 350(52) has a height of about 3.0*H.

Multi-stack 350(52) includes end column 342(52), middle column 344(52) and end column 340(52). Middle column 344(52) is abutted between end column 342(52) and end column 340(52). Multi-stack 350(52) has a vertical axis of symmetry 360(19) that bisects middle column 344(52) and thus bisects multi-stack 350(52).

Middle column 344(52) includes abutted dummy CRs 338(2) and 339(2). Dummy CR 338(2) is abutted to end column 342(52). Dummy CR 339(2) is abutted to end column 340(52). End column 342(52) includes cell regions 328(13), 314(4) and 328(14) stacked on each other. Cell region 314(4) is stacked on cell region 328(14). Cell region 328(13) is stacked on cell region 314(4). End column 340(52) includes cell regions 310(7) and 310(8). Cell region 310(7) is stacked on cell region 310(8).

FIG. 3CA is a layout diagram of a multi-stack 350(53), in accordance with some embodiments.

Multi-stack 350(53) is an example of multi-column stacked arrangement 104 of FIGS. 1B and 1C. Relative to the Y-axis, multi-stack 350(53) has a height of about 3.0*H.

Multi-stack 350(53) includes end column 342(53), middle column 344(53) and end column 340(53). Middle column 344(53) is abutted between end column 342(53) and end column 340(53). Multi-stack 350(53) has: a vertical axis of symmetry 360(21) that bisects middle column 344(53) and thus bisects multi-stack 350(53); and a horizontal axis of symmetry 358(14) that bisects multi-stack 350(53).

Middle column 344(53) includes abutted dummy CRs 359(1) and 339(3). Dummy CR 359(1) is abutted to end column 342(53). Dummy CR 339(3) is abutted to end column 340(53). End column 342(53) includes cell regions 306(9) and 319(4) stacked on each other. Cell region 306(9) is stacked on cell region 328(14). 318(4). End column 340(53) includes cell regions 310(9) and 310(10). Cell region 310(9) is stacked on cell region 310(10).

FIG. 3CB is a layout diagram of a multi-stack 350(54), in accordance with some embodiments.

FIG. 3CB is similar to FIG. 3BQ. For purposes of brevity, the discussion will focus on differences of FIG. 3CB as compared to FIG. 3CA rather than on similarities.

Multi-stack 350(54) is an example of multi-column stacked arrangement 104 of FIGS. 1B and 1C. Relative to the Y-axis, multi-stack 350(54) has a height of about 3.0*H.

Multi-stack 350(54) includes end column 342(54), middle column 344(54) and end column 340(54). Middle column 344(54) is abutted between end column 342(54) and end column 340(54). Middle column 344(54) of FIG. 3CB corresponds to middle column 344(43) of FIG. 3CA. End column 342(54) of FIG. 3CB corresponds to end column 342(43) of FIG. 3CA. End column 340(54) of FIG. 3CB corresponds to end column 340(43) of FIG. 3CA.

Multi-stack 350(54) has horizontal axis of symmetry 358(14) that bisects multi-stack 350(54). Multi-stack 350(54) of FIG. 3CB is a version of multi-stack 350(43) of FIG. 3CA which has been rotated 180 degrees (180°) about horizontal axis of symmetry 358(14) with respect to the orientation of multi-stack 350(43).

FIG. 3CC is a layout diagram of a multi-stack 350(55), in accordance with some embodiments.

Multi-stack 350(55) is an example of multi-column stacked arrangement 104 of FIGS. 1B and 1C. Relative to the Y-axis, multi-stack 350(55) has a height of about 3.0*H.

Multi-stack 350(55) includes end column 342(55), middle column 344(55) and end column 340(55). Middle column 344(55) is abutted between end column 342(55) and end column 340(55). Multi-stack 350(55) has a vertical axis of symmetry 360(19) that bisects middle column 344(55) and thus bisects multi-stack 350(55).

Middle column 344(55) includes abutted dummy CRs 338(3) and 339(4). Dummy CR 338(3) is abutted to end column 342(55). Dummy CR 339(4) is abutted to end column 340(55). End column 342(55) includes cell regions 328(15), 318(5) and 328(16) stacked on each other. Cell region 318(5) is stacked on cell region 328(16). Cell region 328(15) is stacked on cell region 328(16). End column 340(55) includes cell regions 310(11) and 310(12). Cell region 310(11) is stacked on cell region 310(12).

FIG. 3CD is a layout diagram of a multi-stack 350(56), in accordance with some embodiments.

FIG. 3CD is similar to FIG. 3BY. For purposes of brevity, the discussion will focus on differences of FIG. 3CD as compared to FIG. 3BY rather than on similarities.

Multi-stack 350(56) is an example of multi-column stacked arrangement 104 of FIGS. 1B and 1C. Relative to the Y-axis, multi-stack 350(56) has a height of about 3.0*H.

Multi-stack 350(56) includes end column 342(56), middle column 344(56) and end column 340(56). Middle column 344(56) is abutted between end column 342(56) and end column 340(56). Middle column 344(56) of FIG. 3CD corresponds to middle column 344(51) of FIG. 3BY. End column 342(56) of FIG. 3CD corresponds to end column 342(51) of FIG. 3BY. End column 340(56) of FIG. 3CD corresponds to end column 340(51) of FIG. 3BY.

Multi-stack 350(56) has vertical axis of symmetry 360(19) that bisects middle column 344(56) and thus bisects multi-stack 350(56). Multi-stack 350(56) of FIG. 3CD is a version of multi-stack 350(51) of FIG. 3BY which has been rotated 180 degrees (180°) about vertical axis of symmetry 360(19) with respect to the orientation of multi-stack 350(51).

FIG. 3CE is a layout diagram of a multi-stack 350(57), in accordance with some embodiments.

FIG. 3CE is similar to FIG. 3BZ. For purposes of brevity, the discussion will focus on differences of FIG. 3CE as compared to FIG. 3BZ rather than on similarities.

Multi-stack 350(57) is an example of multi-column stacked arrangement 104 of FIGS. 1B and 1C. Relative to the Y-axis, multi-stack 350(57) has a height of about 3.0*H.

Multi-stack 350(57) includes end column 342(57), middle column 344(57) and end column 340(57). Middle column 344(57) is abutted between end column 342(57) and end column 340(57). Middle column 344(57) of FIG. 3CE corresponds to middle column 344(52) of FIG. 3BZ. End column 342(57) of FIG. 3CE corresponds to end column 342(52) of FIG. 3BZ. End column 340(57) of FIG. 3CE corresponds to end column 340(52) of FIG. 3BZ.

Multi-stack 350(57) has vertical axis of symmetry 360(20) that bisects middle column 344(57) and thus bisects multi-stack 350(57). Multi-stack 350(57) of FIG. 3CE is a version of multi-stack 350(52) of FIG. 3BZ which has been rotated 180 degrees (180°) about vertical axis of symmetry 360(20) with respect to the orientation of multi-stack 350(52).

FIG. 3CF is a layout diagram of a multi-stack 350(58), in accordance with some embodiments.

FIG. 3CF is similar to FIG. 3CA. For purposes of brevity, the discussion will focus on differences of FIG. 3CF as compared to FIG. 3CA rather than on similarities.

Multi-stack 350(58) is an example of multi-column stacked arrangement 104 of FIGS. 1B and 1C. Relative to the Y-axis, multi-stack 350(58) has a height of about 3.0*H.

Multi-stack 350(58) includes end column 342(58), middle column 344(58) and end column 340(58). Middle column 344(58) is abutted between end column 342(58) and end column 340(58). Middle column 344(58) of FIG. 3CF corresponds to middle column 344(53) of FIG. 3CA. End column 342(58) of FIG. 3CF corresponds to end column 342(53) of FIG. 3CA. End column 340(58) of FIG. 3CF corresponds to end column 340(53) of FIG. 3CA.

Multi-stack 350(58) has: vertical axis of symmetry 360(21) that bisects middle column 344(58) and thus bisects multi-stack 350(58); and a horizontal axis of symmetry 358(15) that bisects multi-stack 358(58). Multi-stack 350(58) of FIG. 3CF is a version of multi-stack 350(53) of FIG. 3CA which has been rotated 180 degrees (180°) about vertical axis of symmetry 360(21) with respect to the orientation of multi-stack 350(53).

FIG. 3CG is a layout diagram of a multi-stack 350(59), in accordance with some embodiments.

FIG. 3CG is similar to FIG. 3CF. FIG. 3C is also similar to FIG. 3CA and 3CB. For purposes of brevity, the discussion will focus on differences of FIG. 3CG as compared to FIG. 3CF rather than on similarities.

Multi-stack 350(59) is an example of multi-column stacked arrangement 104 of FIGS. 1B and 1C. Relative to the Y-axis, multi-stack 350(59) has a height of about 3.0*H.

Multi-stack 350(59) includes end column 342(59), middle column 344(59) and end column 340(59). Middle column 344(59) is abutted between end column 342(59) and end column 340(59). Middle column 344(59) of FIG. 3CG corresponds to middle column 344(58) of FIG. 3CF. End column 342(59) of FIG. 3CG corresponds to end column 342(58) of FIG. 3CF. End column 340(59) of FIG. 3CG corresponds to end column 340(58) of FIG. 3CF.

Multi-stack 350(59) has horizontal axis of symmetry 358(15) that bisects multi-stack 350(59). Multi-stack 350(59) of FIG. 3CG is a version of multi-stack 350(58) of FIG. 3CF which has been rotated 180 degrees (180°) about horizontal axis of symmetry 358(15) with respect to the orientation of multi-stack 350(58).

FIG. 3CH is a layout diagram of a multi-stack 350(60), in accordance with some embodiments.

FIG. 3CH is similar to FIG. 3CC. For purposes of brevity, the discussion will focus on differences of FIG. 3CH as compared to FIG. 3CC rather than on similarities.

Multi-stack 350(60) is an example of multi-column stacked arrangement 104 of FIGS. 1B and 1C. Relative to the Y-axis, multi-stack 350(60) has a height of about 3.0*H.

Multi-stack 350(60) includes end column 342(60), middle column 344(60) and end column 340(60). Middle column 344(60) is abutted between end column 342(60) and end column 340(60). Middle column 344(60) of FIG. 3CH corresponds to middle column 344(55) of FIG. 3CC. End column 342(60) of FIG. 3CH corresponds to end column 342(55) of FIG. 3CC. End column 340(60) of FIG. 3CH corresponds to end column 340(55) of FIG. 3CC.

Multi-stack 350(60) has: vertical axis of symmetry 360(22) that bisects middle column 344(60) and thus bisects multi-stack 350(60). Multi-stack 350(60) of FIG. 3CH is a version of multi-stack 350(55) of FIG. 3CC which has been rotated 180 degrees (180°) about vertical axis of symmetry 360(22) with respect to the orientation of multi-stack 350(55).

FIG. 4AA-4CH are diagrams of multi-stacks 450(1)-450(60), in accordance with some embodiments, and are discussed below. In some embodiments, FIG. 4AA-4CH are layout diagrams. Examples of multi-stacks which include half-height non-CMOS standard cell regions and thereby facilitate increased transistor densities within macro regions of which the multi-stacks comprise corresponding parts include multi-stacks 450(1), 450(4)-450(52), 450(55), 450(77) and 450(60) of corresponding FIG. 4AA, 4AC-4AE, 4AG-4BX, 4BZ, 4CC, 4CE and 4CH. By facilitating increased transistor densities, macro regions of which the multi-stacks comprise corresponding parts exhibit reductions in areas consumed by the macro regions, improvements in the speeds of the macro regions and reductions in power consumed by the macro regions, improvements in macro region placement flexibility and improvements in pin accessibility as compared to the other approaches.

FIG. 4AA is a layout diagram of a multi-stack 450(1), in accordance with some embodiments.

FIG. 4AA is similar to FIG. 3AA. For purposes of brevity, the discussion will focus on differences of FIG. 4AA as compared to FIG. 3AA rather than on similarities.

Multi-stack 450(1) is an example of multi-column stacked arrangement 104 of FIGS. 1B and 1C. Relative to the Y-axis, multi-stack 450(1) has a height of about 3.0*H.

Multi-stack 450(1) includes end columns 342(1) and 340(1) of FIG. 3AA. Multi-stack 450(1) omits a middle column that otherwise would correspond to middle column 344(1) of multi-stack 350(1) of FIG. 3AA. As such, in some embodiments, multi-stack 450(1) is a two column multi-stack whereas multi-stack 350(1) is a three column multi-stack. In such embodiments, other multi-stacks shown correspondingly in FIG. 4AB-4AZ, 4BA-4BZ and 4CA-4CH are referred to as a two column multi-stacks.

In FIG. 4AA, because otherwise corresponding middle column 344(1) of multi-stack 350(1) of FIG. 3AA is omitted, end column 342(1) is abutted end column 340(1). Multi-stack 460(1) has a vertical axis of symmetry 360(1) that corresponds to vertical axis of symmetry 360(1) of multi-stack 350(1) of FIG. 3AA. However, in FIG. 4AA, vertical axis of symmetry 460(1) aligns to each of the right side/boundary of end column 342(1) and the left side/boundary of end column 340(1). In FIG. 4AA, the outer side/boundary of end column 342(1) represents the left side/boundary of multi-stack 450(1). In FIG. 4AA, the outer side/boundary of end column 340(1) represents the right side/boundary of multi-stack 450(1).

More generally, vertical axis of symmetry 460(1) aligns to the inner side/boundary of each of end column 342(1) and end column 340(1). In FIG. 4AA, the outer side/boundary of end column 342(1) represents a first side/boundary of multi-stack 450(1). In FIG. 4AA, the outer side/boundary of end column 440(1) represents a second side/boundary of multi-stack 450(1).

In FIG. 4AA, end column 342(1) of multi-stack 450(1) includes the same cell regions as in FIG. 3AA, i.e., includes filler cell region 324(1), cell region 306(1) and filler cell region 324(2) of multi-stack 350(1). In FIG. 4AA, end column 340(1) of multi-stack 450(1) includes the same cell region as in FIG. 3AA, i.e., includes cell region 314(1) of multi-stack 350(1).

The arrangement of PG segments in multi-stack 450(1) is the same as in corresponding multi-stack 350(1) of FIG. 3AA. However, for simplicity of illustration, arrangement of PG segments is not shown in FIG. 4AA.

FIG. 4AB-4AZ, 4BA-4BZ and 4CA-4CH are layout diagrams of corresponding multi-stacks 450(2)-450(60), in accordance with some embodiments.

Just as FIG. 4AA is similar to FIG. 3AA (as discussed above), FIG. 4AB-4AZ, 4BA-4BZ and 4CA-4CH are similar to corresponding FIG. 3AB-3AZ, 3BA-3BZ and 3CA-3CH.

Multi-stacks 450(2)-450(60) of FIG. 4AB-4AZ, 4BA-4BZ and 4CA-4CH include the same corresponding end columns 340(2)-340(60) and 342(2)-342(60) of FIG. 3AB-3AZ, 3BA-3BZ and 3CA-3CH. Multi-stacks 450(2)-450(60) of FIG. 4AB-4AZ, 4BA-4BZ and 4CA-4CH omit middle columns that that otherwise would correspond to middle columns 344(2)-344(60) of multi-stacks 350(2)-350(60) of FIG. 3AB-3AZ, 3BA-3BZ and 3CA-3CH.

FIG. 4AB-4AH, 4AO, 4AU-4AZ, 4BA-4BJ and 4BM-4CC correspondingly include vertical axes of symmetry 460(2)-460(22). Vertical axes of symmetry 460(2)-460(22) correspond to vertical axes of symmetry 360(2)-360(22) of FIG. 3AB-3AH, 3AO, 3AU-3AZ, 3BA-3BJ and 3BM-3CC.

In FIG. 4AB-4AZ, 4BA-4BZ and 4CA-4CH, because otherwise corresponding middle columns 344(2)-344(60) of multi-stacks 350(2)-350(60) are omitted, end columns 342(2)-342(60) abut corresponding end columns 340(2)-340(60). Accordingly, in FIG. 4AB-4AZ, 4BA-4BZ and 4CA-4CH, vertical axes of symmetry (if depicted) align to the inner sides/boundaries of the end columns in a manner similar to FIG. 4AA.

FIG. 4AC-4AD, 4AG-4AH, 4AL-4AN, 4AR, 4AU-4AX, 4BA, 4BC-4BG, 4BJ-4BM, 4BO, 4BQ-4BS, 4BU, 4BW and 4CA-4CB correspondingly include horizontal axes of symmetry 458(1)-458(14). Horizontal axes of symmetry 458(1)-458(14) correspond to horizontal axes of symmetry 358(1)-458(14) of corresponding FIG. 3AC-3AD, 3AG-3AH, 3AL-3AN, 3AR, 3AU-3AX, 3BA, 3BC-3BG, 3BJ-3BM, 3BO, 3BQ-3BS, 3BU, 3BW and 3CA-3CB. Horizontal axes of symmetry 458(1)-458(14) bisect corresponding multi-stacks 450(3)-450(4), 450(7)-450(8), 450(12)-450(14), 450(18), 450(21)-450(24), 450(27), 450(29)-450(33), 450(35)-450(39), 450(43)-450(45), 450(47), 450(49), 450(53)-450(54) and 450(58)-450(59).

The arrangement of PG segments in multi-stacks 450(2)-450(60) are the same as in corresponding multi-stacks 350(2)-350(6) of FIG. 3AB-3CH. However, for simplicity of illustration, arrangements of PG segments are not shown in FIG. 4AB-4AH.

FIG. 5AA-5BI are diagrams of single column stacked arrangements (uni-stacks) 568(1)-568(35) of cell regions, in accordance with some embodiments, and are discussed below. In some embodiments, FIG. 5AA-5BI are layout diagrams. Examples of uni-stacks which include half-height non-CMOS standard cell regions and thereby facilitate increased transistor densities within macro regions of which the uni-stacks comprise corresponding parts include uni-stacks 568(1)-568(4), 568(7)-568(24), 568(26)-568(27) and 568(35) of corresponding FIG. 5AA-5AD, 5AG-5AX, 5AZ-5BA and 5BI. By facilitating increased transistor densities, macro regions of which the uni-stacks comprise corresponding parts exhibit reductions in areas consumed by the macro regions, improvements in the speeds of the macro regions and reductions in power consumed by the macro regions, improvements in macro region placement flexibility and improvements in pin accessibility as compared to the other approaches.

FIG. 5AA is a layout diagram of a single column stacked arrangement 568(1), in accordance with some embodiments.

Single column stacked arrangement (uni-stack) 568(1) is an example of single column stacked arrangement 102 of FIGS. 1A and 1C. Uni-stack 568(1), and each of the other uni-stacks shown correspondingly in FIG. 5AB-5BI, is arranged as a single column. Relative to the Y-axis, uni-stack 568(1) has a height of about 3.5*H.

Uni-stack 568(1) includes cell region 506(1), filler cell region 524(1) and cell region 514(1). Filler cell region 524(1) is stacked on cell region 514(1). Cell region 506(1) is stacked on filler cell region 524(1). Uni-stack 568(1) has a horizontal axis of symmetry 558(1) that bisects uni-stack 568(1).

Cell region 506(1) is example of either cell region 206PN of FIG. 2A or cell region 206NP of FIG. 2B. For simplicity of illustration, cell region 506(1) is depicted with the legend “PN” rather than the legend “PN or NP.” More generally, in FIG. 5AA and in other figures disclosed herein, a reference number of the type “506(x),” where x represents an index number, e.g., 506(1), denotes an example of either cell region 206PN of FIG. 2A or cell region 206NP of FIG. 2B.

Filler cell region 524(1) is an example of filler cell region 224P of FIG. 2I or filler cell region 224N of FIG. 2J. More generally, in FIG. 5AA and in other figures disclosed herein, a reference number of the type “524(x),” where x represents an index number, e.g., 524(1), denotes an example of either cell region 224P of FIG. 2I or filler cell region 224N of FIG. 2J.

Cell region 514(1) is example of either cell region 214PPNN of FIG. 2E or cell region 214NNPP of FIG. 2F. For simplicity of illustration, cell region 514(1) is depicted with the legend “PPNN” rather than the legend “PPNN or NNPP.” More generally, in FIG. 5AA and in other figures disclosed herein, a reference number of the type “514(x),” where x represents an index number, e.g., 514(1), denotes an example of either cell region 206PN of FIG. 2A or cell region 206NP of FIG. 2B.

In uni-stack 568(1) and in other uni-stacks disclosed herein, for simplicity of illustration, the various P-type/N-type configurations of the active regions in the uni-stack are not depicted. Rather, relative to the Y-axis, regarding the uni-stacks, it is understood that active regions which abut relative to the X-axis have the same P-type configuration or the same N-type configuration. Also, relative to the Y-axis, the various P-type/N-type configurations of the active regions in the uni-stack are determined according to the architecture of the transistor-based device, e.g., CMOS architecture, of which the uni-stack comprises a part.

FIG. 5AB is a layout diagram of a uni-stack 568(2), in accordance with some embodiments.

FIG. 5AB is similar to FIG. 5AA. For purposes of brevity, the discussion will focus on differences of FIG. 5AB as compared to FIG. 5AA rather than on similarities.

Uni-stack 568(2) is an example of single column stacked arrangement 102 of FIGS. 1A and 1C. Relative to the Y-axis, uni-stack 568(2) has a height of about 3.5*H.

Uni-stack 568(2) has horizontal axis of symmetry 558(1) that bisects uni-stack 568(2). Uni-stack 568(2) of FIG. 5AB is a version of uni-stack 568(1) of FIG. 5AA which has been rotated 180 degrees (180°) about horizontal axis of symmetry 558(1) with respect to the orientation of uni-stack 568(1).

FIG. 5AC is a layout diagram of a uni-stack 568(3), in accordance with some embodiments.

Uni-stack 568(3) is an example of single column stacked arrangement 102 of FIGS. 1A and 1C. Relative to the Y-axis, uni-stack 568(3) has a height of about 4.5*H.

Uni-stack 568(3) includes cell region 514(2), filler cell region 524(2) and cell region 518(1). Filler cell region 524(2) is stacked on cell region 518(1). Cell region 514(2) is stacked on filler cell region 524(2). Uni-stack 568(3) has a horizontal axis of symmetry 558(2) that bisects uni-stack 568(3).

Cell region 518(1) is example of either cell region 218PNP of FIG. 2G or cell region 218NPN of FIG. 2H. More generally, in FIG. 5AC and in other figures disclosed herein, a reference number of the type “518(x),” where x represents an index number, e.g., 518(1), denotes an example of either cell region 218PNP of FIG. 2G or cell region 218NPN of FIG. 2H.

FIG. 5AD is a layout diagram of a uni-stack 568(4), in accordance with some embodiments.

FIG. 5AD is similar to FIG. 5AC. For purposes of brevity, the discussion will focus on differences of FIG. 5AD as compared to FIG. 5AC rather than on similarities.

Uni-stack 568(4) is an example of single column stacked arrangement 102 of FIGS. 1A and 1C. Relative to the Y-axis, uni-stack 568(4) has a height of about 4.5*H.

Uni-stack 568(4) has horizontal axis of symmetry 558(2) that bisects uni-stack 568(4). Uni-stack 568(4) of FIG. 5AD is a version of uni-stack 568(3) of FIG. 5AC which has been rotated 180 degrees (180°) about horizontal axis of symmetry 558(2) with respect to the orientation of uni-stack 568(3).

FIG. 5AE is a layout diagram of a uni-stack 568(5), in accordance with some embodiments.

Uni-stack 568(5) is an example of single column stacked arrangement 102 of FIGS. 1A and 1C. Relative to the Y-axis, uni-stack 568(5) has a height of about 3.0*H.

Uni-stack 568(5) includes cell region 506(2) and cell region 518(2). Cell region 506(2) is stacked on cell region 518(1). Uni-stack 568(5) has a horizontal axis of symmetry 558(3) that bisects uni-stack 568(5).

FIG. 5AF is a layout diagram of a uni-stack 568(6), in accordance with some embodiments.

FIG. 5AF is similar to FIG. 5AE. For purposes of brevity, the discussion will focus on differences of FIG. 5AF as compared to FIG. 5AE rather than on similarities.

Uni-stack 568(6) is an example of single column stacked arrangement 102 of FIGS. 1A and 1C. Relative to the Y-axis, uni-stack 568(6) has a height of about 3.0*H.

Uni-stack 568(6) has horizontal axis of symmetry 558(3) that bisects uni-stack 568(6). Uni-stack 568(6) of FIG. 5AF is a version of uni-stack 568(5) of FIG. 5AE which has been rotated 180 degrees (180°) about horizontal axis of symmetry 558(3) with respect to the orientation of uni-stack 568(5).

FIG. 5AG is a layout diagram of a uni-stack 568(7), in accordance with some embodiments.

Uni-stack 568(7) is an example of single column stacked arrangement 102 of FIGS. 1A and 1C. Relative to the Y-axis, uni-stack 568(7) has a height of about 3.0*H.

Uni-stack 568(7) includes cell region 528(1), 514(3) and 528(2). Cell region 514(3) is stacked on cell region 528(2). Cell region 528(1) is stacked on cell region 514(3).

Each of cell region 528(1) and 528(2) correspondingly is an example of cell region 228P of FIG. 2K or cell region 228N of FIG. 2L. More generally, in FIG. 5AG and in other figures disclosed herein, a reference number of the type “528(x),” where x represents an index number, e.g., 528(1), denotes an example of either cell region 228P of FIG. 2K or cell region 228N of FIG. 2L.

FIG. 5AH is a layout diagram of a uni-stack 568(8), in accordance with some embodiments.

FIG. 5AH is similar to FIG. 5AG. For purposes of brevity, the discussion will focus on differences of FIG. 5AH as compared to FIG. 5AG rather than on similarities.

Uni-stack 568(8) is an example of single column stacked arrangement 102 of FIGS. 1A and 1C. Relative to the Y-axis, uni-stack 568(8) has a height of about 3.0*H.

As compared to uni-stack 568(7) of FIG. 5AG, uni-stack 568(8) of FIG. 5AH includes filler cell region 524(3) and omits cell region 528(1). That is, in uni-stack 568(8), filler cell region 542(3) replaces cell region 528(1) of uni-stack 568(7). In uni-stack 568(8), filler cell region 524(3) is stacked on cell region 514(3). Uni-stack 568(8) has a horizontal axis of symmetry 558(4) that bisects uni-stack 568(8).

FIG. 5AI is a layout diagram of a uni-stack 568(9), in accordance with some embodiments.

FIG. 5AI is similar to FIG. 5AG. FIG. 5AI also is similar to FIG. 5AH. For purposes of brevity, the discussion will focus on differences of FIG. 5AI as compared to each of FIG. 5AG and 5AH rather than on similarities.

Uni-stack 568(9) is an example of single column stacked arrangement 102 of FIGS. 1A and 1C. Relative to the Y-axis, uni-stack 568(9) has a height of about 3.0*H.

As compared to uni-stack 568(7) of FIG. 5AG, uni-stack 568(9) of FIG. 5AI includes filler cell region 524(4) and omits cell region 528(2). That is, in uni-stack 568(9), filler cell region 542(4) replaces cell region 528(2) of uni-stack 568(7). In uni-stack 568(9), cell region 514(3) is stacked on filler cell region 524(4).

Uni-stack 568(9) has horizontal axis of symmetry 558(4) that bisects uni-stack 568(9). Uni-stack 568(9) of FIG. 5AI is a version of uni-stack 568(8) of FIG. 5AH which has been rotated 180 degrees (180°) about horizontal axis of symmetry 558(4) with respect to the orientation of uni-stack 568(8).

FIG. 5AJ is a layout diagram of a uni-stack 568(10), in accordance with some embodiments.

FIG. 5AJ is similar to FIG. 5AG. FIG. 5AJ is also similar to FIG. 5AH. For purposes of brevity, the discussion will focus on differences of FIG. 5AJ as compared to each of FIG. 5AG and 5AH rather than on similarities.

Uni-stack 568(10) is an example of single column stacked arrangement 102 of FIGS. 1A and 1C. Relative to the Y-axis, uni-stack 568(10) has a height of about 2.5*H.

As compared to uni-stack 568(7) of FIG. 5AG, uni-stack 568(10) of FIG. 5AJ omits cell region 528(1). As compared to uni-stack 568(8) of FIG. 5AH, uni-stack 568(10) of FIG. 5AJ omits filler cell region 524(3).

FIG. 5AK is a layout diagram of a uni-stack 568(11), in accordance with some embodiments.

FIG. 5AK is similar to FIG. 5AG. FIG. 5AK is also similar to FIG. 5AI. For purposes of brevity, the discussion will focus on differences of FIG. 5AK as compared to each of FIG. 5AG and 5AI rather than on similarities.

Uni-stack 568(11) is an example of single column stacked arrangement 102 of FIGS. 1A and 1C. Relative to the Y-axis, uni-stack 568(11) has a height of about 2.5*H.

As compared to uni-stack 568(7) of FIG. 5AG, uni-stack 568(11) of FIG. 5AK omits cell region 528(2). As compared to uni-stack 568(8) of FIG. 5AI, uni-stack 568(11) of FIG. 5AK omits filler cell region 524(4).

FIG. 5AL is a layout diagram of a uni-stack 568(12), in accordance with some embodiments.

Uni-stack 568(12) is an example of single column stacked arrangement 102 of FIGS. 1A and 1C. Relative to the Y-axis, uni-stack 568(12) has a height of about 3.0*H.

Uni-stack 568(12) includes cell region 528(3), 518(3) and 528(4). Cell region 518(3) is stacked on cell region 528(4). Cell region 528(3) is stacked on cell region 518(3).

FIG. 5AM is a layout diagram of a uni-stack 568(13), in accordance with some embodiments.

FIG. 5AM is similar to FIG. 5AL. For purposes of brevity, the discussion will focus on differences of FIG. 5AM as compared to FIG. 5AL rather than on similarities.

Uni-stack 568(13) is an example of single column stacked arrangement 102 of FIGS. 1A and 1C. Relative to the Y-axis, uni-stack 568(13) has a height of about 3.0*H.

As compared to uni-stack 568(7) of FIG. 5AL, uni-stack 568(13) of FIG. 5AM includes filler cell region 524(5) and omits cell region 528(3). That is, in uni-stack 568(13), filler cell region 542(5) replaces cell region 528(3) of uni-stack 568(12). In uni-stack 568(13), filler cell region 524(5) is stacked on cell region 518(3). Uni-stack 568(13) has a horizontal axis of symmetry 558(5) that bisects uni-stack 568(13).

FIG. 5AN is a layout diagram of a uni-stack 568(14), in accordance with some embodiments.

FIG. 5AN is similar to FIG. 5AL. FIG. 5AN also is similar to FIG. 5AM. For purposes of brevity, the discussion will focus on differences of FIG. 5AN as compared to each of FIG. 5AL and 5AM rather than on similarities.

Uni-stack 568(14) is an example of single column stacked arrangement 102 of FIGS. 1A and 1C. Relative to the Y-axis, uni-stack 568(14) has a height of about 3.0*H.

As compared to uni-stack 568(12) of FIG. 5AL, uni-stack 568(14) of FIG. 5AN includes filler cell region 524(6) and omits cell region 528(4). That is, in uni-stack 568(14), filler cell region 542(6) replaces cell region 528(4) of uni-stack 568(12). In uni-stack 568(14), cell region 518(3) is stacked on filler cell region 524(6).

Uni-stack 568(14) has horizontal axis of symmetry 558(5) that bisects uni-stack 568(14). Uni-stack 568(14) of FIG. 5AN is a version of uni-stack 568(13) of FIG. 5AM which has been rotated 180 degrees (180°) about horizontal axis of symmetry 558(5) with respect to the orientation of uni-stack 568(13).

FIG. 5AO is a layout diagram of a uni-stack 568(15), in accordance with some embodiments.

FIG. 5AO is similar to FIG. 5AL. FIG. 5AO is also similar to FIG. 5AM. For purposes of brevity, the discussion will focus on differences of FIG. 5AO as compared to each of FIG. 5AL and 5AM rather than on similarities.

Uni-stack 568(15) is an example of single column stacked arrangement 102 of FIGS. 1A and 1C. Relative to the Y-axis, uni-stack 568(15) has a height of about 2.5*H.

As compared to uni-stack 568(12) of FIG. 5AL, uni-stack 568(15) of FIG. 5AO omits cell region 528(3). As compared to uni-stack 568(13) of FIG. 5AM, uni-stack 568(15) of FIG. 5AO omits filler cell region 524(5).

FIG. 5AP is a layout diagram of a uni-stack 568(16), in accordance with some embodiments.

FIG. 5AP is similar to FIG. 5AL. FIG. 5AP is also similar to FIG. 5AN. For purposes of brevity, the discussion will focus on differences of FIG. 5AP as compared to each of FIG. 5AL and 5AN rather than on similarities.

Uni-stack 568(16) is an example of single column stacked arrangement 102 of FIGS. 1A and 1C. Relative to the Y-axis, uni-stack 568(16) has a height of about 2.5*H.

As compared to uni-stack 568(12) of FIG. 5AL, uni-stack 568(16) of FIG. 5AP omits cell region 528(4). As compared to uni-stack 568(14) of FIG. 5AN, uni-stack 568(16) of FIG. 5AP omits filler cell region 524(6).

FIG. 5AQ is a layout diagram of a uni-stack 568(17), in accordance with some embodiments.

Uni-stack 568(17) is an example of single column stacked arrangement 102 of FIGS. 1A and 1C. Relative to the Y-axis, uni-stack 568(17) has a height of about 2.0*H.

Uni-stack 568(17) includes filler cell region 524(7) and cell region 510(1). Cell region 524(7) is stacked on cell region 510(1). Uni-stack 568(17) has a horizontal axis of symmetry 558(6) that bisects uni-stack 568(17).

Cell region 510(1) is example of either cell region 210PN of FIG. 2C or cell region 210NP of FIG. 2D. More generally, in FIG. 5AQ, and in other figures disclosed herein, a reference number of the type “510(x),” where x represents an index number, e.g., 510(1), denotes an example of either 210PN of FIG. 2C or cell region 210NP of FIG. 2D.

FIG. 5AR is a layout diagram of a uni-stack 568(18), in accordance with some embodiments.

FIG. 5AR is similar to FIG. 5AQ. For purposes of brevity, the discussion will focus on differences of FIG. 5AR as compared to FIG. 5AQ rather than on similarities.

Uni-stack 568(18) is an example of single column stacked arrangement 102 of FIGS. 1A and 1C. Relative to the Y-axis, uni-stack 568(18) has a height of about 2.5*H.

Uni-stack 568(18) has horizontal axis of symmetry 558(6) that bisects uni-stack 568(18). Uni-stack 568(18) of FIG. 5AR is a version of uni-stack 568(17) of FIG. 5AQ which has been rotated 180 degrees (180°) about horizontal axis of symmetry 558(6) with respect to the orientation of uni-stack 568(18).

FIG. 5AS is a layout diagram of a uni-stack 568(19), in accordance with some embodiments.

FIG. 5AS is similar to FIG. 5AQ. For purposes of brevity, the discussion will focus on differences of FIG. 5AS as compared to FIG. 5AQ rather than on similarities.

Uni-stack 568(19) is an example of single column stacked arrangement 102 of FIGS. 1A and 1C. Relative to the Y-axis, uni-stack 568(19) has a height of about 3.0*H.

Uni-stack 568(19) includes filler cell region 524(8) and cell region 510(2). Cell region 524(8) is stacked on cell region 510(2). As compared to FIG. 5AQ, filler cell region 524(8) and cell region 510(2) correspond to filler cell region 524(7) and cell region 510(1) of uni-stack 568(17). Also, as compared to uni-stack 568(17) of FIG. 5AQ, uni-stack 568(19) of FIG. 5AS further includes cell region 506(3). Cell region 506(3) is stacked on filler cell region 524(8). Uni-stack 568(19) has a horizontal axis of symmetry 558(7) that bisects uni-stack 568(19).

FIG. 5AT is a layout diagram of a uni-stack 568(20), in accordance with some embodiments.

FIG. 5AT is similar to FIG. 5AS. For purposes of brevity, the discussion will focus on differences of FIG. 5AT as compared to FIG. 5AS rather than on similarities.

Uni-stack 568(20) is an example of single column stacked arrangement 102 of FIGS. 1A and 1C. Relative to the Y-axis, uni-stack 568(20) has a height of about 3.0*H.

Uni-stack 568(20) has horizontal axis of symmetry 558(7) that bisects uni-stack 568(20). Uni-stack 568(20) of FIG. 5AT is a version of uni-stack 568(19) of FIG. 5AS which has been rotated 180 degrees (180°) about horizontal axis of symmetry 558(7) with respect to the orientation of uni-stack 568(19).

FIG. 5AU is a layout diagram of a uni-stack 568(21), in accordance with some embodiments.

FIG. 5AU is similar to FIG. 5AQ. For purposes of brevity, the discussion will focus on differences of FIG. 5AU as compared to FIG. 5AQ rather than on similarities.

Uni-stack 568(21) is an example of single column stacked arrangement 102 of FIGS. 1A and 1C. Relative to the Y-axis, uni-stack 568(21) has a height of about 4.0*H.

Uni-stack 568(21) includes filler cell region 524(9) and cell region 510(3). Cell region 524(9) is stacked on cell region 510(3). As compared to FIG. 5AQ, filler cell region 524(9) and cell region 510(3) correspond to filler cell region 524(7) and cell region 510(1) of uni-stack 568(17). Also, as compared to uni-stack 568(17) of FIG. 5AQ, uni-stack 568(21) of FIG. 5AU further includes cell region 514(3). Cell region 514(3) is stacked on filler cell region 524(9). Uni-stack 568(21) has a horizontal axis of symmetry 558(8) that bisects uni-stack 568(21).

FIG. 5AV is a layout diagram of a uni-stack 568(22), in accordance with some embodiments.

FIG. 5AV is similar to FIG. 5AU. For purposes of brevity, the discussion will focus on differences of FIG. 5AV as compared to FIG. 5AU rather than on similarities.

Uni-stack 568(22) is an example of single column stacked arrangement 102 of FIGS. 1A and 1C. Relative to the Y-axis, uni-stack 568(22) has a height of about 4.0*H.

Uni-stack 568(22) has horizontal axis of symmetry 558(8) that bisects uni-stack 568(22). Uni-stack 568(22) of FIG. 5AV is a version of uni-stack 568(21) of FIG. 5AU which has been rotated 180 degrees (180°) about horizontal axis of symmetry 558(8) with respect to the orientation of uni-stack 568(21).

FIG. 5AW is a layout diagram of a uni-stack 568(23), in accordance with some embodiments.

FIG. 5AW is similar to FIG. 5AQ. For purposes of brevity, the discussion will focus on differences of FIG. 5AW as compared to FIG. 5AQ rather than on similarities.

Uni-stack 568(23) is an example of single column stacked arrangement 102 of FIGS. 1A and 1C. Relative to the Y-axis, uni-stack 568(23) has a height of about 4.0*H.

Uni-stack 568(23) includes filler cell region 524(10) and cell region 510(4). Cell region 524(10) is stacked on cell region 510(4). As compared to FIG. 5AQ, filler cell region 524(10) and cell region 510(4) correspond to filler cell region 524(7) and cell region 510(1) of uni-stack 568(17). Also, as compared to uni-stack 568(17) of FIG. 5AQ, uni-stack 568(23) of FIG. 5AW further includes cell region 518(4). Cell region 518(4) is stacked on filler cell region 524(10). Uni-stack 568(23) has a horizontal axis of symmetry 558(9) that bisects uni-stack 568(23).

FIG. 5AX is a layout diagram of a uni-stack 568(24), in accordance with some embodiments.

FIG. 5AX is similar to FIG. 5AW. For purposes of brevity, the discussion will focus on differences of FIG. 5AX as compared to FIG. 5AW rather than on similarities.

Uni-stack 568(24) is an example of single column stacked arrangement 102 of FIGS. 1A and 1C. Relative to the Y-axis, uni-stack 568(24) has a height of about 4.0*H.

Uni-stack 568(24) has horizontal axis of symmetry 558(9) that bisects uni-stack 568(24). Uni-stack 568(24) of FIG. 5AX is a version of uni-stack 568(23) of FIG. 5AW which has been rotated 180 degrees (180°) about horizontal axis of symmetry 558(9) with respect to the orientation of uni-stack 568(23).

FIG. 5AY is a layout diagram of a uni-stack 568(25), in accordance with some embodiments.

Uni-stack 568(25) is an example of single column stacked arrangement 102 of FIGS. 1A and 1C. Relative to the Y-axis, uni-stack 568(25) has a height of about 3.0*H.

Uni-stack 568(25) includes cell region 510(5) and cell region 510(6). Cell region 510(5) is stacked on cell region 510(6). Uni-stack 568(25) has: a horizontal axis of symmetry 558(10) that bisects cell region 510(5); and a horizontal axis of symmetry 558(11) that bisects cell region 510(6).

FIG. 5AZ is a layout diagram of a uni-stack 568(26), in accordance with some embodiments.

FIG. 5AZ is similar to FIG. 5AQ. For purposes of brevity, the discussion will focus on differences of FIG. 5AZ as compared to FIG. 5AQ rather than on similarities.

Uni-stack 568(26) is an example of single column stacked arrangement 102 of FIGS. 1A and 1C. Relative to the Y-axis, uni-stack 568(26) has a height of about 2.0*H.

Uni-stack 568(26) includes cell region 528(5) and cell region 510(7). As compared to FIG. 5AQ, cell region 510(7) of uni-stack 568(26) corresponds to cell region 510(1) of uni-stack 568(17). Also as compared to uni-stack 568(17) of FIG. 5AQ, uni-stack 568(26) of FIG. 5AZ includes cell region 528(5) and omits filler cell region 524(7). That is, in uni-stack 568(26), cell region 528(5) replaces filler cell region 524(7) of uni-stack 568(17). In uni-stack 568(26), cell region 528(5) is stacked on cell region 510(7). Uni-stack 568(26) has a horizontal axis of symmetry 558(12) that bisects uni-stack 568(26).

FIG. 5BA is a layout diagram of a uni-stack 568(27), in accordance with some embodiments.

FIG. 5BA is similar to FIG. 5AZ. For purposes of brevity, the discussion will focus on differences of FIG. 5BA as compared to FIG. 5AZ rather than on similarities.

Uni-stack 568(27) is an example of single column stacked arrangement 102 of FIGS. 1A and 1C. Relative to the Y-axis, uni-stack 568(27) has a height of about 2.0*H.

Uni-stack 568(27) has horizontal axis of symmetry 558(12) that bisects uni-stack 568(27). Uni-stack 568(27) of FIG. 5BA is a version of uni-stack 568(26) of FIG. 5AZ which has been rotated 180 degrees (180°) about horizontal axis of symmetry 558(12) with respect to the orientation of uni-stack 568(26).

FIG. 5BB is a layout diagram of a uni-stack 568(28), in accordance with some embodiments.

FIG. 5BB is similar to FIG. 5AQ. For purposes of brevity, the discussion will focus on differences of FIG. 5BB as compared to FIG. 5AQ rather than on similarities.

Uni-stack 568(28) is an example of single column stacked arrangement 102 of FIGS. 1A and 1C. Relative to the Y-axis, uni-stack 568(28) has a height of about 2.5*H.

Uni-stack 568(28) includes cell region 506(4) and cell region 510(8). As compared to FIG. 5AQ, cell region 510(8) of uni-stack 568(28) corresponds to cell region 510(1) of uni-stack 568(17). Also as compared to uni-stack 568(17) of FIG. 5AQ, uni-stack 568(28) of FIG. 5BB includes cell region 506(4) and omits filler cell region 524(7). That is, in uni-stack 568(28), cell region 506(4) replaces filler cell region 524(7) of uni-stack 568(17). In uni-stack 568(28), cell region 506(4) is stacked on cell region 510(8). Uni-stack 568(28) has a horizontal axis of symmetry 558(13) that bisects uni-stack 568(28).

FIG. 5BC is a layout diagram of a uni-stack 568(29), in accordance with some embodiments.

FIG. 5BC is similar to FIG. 5BB. For purposes of brevity, the discussion will focus on differences of FIG. 5BC as compared to FIG. 5BB rather than on similarities.

Uni-stack 568(29) is an example of single column stacked arrangement 102 of FIGS. 1A and 1C. Relative to the Y-axis, uni-stack 568(29) has a height of about 2.5*H.

Uni-stack 568(29) has horizontal axis of symmetry 558(13) that bisects uni-stack 568(29). Uni-stack 568(29) of FIG. 5BC is a version of uni-stack 568(28) of FIG. 5BB which has been rotated 180 degrees (180°) about horizontal axis of symmetry 558(13) with respect to the orientation of uni-stack 568(28).

FIG. 5BD is a layout diagram of a uni-stack 568(30), in accordance with some embodiments.

FIG. 5BD is similar to FIG. 5AQ. For purposes of brevity, the discussion will focus on differences of FIG. 5BD as compared to FIG. 5AQ rather than on similarities.

Uni-stack 568(30) is an example of single column stacked arrangement 102 of FIGS. 1A and 1C. Relative to the Y-axis, uni-stack 568(30) has a height of about 3.5*H.

Uni-stack 568(30) includes cell region 514(4) and cell region 510(9). As compared to FIG. 5AQ, cell region 510(9) of uni-stack 568(30) corresponds to cell region 510(1) of uni-stack 568(17). Also as compared to uni-stack 568(17) of FIG. 5AQ, uni-stack 568(30) of FIG. 5BD includes cell region 514(4) and omits filler cell region 524(7). That is, in uni-stack 568(30), cell region 514(4) replaces filler cell region 524(7) of uni-stack 568(17). In uni-stack 568(30), cell region 514(4) is stacked on cell region 510(9). Uni-stack 568(30) has a horizontal axis of symmetry 558(14) that bisects uni-stack 568(30).

FIG. 5BE is a layout diagram of a uni-stack 568(31), in accordance with some embodiments.

FIG. 5BE is similar to FIG. 5BD. For purposes of brevity, the discussion will focus on differences of FIG. 5BE as compared to FIG. 5BD rather than on similarities.

Uni-stack 568(31) is an example of single column stacked arrangement 102 of FIGS. 1A and 1C. Relative to the Y-axis, uni-stack 568(31) has a height of about 3.5*H.

Uni-stack 568(31) has horizontal axis of symmetry 558(14) that bisects uni-stack 568(31). Uni-stack 568(31) of FIG. 5BE is a version of uni-stack 568(30) of FIG. 5BD which has been rotated 180 degrees (180°) about horizontal axis of symmetry 558(14) with respect to the orientation of uni-stack 568(30).

FIG. 5BF is a layout diagram of a uni-stack 568(32), in accordance with some embodiments.

FIG. 5BF is similar to FIG. 5AQ. For purposes of brevity, the discussion will focus on differences of FIG. 5BF as compared to FIG. 5AQ rather than on similarities.

Uni-stack 568(32) is an example of single column stacked arrangement 102 of FIGS. 1A and 1C. Relative to the Y-axis, uni-stack 568(32) has a height of about 3.5*H.

Uni-stack 568(32) includes cell region 518(5) and cell region 510(10). As compared to FIG. 5AQ, cell region 510(10) of uni-stack 568(32) corresponds to cell region 510(1) of uni-stack 568(17). Also as compared to uni-stack 568(17) of FIG. 5AQ, uni-stack 568(32) of FIG. 5BF includes cell region 518(5) and omits filler cell region 524(7). That is, in uni-stack 568(32), cell region 518(5) replaces filler cell region 524(7) of uni-stack 568(17). In uni-stack 568(32), cell region 518(5) is stacked on cell region 510(10). Uni-stack 568(32) has a horizontal axis of symmetry 558(15) that bisects uni-stack 568(32).

FIG. 5BG is a layout diagram of a uni-stack 568(33), in accordance with some embodiments.

FIG. 5BG is similar to FIG. 5BF. For purposes of brevity, the discussion will focus on differences of FIG. 5BG as compared to FIG. 5BF rather than on similarities.

Uni-stack 568(33) is an example of single column stacked arrangement 102 of FIGS. 1A and 1C. Relative to the Y-axis, uni-stack 568(33) has a height of about 3.5*H.

Uni-stack 568(33) has horizontal axis of symmetry 558(15) that bisects uni-stack 568(33). Uni-stack 568(33) of FIG. 5BG is a version of uni-stack 568(32) of FIG. 5BF which has been rotated 180 degrees (180°) about horizontal axis of symmetry 558(15) with respect to the orientation of uni-stack 568(32).

FIG. 5BH is a layout diagram of a uni-stack 568(34), in accordance with some embodiments.

FIG. 5BH is similar to FIG. 5AY. For purposes of brevity, the discussion will focus on differences of FIG. 5BH as compared to FIG. 5AY rather than on similarities.

Uni-stack 568(34) is an example of single column stacked arrangement 102 of FIGS. 1A and 1C. Relative to the Y-axis, uni-stack 568(34) has a height of about 3.0*H.

Uni-stack 568(34) includes cell region 510(11) and cell region 510(12). Cell region 510(11) is stacked on cell region 510(12). As compared to FIG. 5AY, cell region 510(11) and cell region 510(12) of uni-stack 568(34) correspond to cell region 510(5) and cell region 510(6) of uni-stack 568(25). Uni-stack 568(34) has: horizontal axis of symmetry 558(10) that bisects cell region 510(11); and a horizontal axis of symmetry 558(11) that bisects cell region 510(12).

Cell region 510(11) of FIG. 5BH is a version of cell region 510(5) of FIG. 5AY which has been rotated 180 degrees (180°) about horizontal axis of symmetry 558(10) with respect to the orientation of cell region 510(5). Cell region 510(12) of FIG. 5BH is a version of cell region 510(6) of FIG. 5AY which has been rotated 180 degrees (180°) about horizontal axis of symmetry 558(11) with respect to the orientation of cell region 510(6).

FIG. 5BI is a layout diagram of a uni-stack 568(35), in accordance with some embodiments.

FIG. 5BI is similar to FIG. 5BH. For purposes of brevity, the discussion will focus on differences of FIG. 5BI as compared to FIG. 5BH rather than on similarities.

Uni-stack 568(35) is an example of single column stacked arrangement 102 of FIGS. 1A and 1C. Relative to the Y-axis, uni-stack 568(35) has a height of about 3.5*H.

Uni-stack 568(35) includes filler cell region 524(11), cell region 510(13), cell region 510(14) and filler cell region 524(12). As compared to FIG. 5BH, cell regions 510(13) and 510(14) of uni-stack 568(35) correspond to cell regions 510(11) and 510(12) of uni-stack 568(34). Also as compared to uni-stack 568(34) of FIG. 5BH, uni-stack 568(35) of FIG. 5BI further includes filler cell regions 524(11) and 524(12). In uni-stack 568(35), cell region 510(14) is stacked on filler cell region 524(12), and filler cell region 524(11) is stacked on cell region 510(13).

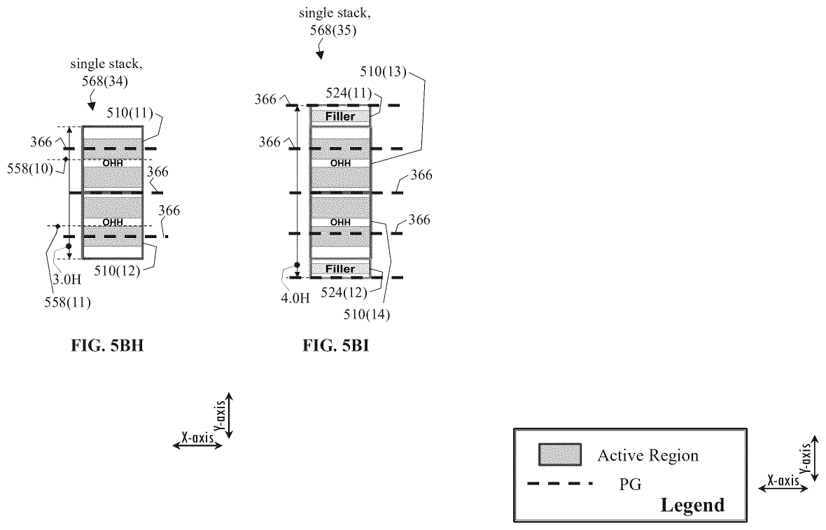

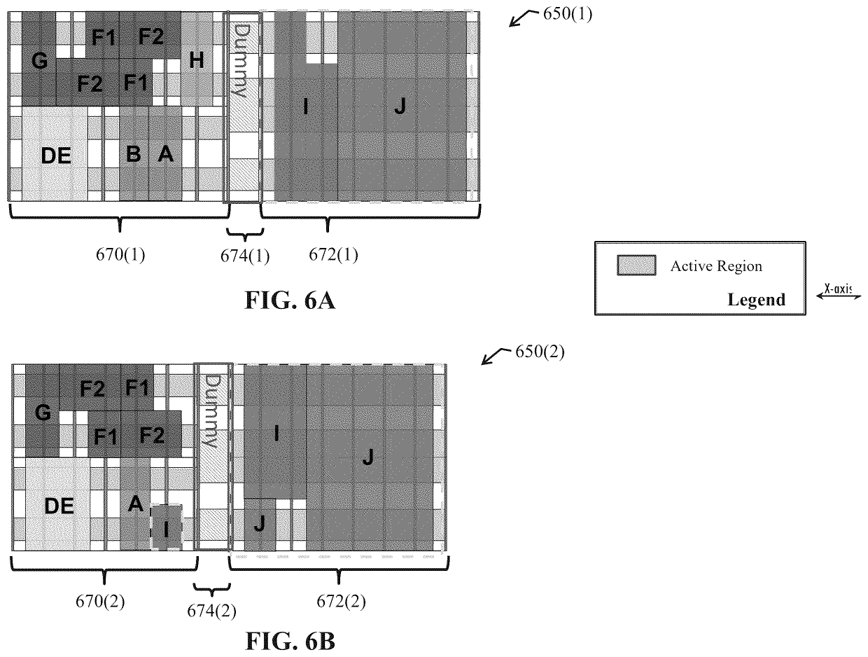

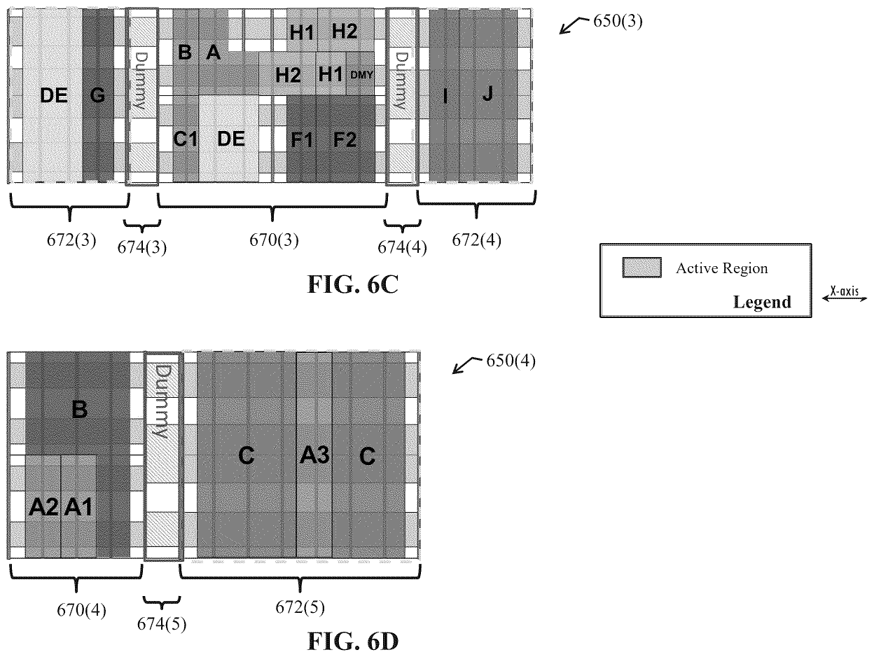

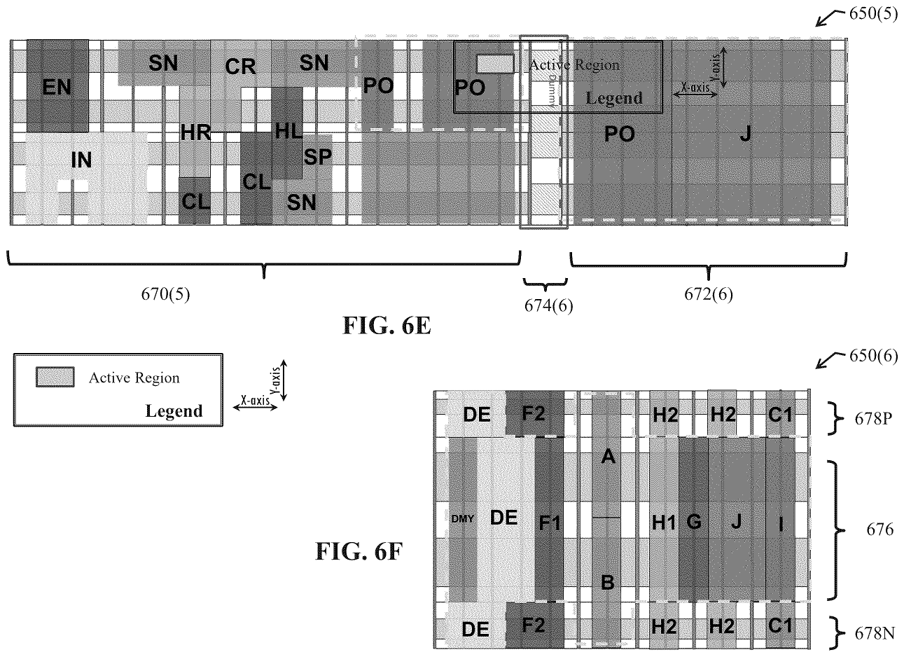

FIG. 6A is a floorplan diagram of a multi-stack 650(1), in accordance with some embodiments.

In general, a floorplan diagram is a type of layout diagram.

In some embodiments, multi-stack 650(1) is an example of an integrated clock-gating (ICG) macro. Multi-stack 650(1) includes an area 670(1), an area 672(1) and an area 674(1).

Area 670(1) includes instances of cell region 206PN of FIG. 2A and/or instances of cell region 206NP of FIG. 2B. More generally, in FIG. 6A and in other figures disclosed herein, a reference number of the type “670(x),” where x represents an index number, e.g., 670(1), denotes an example of an area that includes instances of cell region 206PN of FIG. 2A and/or instances of cell region 206NP of FIG. 2B.

Area 672(1) includes instances of cell region 218PNP of FIG. 2G and/or instances of cell region 218NPN of FIG. 2H. More generally, in FIG. 6A and in other figures disclosed herein, a reference number of the type “672(x),” where x represents an index number, e.g., 672(1), denotes an example of an area that includes instances of cell region 218PNP of FIG. 2G and/or instances of cell region 218NPN of FIG. 2H.

Area 674(1) includes one or more instances of dummy cell regions 232-239 and/or 259 of corresponding FIGS. 2M-2Q. More generally, in FIG. 6A and in other figures disclosed herein, a reference number of the type “674(x),” where x represents an index number, e.g., 674(1), denotes an example of an area that includes one or more instances of dummy cell regions 232-239 and/or 259 of corresponding FIGS. 2M-2Q.

Area 670(1) of multi-stack 650(1) includes zones A, B, DE, G and H, first and second instances of zone F1, and first and second instances zone F2. Area 672(1) includes zones I and J. Relative to the X-axis, multi-stack 650(1) has a width of about 30*S. In some embodiments, a zone represents a function provided by the components, e.g., transistors, included therein. In some embodiments, a zone represents a circuit comprised by the components, e.g., transistors, included therein. In some embodiments, zones I and J are useable for timing paths of multi-stack 650(1). In some embodiments, by forming zones I and J in area 672(1), speed and driving strength of multi-stack 650(1) are increased though the size of the footprint is maintained if not reduced. In some embodiments, multi-stack 650(1) exhibits an overall area (footprint) that is reduced by an amount, CHG1, in a range (≈17%)≤CHG1≤(≈18), In some embodiments, multi-stack 650(1) exhibits a speed improvement by an amount, CHG2, in a range (≈12%)≤CHG2≤(≈14%). In some embodiments, multi-stack 650(1) exhibits a power consumption reduction by an amount, CHG3, in a range (≈7%)≤CHG3≤(≈8%).

FIG. 6B is a floorplan diagram of a multi-stack 650(2), in accordance with some embodiments.

In some embodiments, multi-stack 650(2) is an example of an ICG macro. Multi-stack 650(2) includes an area 670(2), an area 672(2) and an area 674(2).

Area 670(2) of multi-stack 650(2) includes zones A, DE, G and H, first and second instances of zone F1, first and second instances zone F2 and a first instance of zone I. Area 672(2) includes a second instance of zone I and first and second instances of zone J. Relative to the X-axis, multi-stack 650(2) has a width of about 28*S. some embodiments, zones I and J are useable for timing paths of multi-stack 650(1). In some embodiments, by forming zones I and J in area 672(2), speed and driving strength of multi-stack 650(2) are increased though the size of the footprint is maintained if not reduced. In some embodiments, multi-stack 650(2) exhibits a speed improvement by an amount, CHG4, in a range (≈12%)≤CHG4≤(≈14%). In some embodiments, multi-stack 650(2) exhibits a power consumption reduction by an amount, CHG5, in a range (≈7%)≤CHG5≤(≈8%).

FIG. 6C is a floorplan diagram of a multi-stack 650(3), in accordance with some embodiments.

In some embodiments, multi-stack 650(3) is an example of a flip-flop. In some embodiments, the flip-flop is a a scan-insertion type D flip-flop, with a a transmission gate. Multi-stack 650(3) includes an area 672(3), an area 674(3), an area 670(3), an area 674(4) and an area 672(4).

Area 672(3) of multi-stack 650(3) includes zone G and a first instance of zone DE. Area 670(3) includes zones A, B, C1, F1, F2, a second instance of zone DE, first and second instances of zone H1, and first and second instances zone H2 and a dummy region DMY. Area 672(4) includes zones I and J. Relative to the X-axis, multi-stack 650(3) has a width of about 36*S. In some embodiments, regions I and J and DE and G are useable for timing paths of multi-stack 650(3). In some embodiments, by forming zone G and the first instance of zone DE in area 672(3) and by forming zones I and J in area 672(4), the driving strength and speed of multi-stack 650(3) are increased though though the size of the footprint is maintained if not reduced.

FIG. 6D is a floorplan diagram of a multi-stack 650(4), in accordance with some embodiments.

In some embodiments, multi-stack 650(4) is an example of an Exclusive OR (XOR) macro. In some embodiments, multi-stack 650(4) is an example of an Exclusive NOR (XNOR) macro. In some embodiments, the macro represented by multi-stack 650(4) has three inputs. Multi-stack 650(4) includes an area 670(4), an area 674(5) and an area 672(5).

Area 670(4) of multi-stack 650(4) includes zones A1, A2 and B. Area 672(5) includes a zone A3, and first and second instances of zone C. Relative to the X-axis, multi-stack 650(4) has a width of about 24*S. In some embodiments, region C and A3 are useable for timing paths of multi-stack 650(4). In some embodiments, by forming a zone A3 and the first and second instances of zone C in area 672(5), the driving strength and speed of multi-stack 650(4) are increased though the size of the footprint is maintained if not reduced.

FIG. 6E is a floorplan diagram of a multi-stack 650(5), in accordance with some embodiments.

In some embodiments, multi-stack 650(5) is an example of a low to high clamp and source macro. Multi-stack 650(5) includes an area 670(5), an area 674(6) and an area 672(6).

Area 670(5) of multi-stack 650(5) includes zones EN, IN, CR, HL and HR, first and second instances of a zone CL, first and second instances of a zone PO, and first, second and third instances of zone SN. Area 672(6) includes a zone J and a third instance of zone PO. Relative to the X-axis, multi-stack 650(5) has a width of about 54*S. In some embodiments, regions PO and J are useable for timing paths of multi-stack 650(). In some embodiments, by forming zone J and the third instance of zone PO in area 672(6), the driving strength and speed of multi-stack 650(5) are increased though the size of the footprint is maintained if not reduced.

FIG. 6F is a floorplan diagram of a multi-stack 650(6), in accordance with some embodiments.

In some embodiments, multi-stack 650(6) is an example of a flip-flop macro. Multi-stack 650(6) includes an area 678P, an area 676 and an area 678N.

Area 678P of multi-stack 650(6) includes a first instance of a zone C1, a first instance of a zone DE, a first instance of a zone F2, first and second instances of a zone H2 and a first portion of a zone A. Area 678N of multi-stack 650(6) includes a second instance of zone C1, a second instance of zone DE, a second instance of zone F2, third and fourth instances of zone H2 and a first portion of a zone B. Area 676 includes zones F1, G, H1, I and J, a third instance of zone DE, a second portion of zone A, a second portion of zone B, and a dummy zone DMY. Relative to the X-axis, multi-stack 650(6) has a width of about 26*S. In some embodiments, zones F1, G, H1, I and J, a third instance of zone DE, a second portion of zone A, a second portion of zone B, and a dummy zone DMY are useable for timing paths of multi-stack 650(6). In some embodiments, by forming zones F1, G, H1, I and J, the third instance of zone DE, the second portion of zone A, the second portion of zone B and the dummy zone DMY in in area 676, the driving strength and speed of multi-stack 650(6) are increased though the size of the footprint is maintained if not reduced.

FIGS. 7A-7B are corresponding cross-sectional views 705A-705B of a cell region, in accordance with some embodiments.

In particular, FIGS. 7A-7B are corresponding cross sectional views (cross-sections) of a cell region based on cell region 206PN of FIG. 2A. FIG. 7A corresponds to section line 7A-7A′ of FIG. 2A. FIG. 7B corresponds to section line 7B-7B′ of FIG. 2A.

Each of FIGS. 7A-7B includes: an active region layer 753; a transistor-components layer 755; and MET0 layer 757. Each of FIGS. 7A-7B further includes: a P-type substrate 741; an N-well 743 formed in substrate 741; P-type fins 747 formed partially in N-well 743 relative to the Z-axis; fin-insulator 745 formed against fins 747; and an insulating layer 751 formed on fins 747, the upper surface of N-well 743, the upper surface of fin-insulator 745 and substrate 743.

Each of FIGS. 7A-7B additionally includes N-type fins 749 formed partially in substrate 743 relative to the Z-axis. In each of FIGS. 7A-7B: fins 747 represent an active region 707P corresponding to active region 208P of FIG. 2A; and fins 749 represent an active region 708N corresponding to active region 208N of FIG. 2A. Insulating layer 751 is also formed on fins 749. Insulating structures 711 are (1) formed on insulating layer 751 and (2), relative to the Y-axis, abut gate segment 709_g.

Each of FIGS. 7A-7B assumes an example of a CMOS architecture implemented with a finFET transistor architecture. In some embodiments, the CMOS architecture is implemented with a different transistor architecture, e.g., planar field-effect transistor (FET) architecture, gate-all-around FET (GAAFET) architectures, or the like. Examples of the GAAFET architecture include as nanowire architecture, nanosheet architecture, forksheet architecture, or the like.

FIG. 7A further includes: a gate segment 709_g; a via-to-gate (VG) contact 713; M0_PG segments 717(1) and 717(2); and M0_RTE 719. VG contact 713 is formed between gate segment 709_g and a corresponding one of M0_RTE segments 719. M0_PG segment 717(1) is an example of M0_PG segment 262 of FIGS. 2A-2B. M0_PG segment 717(2) is an example of M0_PG segment 264 of FIGS. 2A-2B.

FIG. 7B is similar to FIG. 7A. For purposes of brevity, the discussion will focus on differences of FIG. 7B as compared to FIG. 7A rather than on similarities.

FIG. 7B includes: a metal-to-source/drain contact (MD) structure 709_md rather than gate segment 709_g of FIG. 7A; and a via-to-MD (VD) contact 715 rather than VG contact 713 of FIG. 7A.

VD contact structure 715 is formed between MD structure 709_md a corresponding one of M0_RTE segments 719.

FIG. 8 is a flowchart (flow diagram) of a method 800 of manufacturing device, in accordance with some embodiments.

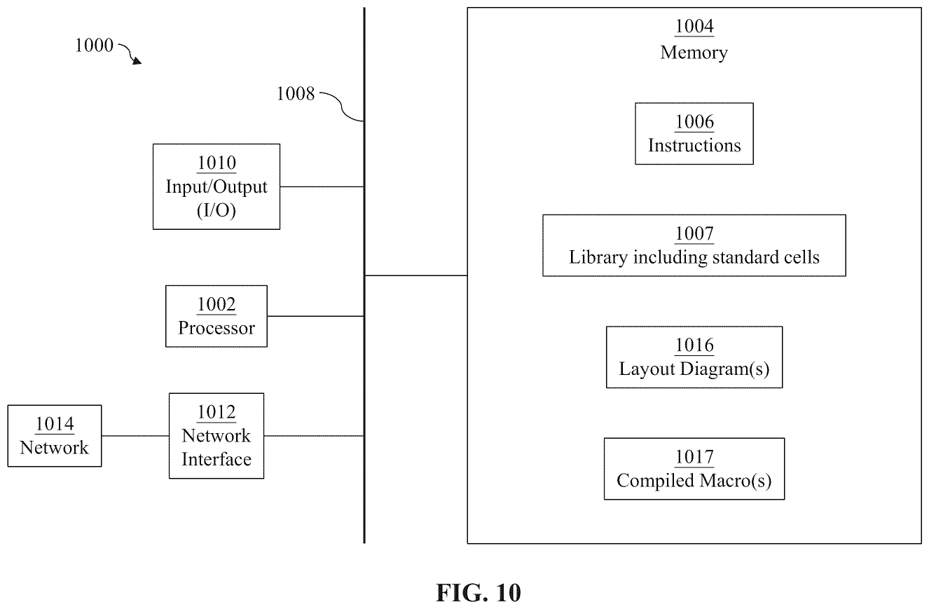

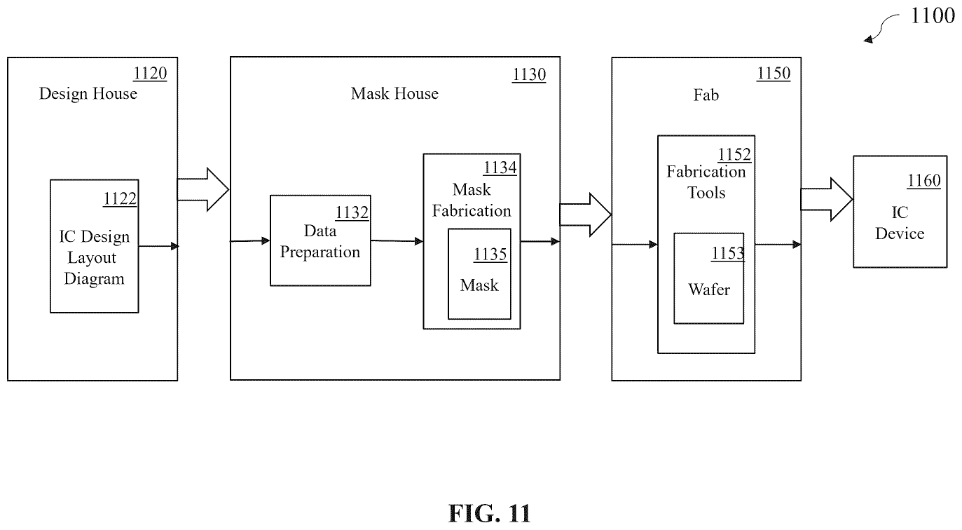

Method 800 is implementable, for example, using EDA system 1000 (see FIG. 10, discussed below) and an IC manufacturing system 1100 (see FIG. 11, discussed below), in accordance with some embodiments. Examples of semiconductor devices which can be manufactured according to method 800 include the semiconductor devices disclosed herein, or the like.

In FIG. 8, method 800 includes blocks 802-804. At block 802, a layout diagram is generated which, among other things, includes one or more layout diagrams disclosed herein, or one or more layout diagrams corresponding to one or more of the semiconductor devices disclosed herein, or the like. Block 802 is implementable, for example, using EDA system 1000 (see FIG. 10, discussed below), in accordance with some embodiments. From block 802, flow proceeds to block 804.

At block 804, based on the layout diagram, at least one of (A) one or more photolithographic exposures are made or (b) one or more photolithography masks are fabricated or (C) one or more components in a layer of a device, e.g., a device is fabricated. Block 804 is implementable, for example, using IC manufacturing system 1100 (see FIG. 11, discussed below), in accordance with some embodiments.

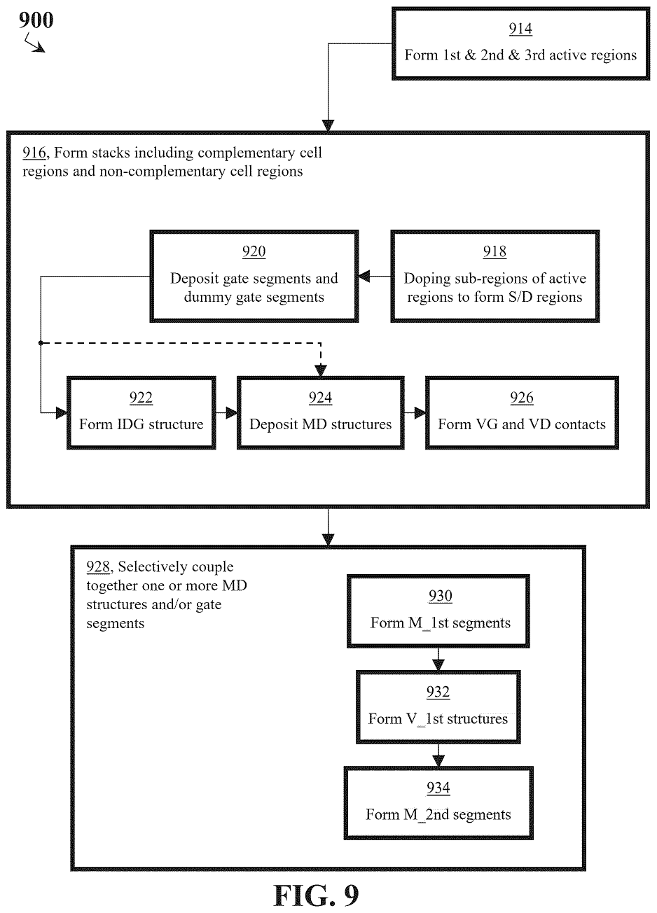

FIG. 9 is a flowchart of a method 900 of manufacturing a device, in accordance with some embodiments.

Method 900 is an example of block 804 (see FIG. 8, discussed above). Method 900 is implementable, for example, using IC manufacturing system 1000 (see FIG. 10, discussed below), in accordance with some embodiments. Examples of a devices which can be manufactured according to method 900 include devices that include one or more of the devices disclosed herein, devices including one or more of the macro regions disclosed herein, devices including one or more of the cell regions disclosed herein, or the like. Method 900 includes blocks 914-934.

At block 914, active regions that extend in a first direction (e.g., parallel to the X-axis), are formed. Examples of the active regions include active regions 208P and 208N of FIGS. 2A-2B, 212P and 212N of FIGS. 2C-2D, 216P and 216N of FIGS. 2E-2F, 220P and 222N of FIGS. 2G-2H, 226P of FIGS. 2I, 226N of FIGS. 2J, 230P of FIGS. 2K, 230N of FIGS. 2L, 249(1)-249(7) of FIGS. 2M-2Q, or the like. From block 914, flow proceeds to block 916.

At block 916, stacks are formed that include complementary cell regions and non-complementary cell regions. In some embodiments, in a stack, at least one of the complementary cell regions is above at least one of the non-complementary cell regions. In some embodiments, in a stack, at least one of the non-complementary cell regions is above at least one of the complementary cell regions. Examples of the stacks include multi-stacks and uni-stacks. Examples of multi-stacks include multi-stacks 350(1)-350(60) of corresponding FIG. 3AA-3CH, 450(1)-450(60) of corresponding FIG. 4AA-4CH, or the like. Examples of uni-stacks include uni-stacks 568(1)-568(35) of corresponding FIG. 5AA-5BI, or the like.

Regarding block 916, examples of complementary cell regions include cell regions 206PN, 206NP, 210PN, 210NP, 214PPNN, 214NNPP and 218PNP of corresponding FIGS. 2A-2L, or the like. , and dummy CRs 232, 234, 236, 238, 239 and 259 of corresponding FIGS. 2M-2Q.

Regarding block 916, examples of non-complementary cell regions include non-complementary cell regions 228P and 228N of corresponding FIGS. 2K-2L, filler cell regions 224P and 224N of corresponding FIGS. 2I-2J, or the like. Regarding block 916, more generally, examples of the cell regions include any of the complementary cell regions disclosed herein or the like, and examples of the non-complementary cell regions include any of the non-complementary cell regions disclosed herein or the like. Block 916 includes blocks 918-926. Within block 916, flow proceeds to block 918.

At block 918, sub-regions of the ARs are doped to form S/D regions. Example locations of the S/D regions include intersections where an MD structures (e.g., 209_md in FIGS. 2A-2B, or the like) overlie corresponding active regions. From block 918, flow proceeds to block 920.

At block 920, gate segments and dummy gate segments are deposited that extend in a second direction (e.g., parallel to the Y-axis) and are over one or more of the active regions. Examples of the gate segment include gate segments 209_g of FIGS. 2A-2B, or the like. Examples of the dummy gate segments include dummy gate segments 209_d of FIGS. 2A-2D, or the like. From block 920, flow proceeds to block 922. In some embodiments, flow proceeds from block 920 to block 920.

In some embodiments, regarding block 920, gate lines and dummy gate lines are deposited. Then portions of the gate lines and the dummy gate lines are removed resulting in the corresponding gate segments and dummy gate segments.

At block 922, dummy gate segments are converted into IDG structures. Discussion of dummy gate segments is included in the discussion of FIGS. 2A-2B. From block 922, flow proceeds to block 928.

At block 924, MD structures (e.g., 209_md in FIGS. 2A-2B, or the like) are deposited. From block 924, flow proceeds to block 926.

At block 926, VG contacts (not shown) and VD contacts (not shown) are formed over corresponding (A) ones of the gate segments and (B) ones of the MD structures. From block 926, flow exits block 916. From block 916, flow exits block 914 and proceeds to block 928.

At block 928, one or more of the MD structures and/or one or more of the gate segments are coupled together to form corresponding transistors. Within block 928, flow proceeds to block 930.

At block 930, in a first metallization layer (M_1st layer), M_1st segments that extend in the first direction (e.g., parallel to the X-axis) and are over (A) corresponding ones of the VG contacts and/or (B) corresponding ones of the VD contacts are formed, the M_1st segments including M_1st power grid (PG) segments. An example of the M_1st layer is layer MET0 757 in FIGS. 7A-7B, or the like. Examples of the M_1st segments include M0_PG segments 262 and 264 in FIGS. 2A-2B, 717(1) and 717(2) in FIGS. 7A-7B, or the like. From block 930, flow proceeds to block 932.

At block 932, V0 structures (not shown) are formed over corresponding ones of the M0 segments. From block 932, flow proceeds to block 934.

At block 934, M1 segments (not shown) are formed over corresponding ones of the V0 structures.

In some embodiments, method 900 includes one or more blocks to form BM0, VB0, BM1 structures on the back-side of the integrated circuit.

In some embodiments, blocks 912-928 result in the following including: relative to the first direction, e.g., parallel to the X-axis, left and right boundaries of each cell region are corresponding first and second ones of the IDG segments. Examples of the left and right boundaries include left 223_L and right 223_R boundaries of FIGS. 2A-2B, or the like.

In some embodiments, blocks 912-928 result in the following including: relative to the second direction, e.g., top and bottom boundaries of each of the cell regions are at least proximal to corresponding ones of the PG segments (e.g., 717(1), 717(2), 719). Examples of the top and bottom boundaries include top 223_T and bottom 223_B boundaries of FIGS. 2A-2B, or the like.

In some embodiments, blocks 912-920 result in the following including: the complementary cell regions having a height of at least about one unit and the non-complementary cell regions having a height of about one-half unit. Examples of the complementary cell regions and the non-complementary cell regions are provided above in the discussion of block 916. Examples of the unit include height H, discussed above.

In some embodiments, blocks 912-920 result in the following including: a first one of the non-complementary cell regions being stacked one of above or under a first one of the complementary cell regions. Examples such stacking include the stacking shown in 3AA, 3AC-3AE, 3AG-3BX, 3BZ, 3CC, 3CE, 3CH, 4AA, 4AC-4AE, 4AG-4BX, 4BZ, 4CC, 4CE, 4CH, 5AA-5AD, 5AG-5AX, 5AZ-5BA and 5BI, or the like.

FIG. 10 is a block diagram of an electronic design automation (EDA) system 1000 in accordance with some embodiments.

In some embodiments, EDA system 1000 includes an automatic placement and routing (APR) system. In some embodiments, EDA system 1000 is a general purpose computing device including a processor 1002 (e.g., a hardware processor) and a non-transitory, computer-readable storage medium 1004. Storage medium 1004, amongst other things, is encoded with, i.e., stores, computer program code 1006, i.e., a set of executable instructions. Execution of instructions 1006 by processor 1002 represents (at least in part) an EDA tool which implements a portion of or all of one or more methods of generating layout diagrams corresponding to the layout diagrams disclosed herein, layout diagrams corresponding to the semiconductor devices disclosed herein, or the like, in accordance with one or more embodiments (hereinafter, the noted processes and/or methods).

Storage medium 1004, amongst other things, stores layout diagrams 1011 such as the layout diagrams disclosed herein, other the like.

Processor 1002 is electrically coupled to storage medium 1004 via a bus 1008. Processor 1002 is further electrically coupled to an I/O interface 1010 by a bus 1008. A network interface 1012 is further electrically connected to processor 1002 via bus 1008. Network interface 1012 is connected to a network 1014, so that processor 1002 and storage medium 1004 are capable of connecting to external elements via network 1014. Processor 1002 is configured to execute computer program code 1006 encoded in storage medium 1004 in order to cause EDA system 1000 to be usable for performing a portion of or all the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, storage medium 1004 is an electronic, magnetic, optical, electromagnetic, infrared, and/or a semiconductor system (or apparatus or device). For example, storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 1004 includes a compact disk-read only memory (CD-ROM), a compact disk-read/write (CD-R/W), and/or a digital video disc (DVD).

In one or more embodiments, storage medium 1004 stores instructions, i.e., computer program code 1006 configured to cause EDA system 1000 (where such execution represents (at least in part) the EDA tool) to be usable for performing a portion of or all the noted processes and/or methods. In one or more embodiments, storage medium 1004 further stores information which facilitates performing a portion of or all the noted processes and/or methods. In one or more embodiments, storage medium 1004 stores library 1007 of standard cells including standard cells that correspond to components of the layout diagrams disclosed herein. Storage medium 1004 stores one or more layout diagrams 1016 such as one or more layout diagrams corresponding to the layout diagrams disclosed herein, one or more layout diagrams corresponding to the semiconductor devices disclosed herein, one or more compiled macros 1017 based on such layout diagrams, or the like.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 further includes network interface 1012 coupled to processor 1002. Network interface 1012 allows EDA system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 1000.

EDA system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a user interface (UI) through I/O interface 1010. The information is stored in computer-readable medium 1004 as UI 1042.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 1000. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an integrated circuit (IC) manufacturing system 1100, and an IC manufacturing flow associated therewith, in accordance with some embodiments.

In some embodiments, based on the layout diagram generated by block 802 of FIG. 8, the IC manufacturing system 1100 implements block 804 of FIG. 8 wherein at least one of (A) one or more semiconductor masks or (B) at least one component in a layer of an inchoate semiconductor integrated circuit is fabricated using manufacturing system 1100. In some embodiments, the IC manufacturing system 1100 implements the flowcharts of FIG. 8, or the like.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout 1122. IC design layout 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout 1122 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 1120 implements a proper design procedure to form IC design layout 1122. The design procedure includes one or more of logic design, physical design or place and route. IC design layout 1122 is presented in one or more data files having information of the geometrical patterns. For example, IC design layout 1122 is expressed in a GDSII file format or DFII file format.

Mask house 1130 includes data preparation 1132 and mask fabrication 1134. Mask house 1130 uses IC design layout 1122 to manufacture one or more masks 1135 to be used for fabricating the various layers of IC device 1160 according to IC design layout 1122. Mask house 1130 performs mask data preparation 1132, where IC design layout 1122 is translated into a representative data file (“RDF”). Mask data preparation 1132 supplies the RDF to mask fabrication 1134. Mask fabrication 1134 includes a mask writer. A mask writer converts the RDF to an image on a substrate, such as a mask (reticle) or a semiconductor wafer. The design layout is manipulated by mask data preparation 1132 to comply with particular characteristics of the mask writer and/or requirements of IC fab 1150. In FIG. 11, mask data preparation 1132, mask fabrication 1134, and mask 1135 are illustrated as separate elements. In some embodiments, mask data preparation 1132 and mask fabrication 1134 are collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout 1122. In some embodiments, mask data preparation 1132 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 1132 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1134, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout 1122 to fabricate a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 1122.

The above description of mask data preparation 1132 has been simplified for the purposes of clarity. In some embodiments, mask data preparation 1132 includes additional features such as a logic operation (LOP) to modify the IC design layout according to manufacturing rules. Additionally, the processes applied to IC design layout 1122 during data preparation 1132 may be executed in a variety of different orders.

After mask data preparation 1132 and during mask fabrication 1134, a mask 1135 or a group of masks 1135 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 1134 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1150 is an IC fabrication business that includes one or more manufacturing facilities for the fabrication of a variety of different IC products. In some embodiments, IC fab 1150 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 1150 uses mask (or masks) 1135 fabricated by mask house 1130 to fabricate IC device 1160 using fabrication tools 1152. Thus, IC fab 1150 at least indirectly uses IC design layout 1122 to fabricate IC device 1160. In some embodiments, a semiconductor wafer 1153 is fabricated by IC fab 1150 using mask (or masks) 1135 to form IC device 1160. Semiconductor wafer 1153 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a semiconductor device includes: active regions (ARs) extending in a first direction and correspondingly configured with a first dopant type (first-type AR) or a second dopant type (second-type AR); gate segments and isolation dummy gate (IDG) segments extending in a perpendicular second direction and being over one or more of the ARs; and in a first metallization (M_1st) layer, M_1st segments extending in the first direction, the M_1st segments configured for a reference voltage or routing signals; cell regions including complementary cell regions and non-complementary cell regions; wherein each of the complementary cell regions including at least one of the first-type ARs and at least one of the second-type ARs; wherein each of the non-complementary cell regions including one of the first-type ARs or the second-type ARs and being free of including another of the second-type ARs or the first-type ARs; wherein, relative to the first direction, left and right boundaries of each cell region being corresponding first and second ones of the IDG segments; and wherein, relative to the second direction: top and bottom boundaries of each of the cell regions being proximal to or overlapping of corresponding ones of the M_1st segments; the complementary cell regions having a height of at least about one unit, and the non-complementary cell regions having a height of about one-half unit; and a first one of the non-complementary cell regions being arranged one of above or under a first one of the complementary cell regions.

In some embodiments, the first one of the non-complementary cell regions is a first filler cell region such that the corresponding first-type AR or second-type AR of the first filler cell region, is free from being electrically coupled to the M_1st segments.

In some embodiments, a second one of the non-complementary cell regions is a second filler cell region; and the second filler cell region is arranged conversely under or above the first one of the complementary cell regions such that the second filler cell region and the first filler cell region are on opposite sides of the first one of the complementary cell regions.

In some embodiments, a second one of the complementary cell regions is between the second one of the non-complementary cell regions and the first one of the complementary cell regions.

In some embodiments, each of the first complementary cell region and the second complementary cell region has a height of about one unit.

In some embodiments, a second one of the non-complementary cell regions is a functional cell region such that the corresponding first-type AR or second-type AR of the second one of the non-complementary cell regions is electrically coupled to one or more of the M_1st segments; and the second one of the non-complementary cell regions is arranged conversely under or above the first one of the complementary cell regions such that second one of the non-complementary cell regions is and the first one of the non-complementary cell regions are on opposite sides of the first one of the complementary cell regions.

In some embodiments, the first one of the complementary cell regions has a height of about one unit.

In some embodiments, the first one of the complementary cell regions has a height of about two units. In some embodiments, the first one of the complementary cell regions further includes a second one of the first-type ARs or a second one of the second-type ARs.

In some embodiments, the first one of the complementary cell regions is a functional cell region such that the at least one of the first-type ARs and the at least one of the second-type ARs are electrically coupled to one or more of the M_1st segments. the first one of the non-complementary cell regions is a functional cell region such that the corresponding first-type AR or second-type AR is electrically coupled to one or more of the M_1st segments.

In some embodiments, a second one of the non-complementary cell regions is arranged conversely under or above the first one of the complementary cell regions such that the second one of the non-complementary cell regions and the first one of the non-complementary cell regions are on opposite sides of the first one of the complementary cell regions.

In some embodiments, a semiconductor device includes: active regions (ARs) extending in a first direction and correspondingly configured with a first dopant type (first-type AR) or a second dopant type (second-type AR); gate segments and isolation dummy gate (IDG) segments extending in a perpendicular second direction and being over one or more of the ARs; and in a first metallization (M_1st) layer, M_1st segments extending in the first direction, the M_1st segments including power grid (PG) segments configured for a reference voltage and routing segments configured for corresponding signals; cell regions including complementary cell regions and non-complementary cell regions; wherein each of the complementary cell regions including at least one of the first-type ARs and at least one of the second-type ARs; wherein each of the non-complementary cell regions including one of the first-type ARs or the second-type ARs and being free of including another of the second-type ARs or the first-type ARs; wherein, relative to the first direction, left and right boundaries of each cell region being corresponding first and second ones of the IDG segments; and wherein, relative to the second direction: top and bottom boundaries of each of the cell regions being proximal to or overlapping of corresponding ones of the PG segments or the routing segments; the complementary cell regions having a height of at least about one unit, and the non-complementary cell regions having a height of about one-half unit; a first one of the non-complementary cell regions being arranged one of above or under a first one of the complementary cell regions; a second one of the non-complementary cell regions is arranged conversely under or above the first one of the complementary cell regions. such that the second one of the non-complementary cell regions and the first one of the non-complementary cell regions are on opposite sides of the first one of the complementary cell regions.

In some embodiments, the first one of the non-complementary cell regions is a first filler cell region such that the corresponding first-type AR or second-type AR is free from being electrically coupled to the M_1st segments.

In some embodiments, the first one of the non-complementary cell regions is a functional cell region such that the at least one of the first-type ARs and the at least one of the second-type ARs are electrically coupled to one or more of the M_1st segments.

In some embodiments, the second one of the non-complementary cell regions is a second functional cell region.

In some embodiments, the first one of the complementary cell regions has a height of about one unit.

In some embodiments, the first one of the complementary cell regions has a height of about two units.

In some embodiments, the first one of the complementary cell region includes a second one of the first-type ARs or a second one of the second-type ARs.

In some embodiments, a method (of forming a semiconductor device) includes: doping areas of a substrate resulting in active regions (ARs) that extend in a first direction and correspondingly are configured with a first dopant type (first-type AR) or a second dopant type (second-type AR); forming cell regions including complementary cell regions and non-complementary cell regions; wherein the forming cell regions resulting in at least: each of the complementary cell regions including at least one of the first-type ARs and at least one of the second-type ARs; and each of the non-complementary cell regions including one of the first-type ARs or the second-type ARs and being free of including another of the second-type ARs or the first-type ARs; wherein the forming cell regions including: depositing gate lines extending in the second direction and being over one or more of the ARs; removing portions of the gate lines resulting in corresponding gate segments; and converting selected ones of the gate segments into isolation dummy gate (IDG) segments; and in a first metallization (M_1st) layer, forming M_1st segments extending in the first direction, the M_1st segments including power grid (PG) segments configured for a reference voltage and routing segments configured for corresponding signals; and wherein the forming cell regions and the forming M_1st segments resulting in at least: relative to the first direction, left and right boundaries of each cell region being corresponding first and second ones of the IDG segments; and relative to the second direction: top and bottom boundaries of each of the cell regions being proximal to or overlapping of corresponding ones of the PG segments or the routing segments; the complementary cell regions having a height of at least about one unit, and the non-complementary cell regions having a height of about one-half unit; and a first one of the non-complementary cell regions being arranged above or under a first one of the complementary cell regions.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A semiconductor device comprising:
active regions (ARs) extending in a first direction and correspondingly configured with a first dopant type (first-type AR) or a second dopant type (second-type AR);
gate segments and isolation dummy gate (IDG) segments extending in a perpendicular second direction and being over one or more of the ARs; and
in a first metallization (M_1st) layer, M_1st segments extending in the first direction, the M_1st segments configured for a reference voltage or routing signals;
cell regions including complementary cell regions and non-complementary cell regions;
wherein each of the complementary cell regions including at least one of the first-type ARs and at least one of the second-type ARs;
wherein each of the non-complementary cell regions including one of the first-type ARs or the second-type ARs and being free of including another of the second-type ARs or the first-type ARs;
wherein, relative to the first direction, left and right boundaries of each cell region being corresponding first and second ones of the IDG segments; and
wherein, relative to the second direction:
top and bottom boundaries of each of the cell regions being proximal to or overlapping of corresponding ones of the M_1st segments;
the complementary cell regions having a height of at least about one unit, and the non-complementary cell regions having a height of about one-half unit; and
a first one of the non-complementary cell regions being arranged one of above or under a first one of the complementary cell regions.

2. The semiconductor device of claim 1, wherein:
the first one of the non-complementary cell regions is a first filler cell region such that the corresponding first-type AR or second-type AR of the first filler cell region, is free from being electrically coupled to the M_1st segments.

3. The semiconductor device of claim 2, wherein:
a second one of the non-complementary cell regions is a second filler cell region; and
the second filler cell region is arranged conversely under or above the first one of the complementary cell regions such that the second filler cell region and the first filler cell region are on opposite sides of the first one of the complementary cell regions.

4. The semiconductor device of claim 3, wherein:
a second one of the complementary cell regions is between the second one of the non-complementary cell regions and the first one of the complementary cell regions.

5. The semiconductor device of claim 4, wherein:
each of the first complementary cell region and the second complementary cell region has a height of about one unit.

6. The semiconductor device of claim 2, wherein:
a second one of the non-complementary cell regions is a functional cell region such that the corresponding first-type AR or second-type AR of the second one of the non-complementary cell regions is electrically coupled to one or more of the M_1st segments; and
the second one of the non-complementary cell regions is arranged conversely under or above the first one of the complementary cell regions such that second one of the non-complementary cell regions is and the first one of the non-complementary cell regions are on opposite sides of the first one of the complementary cell regions.

7. The semiconductor device of claim 6, wherein:
the first one of the complementary cell regions has a height of about one unit.

8. The semiconductor device of claim 6, wherein:
the first one of the complementary cell regions has a height of about two units.

9. The semiconductor device of claim 8, wherein:
the first one of the complementary cell regions further includes a second one of the first-type ARs or a second one of the second-type ARs.

10. The semiconductor device of claim 1, wherein:
the first one of the complementary cell regions is a functional cell region such that the at least one of the first-type ARs and the at least one of the second-type ARs are electrically coupled to one or more of the M_1st segments.

11. The semiconductor device of claim 1, wherein:
the first one of the non-complementary cell regions is a functional cell region such that the corresponding first-type AR or second-type AR is electrically coupled to one or more of the M_1st segments.

12. The semiconductor device of claim 1, wherein:
a second one of the non-complementary cell regions is arranged conversely under or above the first one of the complementary cell regions such that the second one of the non-complementary cell regions and the first one of the non-complementary cell regions are on opposite sides of the first one of the complementary cell regions.

13. A semiconductor device comprising:
active regions (ARs) extending in a first direction and correspondingly configured with a first dopant type (first-type AR) or a second dopant type (second-type AR);
gate segments and isolation dummy gate (IDG) segments extending in a perpendicular second direction and being over one or more of the ARs; and
in a first metallization (M_1st) layer, M_1st segments extending in the first direction, the M_1st segments including power grid (PG) segments configured for a reference voltage and routing segments configured for corresponding signals;
cell regions including complementary cell regions and non-complementary cell regions;
wherein each of the complementary cell regions including at least one of the first-type ARs and at least one of the second-type ARs;
wherein each of the non-complementary cell regions including one of the first-type ARs or the second-type ARs and being free of including another of the second-type ARs or the first-type ARs;
wherein, relative to the first direction, left and right boundaries of each cell region being corresponding first and second ones of the IDG segments; and
wherein, relative to the second direction:
top and bottom boundaries of each of the cell regions being proximal to or overlapping of corresponding ones of the PG segments or the routing segments;
the complementary cell regions having a height of at least about one unit, and the non-complementary cell regions having a height of about one-half unit;
a first one of the non-complementary cell regions being arranged one of above or under a first one of the complementary cell regions;
a second one of the non-complementary cell regions is arranged conversely under or above the first one of the complementary cell regions. such that the second one of the non-complementary cell regions and the first one of the non-complementary cell regions are on opposite sides of the first one of the complementary cell regions.

14. The semiconductor device of claim 13, wherein:
the first one of the non-complementary cell regions is a first filler cell region such that the corresponding first-type AR or second-type AR is free from being electrically coupled to the M_1st segments.

15. The semiconductor device of claim 13, wherein:
the first one of the non-complementary cell regions is a functional cell region such that the at least one of the first-type ARs and the at least one of the second-type ARs are electrically coupled to one or more of the M_1st segments.

16. The semiconductor device of claim 15, wherein:
the second one of the non-complementary cell regions is a second functional cell region.

17. The semiconductor device of claim 13, wherein:
the first one of the complementary cell regions has a height of about one unit.

18. The semiconductor device of claim 13, wherein:
the first one of the complementary cell regions has a height of about two units.

19. The semiconductor device of claim 14, wherein:
the first one of the complementary cell region includes a second one of the first-type ARs or a second one of the second-type ARs.

20. A method of forming a semiconductor device, the method comprising:
doping areas of a substrate resulting in active regions (ARs) that extend in a first direction and correspondingly are configured with a first dopant type (first-type AR) or a second dopant type (second-type AR);
forming cell regions including complementary cell regions and non-complementary cell regions;
wherein the forming cell regions resulting in at least:
each of the complementary cell regions including at least one of the first-type ARs and at least one of the second-type ARs; and
each of the non-complementary cell regions including one of the first-type ARs or the second-type ARs and being free of including another of the second-type ARs or the first-type ARs;
wherein the forming cell regions including:
depositing gate lines extending in the second direction and being over one or more of the ARs;
removing portions of the gate lines resulting in corresponding gate segments; and
converting selected ones of the gate segments into isolation dummy gate (IDG) segments; and
in a first metallization (M_1st) layer, forming M_1st segments extending in the first direction, the M_1st segments including power grid (PG) segments configured for a reference voltage and routing segments configured for corresponding signals; and
wherein the forming cell regions and the forming M_1st segments resulting in at least:
relative to the first direction, left and right boundaries of each cell region being corresponding first and second ones of the IDG segments; and
relative to the second direction:
top and bottom boundaries of each of the cell regions being proximal to or overlapping of corresponding ones of the PG segments or the routing segments;
the complementary cell regions having a height of at least about one unit, and the non-complementary cell regions having a height of about one-half unit; and
a first one of the non-complementary cell regions being arranged above or under a first one of the complementary cell regions.
